(19) United States
(12) Patent Application Publication
(10) Pub. No.: US 2024/0243061 A1
(43) Pub. Date: Jul. 18, 2024

(54) BONDED THREE-DIMENSIONAL MEMORY DEVICE HAVING TEMPORARY ELECTRICAL GROUNDING PATHS IN DUMMY BLOCK AND METHODS OF MAKING THE SAME

(71) Applicant: SANDISK TECHNOLOGIES LLC, ADDISON, TX (US)

(72) Inventors: Takumi MORIYAMA, Yokkaichi (JP); Junji OH, Yokkaichi (JP); Masanori TSUTSUMI, Yokkaichi (JP)

(21) Appl. No.: 18/355,765

(22) Filed: Jul. 20, 2023

Related U.S. Application Data
(60) Provisional application No. 63/480,132, filed on Jan. 17, 2023.

(51) Int. Cl. H01L 23/528; H01L 23/522; H10B 41/10; H10B 41/27; H10B 41/35; H10B 41/40; H10B 43/10; H10B 43/27; H10B 43/35; H10B 43/40

(52) U.S. Cl. CPC H01L 23/5283; H01L 23/5226; H10B 41/10; H10B 41/27; H10B 41/35; H10B 41/40; H10B 43/10; H10B 43/27; H10B 43/35; H10B 43/40

(57) ABSTRACT

Memory stack structures including electrically floating vertical semiconductor channels can vertically extend through an alternating stack of insulating layers and electrically conductive layers. Metal interconnect structures connected to the electrically floating vertical semiconductor channels can be temporarily electrically grounded by a connection via structure that contacts a semiconducting or conductive carrier substrate, which is subsequently removed. The conductive via structure may be formed through the alternating stack, through a vertical stack of dielectric material plates and the insulating layers, or through a dielectric material portion. The conductive via structure may be connected to at least one bit line. In case the conductive via structure is temporarily connected to a plurality bit lines, the conductive via structure can be subsequently isolated from the bit lines.

### FIELD

The present disclosure relates generally to the field of semiconductor devices, and particularly to a bonded three-dimensional memory device containing temporary electrical grounding paths in a dummy memory block for electrically grounding metal interconnect structures during processing steps and methods of making the same.

### BACKGROUND

Three-dimensional vertical NAND strings having one bit per cell are disclosed in an article by T. Endoh et al., titled “Novel Ultra High-Density Memory With A Stacked-Surrounding Gate Transistor (S-SGT) Structured Cell”, IEDM Proc. (2001) 33-36.

### SUMMARY

According to an aspect of the present disclosure, a memory device comprising a memory die is provided. The memory die comprises: an alternating stack of insulating layers and electrically conductive layers that overlies a backside dielectric material layer; a memory opening vertically extending through the alternating stack; a memory opening fill structure located in the memory opening and comprising a vertical stack of memory elements and a vertical semiconductor channel; memory-side metal interconnect structures embedded within memory-side dielectric material layers that overlie the alternating stack; and a conductive via structure vertically extending between one of the memory-side metal interconnect structures and the backside dielectric material layer, wherein an entirety of an end surface of the conductive via structure is in contact with the backside dielectric material layer.

According to another aspect of the present disclosure, a method forming a memory device is provided. The method comprises: forming an alternating stack of insulating layers and spacer material layers over a carrier substrate, wherein the spacer material layers are formed as, or are subsequently replaced at least partly with, electrically conductive layers; forming a memory opening through the alternating stack; forming a memory opening fill structure in the memory opening, wherein the memory opening fill structure comprises a vertical stack of memory elements and a vertical semiconductor channel; forming a conductive via structure in electrical contact with the carrier substrate through or adjacent to the alternating stack, wherein the conductive via structure vertically extends at least from a first horizontal plane including a top surface of a bottommost insulating layer within the alternating stack to a second horizontal plane including a top surface of a topmost insulating layer within the alternating stack; forming memory-side metal interconnect structures embedded within memory-side dielectric material layers over the alternating stack and the conductive via structure; removing the carrier substrate; and forming a backside dielectric layer underneath the alternating stack and the conductive via structure, wherein an entirety of a bottom surface of the conductive via structure is contacted by the backside dielectric layer.

### BRIEF DESCRIPTION OF THE DRAWINGS

FIG. 1 is a schematic vertical cross-sectional view of a first exemplary structure after formation of a first alternating stack of first insulating layers and first sacrificial material layers and first dielectric material portions over a carrier substrate according to a first embodiment of the present disclosure.

FIG. 2A is a schematic vertical cross-sectional view of the first exemplary structure after formation of first-tier openings according to the first embodiment of the present disclosure.

FIG. 2B is a top-down view of the first exemplary structure of FIG. 2A. The vertical plane A-A′ is the cut plane of the vertical cross-sectional view of FIG. 2A.

FIG. 3 is a vertical cross-sectional view of the first exemplary structure after formation of sacrificial pillar structures according to the first embodiment of the present disclosure.

FIG. 4 is a vertical cross-sectional view of the first exemplary structure after formation of first-tier sacrificial opening fill structures according to the first embodiment of the present disclosure.

FIG. 5 is a schematic vertical cross-sectional view of a first exemplary structure after formation of a second alternating stack of second insulating layers and second sacrificial material layers and second dielectric material portions according to the first embodiment of the present disclosure.

FIG. 6 is a schematic vertical cross-sectional view of the first exemplary structure after formation of second-tier openings according to the first embodiment of the present disclosure.

FIG. 7 is a vertical cross-sectional view of the first exemplary structure after formation of memory openings and connection openings according to the first embodiment of the present disclosure.

FIG. 8 is a vertical cross-sectional view of the first exemplary structure after formation of a hard mask over the connection openings according to the first embodiment of the present disclosure.

FIGS. 9A-9D are sequential vertical cross-sectional views of a memory opening during formation of a memory opening fill structure according to the first embodiment of the present disclosure.

FIG. 10 is a vertical cross-sectional view of the first exemplary structure after formation of memory opening fill structures according to the first embodiment of the present disclosure.

FIG. 11 is a vertical cross-sectional view of the first exemplary structure after formation of conductive via structures according to the first embodiment of the present disclosure.

FIG. 12 is a top-down view of the first exemplary structure of FIG. 11. The vertical plane A-A′ is the cut plane of the vertical cross-sectional view of FIG. 11.

FIG. 13A is a vertical cross-sectional view of the first exemplary structure after formation of backside trenches according to the first embodiment of the present disclosure.

FIG. 13B is a top-down view of the first exemplary structure of FIG. 13A. The vertical plane A-A′ is the cut plane of the vertical cross-sectional view of FIG. 13A.

FIG. 14 is a vertical cross-sectional view of the first exemplary structure after formation of backside recesses according to the first embodiment of the present disclosure.

FIG. 15 is a vertical cross-sectional view of the first exemplary structure after formation of cylindrical semiconductor oxide portions according to the first embodiment of the present disclosure.

FIG. 16 is a vertical cross-sectional view of the first exemplary structure after formation of electrically conductive layers according to the first embodiment of the present disclosure.

FIG. 17 is a vertical cross-sectional view of the first exemplary structure after formation of backside trench fill structures according to the first embodiment of the present disclosure.

FIG. 18A is a vertical cross-sectional view of the first exemplary structure after formation of contact via structures according to the first embodiment of the present disclosure.

FIG. 18B is a top-down view of the first exemplary structure of FIG. 18A. The vertical plane A-A′ is the cut plane of the vertical cross-sectional view of FIG. 18A.

FIG. 18C is a vertical cross-sectional view of the first exemplary structure along the vertical plane C-C′ of FIG. 18B.

FIG. 19A is a vertical cross-sectional view of the first exemplary structure after formation of connection via structures according to the first embodiment of the present disclosure.

FIG. 19B is a top-down view of the first exemplary structure of FIG. 19A. The vertical plane A-A′ is the cut plane of the vertical cross-sectional view of FIG. 19A.

FIG. 20A is a vertical cross-sectional view of the first exemplary structure after formation of first-level metal lines including bit lines according to the first embodiment of the present disclosure.

FIG. 20B is a top-down view of the first exemplary structure of FIG. 20A. The vertical plane A-A′ is the cut plane of the vertical cross-sectional view of FIG. 20A.

FIG. 20C is a vertical cross-sectional view of the first exemplary structure along the vertical plane C-C′ of FIG. 20B.

FIG. 21 is a vertical cross-sectional view of the first exemplary structure after formation of additional metal interconnect structures and memory-side bonding pads according to the first embodiment of the present disclosure.

FIG. 22 is a vertical cross-sectional view of the first exemplary structure after attaching a logic die to a memory die according to the first embodiment of the present disclosure.

FIG. 23 is a vertical cross-sectional view of the first exemplary structure after removal of the carrier substrate according to the first embodiment of the present disclosure.

FIG. 24A is a vertical cross-sectional view of the first exemplary structure after removal of sacrificial pillar structures according to the first embodiment of present disclosure.

FIG. 24B is a magnified view of a region of the first exemplary structure of FIG. 24A.

FIG. 25A is a vertical cross-sectional view of the first exemplary structure after removing end portions of the memory films according to the first embodiment of present disclosure.

FIG. 25B is a magnified view of a region of the first exemplary structure of FIG. 25A.

FIG. 26 is a vertical cross-sectional view of the first exemplary structure after formation of a source layer and a dielectric cover layer according to the first embodiment of the present disclosure.

FIG. 27 is a vertical cross-sectional view of the first exemplary structure after patterning the source layer and the dielectric cover layer according to the first embodiment of the present disclosure.

FIG. 28 is a vertical cross-sectional view of the first exemplary structure after formation of a backside dielectric layer and backside bonding pads according to the first embodiment of the present disclosure.

FIG. 29A is a vertical cross-sectional view of a second exemplary structure after formation of conductive via structures according to a second embodiment of the present disclosure.

FIG. 29B is a top-down view of the second exemplary structure of FIG. 29A. The vertical plane A-A′ is the cut plane of the vertical cross-sectional view of FIG. 29A.

FIG. 30A is a vertical cross-sectional view of the second exemplary structure after formation of backside trenches according to the second embodiment of the present disclosure.

FIG. 30B is a top-down view of the second exemplary structure of FIG. 30A. The vertical plane A-A′ is the cut plane of the vertical cross-sectional view of FIG. 30A.

FIG. 31 is a vertical cross-sectional view of the second exemplary structure after formation of backside recesses according to the second embodiment of the present disclosure.

FIG. 32 is a vertical cross-sectional view of the second exemplary structure after formation of electrically conductive layers according to the second embodiment of the present disclosure.

FIG. 33 is a vertical cross-sectional view of the second exemplary structure after formation of backside trench fill structures according to the second embodiment of the present disclosure.

FIG. 34A is a vertical cross-sectional view of the second exemplary structure after formation of contact via structures according to the second embodiment of the present disclosure.

FIG. 34B is a top-down view of the second exemplary structure of FIG. 34A. The vertical plane A-A′ is the cut plane of the vertical cross-sectional view of FIG. 34A.

FIG. 34C is a vertical cross-sectional view of the second exemplary structure along the vertical plane C-C′ of FIG. 34B.

FIG. 35A is a vertical cross-sectional view of the second exemplary structure after formation of connection via structures according to the second embodiment of the present disclosure.

FIG. 35B is a top-down view of the second exemplary structure of FIG. 35A. The vertical plane A-A′ is the cut plane of the vertical cross-sectional view of FIG. 35A.

FIG. 36A is a vertical cross-sectional view of the second exemplary structure after formation of first-level metal lines including bit lines according to the second embodiment of the present disclosure.

FIG. 36B is a top-down view of the second exemplary structure of FIG. 36A. The vertical plane A-A′ is the cut plane of the vertical cross-sectional view of FIG. 36A.

FIG. 36C is a vertical cross-sectional view of the second exemplary structure along the vertical plane C-C′ of FIG. 36B.

FIG. 37 is a vertical cross-sectional view of the second exemplary structure after formation of additional metal interconnect structures and memory-side bonding pads according to the second embodiment of the present disclosure.

FIG. 38 is a vertical cross-sectional view of the second exemplary structure after attaching a logic die to a memory die, removal of the carrier substrate, the sacrificial pillar structures, and end portions of the memory films according to the second embodiment of present disclosure.

FIG. 39 is a vertical cross-sectional view of the second exemplary structure after formation and patterning of a source layer and a dielectric cover layer, and formation of a backside dielectric layer and backside bonding pads according to the second embodiment of the present disclosure.

FIG. 40 is a vertical cross-sectional view of the third exemplary structure after formation of inter-tier memory openings according to the third embodiment of the present disclosure.

FIG. 41A is a vertical cross-sectional view of the third exemplary structure after formation of memory opening fill structures according to the third embodiment of the present disclosure.

FIG. 41B is a top-down view of the third exemplary structure of FIG. 41A. The vertical plane A-A′ is the cut plane of the vertical cross-sectional view of FIG. 41A.

FIG. 41C is a vertical cross-sectional view of the third exemplary structure along the vertical plane C-C′ of FIG. 41B.

FIG. 42 is a vertical cross-sectional view of the third exemplary structure after formation of backside trenches according to the third embodiment of the present disclosure.

FIG. 43 is a top-down view of the third exemplary structure of FIG. 42. The vertical plane A-A′ is the cut plane of the vertical cross-sectional view of FIG. 42.

FIG. 44 is a vertical cross-sectional view of the third exemplary structure after formation of backside recesses according to the third embodiment of the present disclosure.

FIG. 45 is a vertical cross-sectional view of the third exemplary structure after formation of electrically conductive layers according to the third embodiment of the present disclosure.

FIG. 46 is a vertical cross-sectional view of the third exemplary structure after formation of backside trench fill structures according to the third embodiment of the present disclosure.

FIG. 47A is a vertical cross-sectional view of the third exemplary structure after formation of conductive via structures and contact via structures according to the third embodiment of the present disclosure.

FIG. 47B is a top-down view of the third exemplary structure of FIG. 47A. The vertical plane A-A′ is the cut plane of the vertical cross-sectional view of FIG. 47A.

FIG. 47C is a vertical cross-sectional view of the third exemplary structure along the vertical plane C-C′ of FIG. 47B.

FIG. 48A is a vertical cross-sectional view of the third exemplary structure after formation of connection via structures according to the third embodiment of the present disclosure.

FIG. 48B is a top-down view of the third exemplary structure of FIG. 48A. The vertical plane A-A′ is the cut plane of the vertical cross-sectional view of FIG. 48A.

FIG. 49A is a vertical cross-sectional view of the third exemplary structure after formation of first-level metal lines including bit lines according to the third embodiment of the present disclosure.

FIG. 49B is a top-down view of the third exemplary structure of FIG. 49A. The vertical plane A-A′ is the cut plane of the vertical cross-sectional view of FIG. 49A.

FIG. 49C is a vertical cross-sectional view of the third exemplary structure along the vertical plane C-C′ of FIG. 49B.

FIG. 50 is a vertical cross-sectional view of the third exemplary structure after formation of additional metal interconnect structures and memory-side bonding pads according to the third embodiment of the present disclosure.

FIG. 51 is a vertical cross-sectional view of the third exemplary structure after formation of a cut trench according to the third embodiment of the present disclosure.

FIG. 52 is a vertical cross-sectional view of the third exemplary structure after formation of a dielectric trench fill structure according to the third embodiment of the present disclosure.

FIG. 53 is a vertical cross-sectional view of the third exemplary structure after attaching a logic die to a memory die according to the third embodiment of the present disclosure.

FIG. 54 is a vertical cross-sectional view of the third exemplary structure after removal of the carrier substrate, the sacrificial pillar structures, and end portions of the memory films according to the third embodiment of present disclosure.

FIG. 55 is a vertical cross-sectional view of the third exemplary structure after formation and patterning of a source layer and a dielectric cover layer and formation of a backside dielectric layer and backside bonding pads according to the third embodiment of the present disclosure.

### DETAILED DESCRIPTION

As discussed above, the present disclosure is directed to a bonded three-dimensional memory device containing temporary electrical grounding paths for electrically grounding metal interconnect structures during processing steps and methods of making the same, the various aspects of which are described below. Embodiments of the disclosure can be employed to form various structures including a multilevel memory structure, non-limiting examples of which include three-dimensional memory array devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁷ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

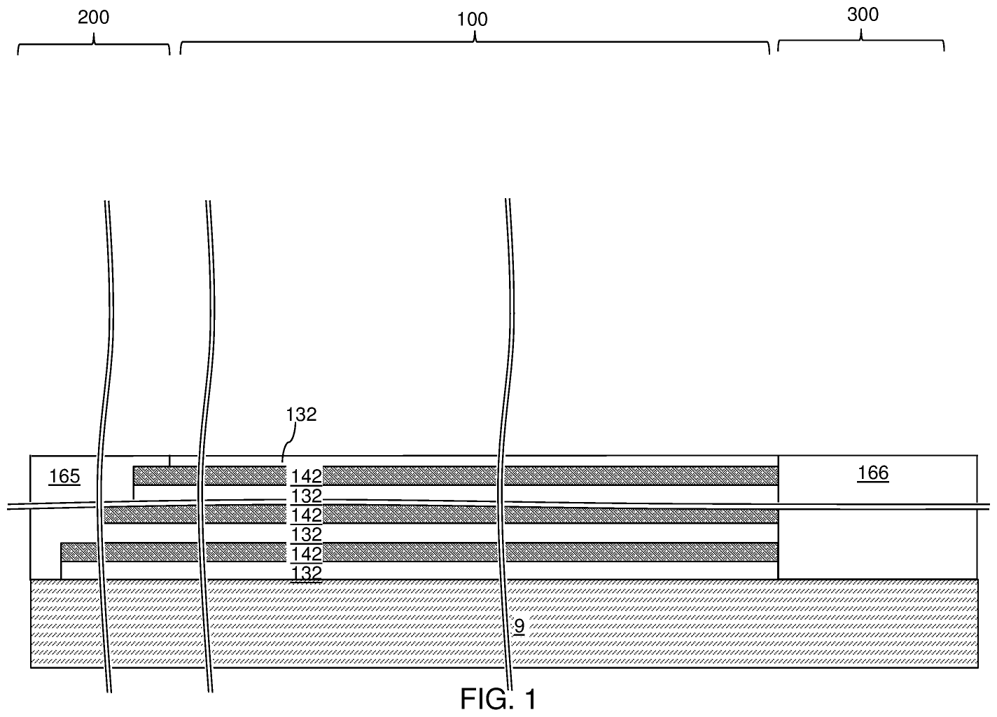

Referring to FIG. 1, a first exemplary structure according to a first embodiment of the present disclosure is illustrated. The first exemplary structure comprises a carrier substrate 9, which may be a semiconductor substrate or a conductive substrate. For example, the carrier substrate 9 may comprise a commercially available silicon wafer.

A first alternating stack of first insulating layers 132 and first spacer material layers can be formed over the carrier substrate 9. In one embodiment, the first spacer material layers may comprise first sacrificial material layers 142. In this case, a first alternating stack (132, 142) of first insulating layers 132 and first sacrificial material layers 142 can be formed over the carrier substrate 9. The first insulating layers 132 comprise an insulating material such as undoped silicate glass or a doped silicate glass, and the first sacrificial material layers 142 comprise a sacrificial material such as silicon nitride or a silicon-germanium alloy. The first alternating stack (132, 142) may comprise multiple repetitions of a unit layer stack including a first insulating layer 132 and a first sacrificial material layer 142. The total number of repetitions of the unit layer stack within the first alternating stack (132, 142) may be, for example, in a range from 8 to 1,024, such as from 32 to 256, although lesser and greater number of repetitions may also be employed.

Each of the first insulating layers 132 other than the topmost first insulating layer 132 may have a thickness in a range from 20 nm to 100 nm, such as from 30 nm to 60 nm, although lesser and greater thicknesses may also be employed. Each of the first sacrificial material layers 142 may have a thickness in a range from 20 nm to 100 nm, such as from 30 nm to 60 nm, although lesser and greater thicknesses may also be employed. In one embodiment, the topmost first insulating layer 132 may have a thickness of about one half of the thickness of other first insulating layers 132.

While an embodiment is described in which the first spacer material layers are formed as first sacrificial material layers 142, in an alternative embodiment, the first spacer material layers may be formed as first electrically conductive layers. Generally, the spacer material layers may be formed as, or may be subsequently replaced at least partly with, electrically conductive layers.

In one embodiment, first stepped surfaces may be formed in a staircase (i.e., contact) region 200 by patterning one side of the first alternating stack (132, 142). Another side of the first alternating stack (132, 142) in a peripheral region 300 may optionally be removed to provide a straight sidewall that extends from a bottommost surface to a topmost surface of the first alternating stack (132, 142). Alternatively, dummy stepped surfaces may be formed in the peripheral region 300. The remaining portion of the first alternating stack (132, 142) is located in a memory array region 100. A dielectric fill material such as undoped silicate glass or a doped silicate glass can be deposited over the first alternating stack (132, 142), and excess portions of the dielectric fill material may be removed from above the horizontal plane including the top surface of the topmost first insulating layer 132 by a planarization process, which may employ a chemical mechanical polishing process and/or a recess etch process. A first retro-stepped dielectric material portion 165 may be formed over the first stepped surfaces in the staircase region 200. A first field dielectric material portion 166 may be formed in peripheral region 300 over a top surface of the carrier substrate 9 adjacent to sidewall(s) of the first alternating stack (132, 142). The first retro-stepped dielectric material portion 165 and the first field dielectric material portion 166 are herein collectively referred to as first dielectric material portions (165, 166).

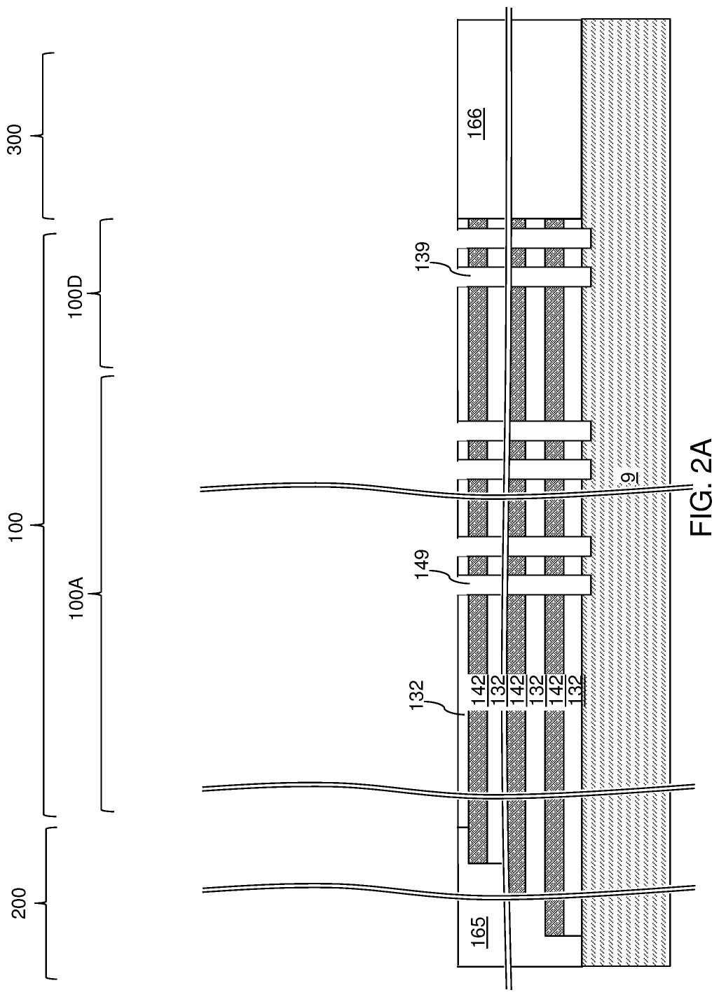

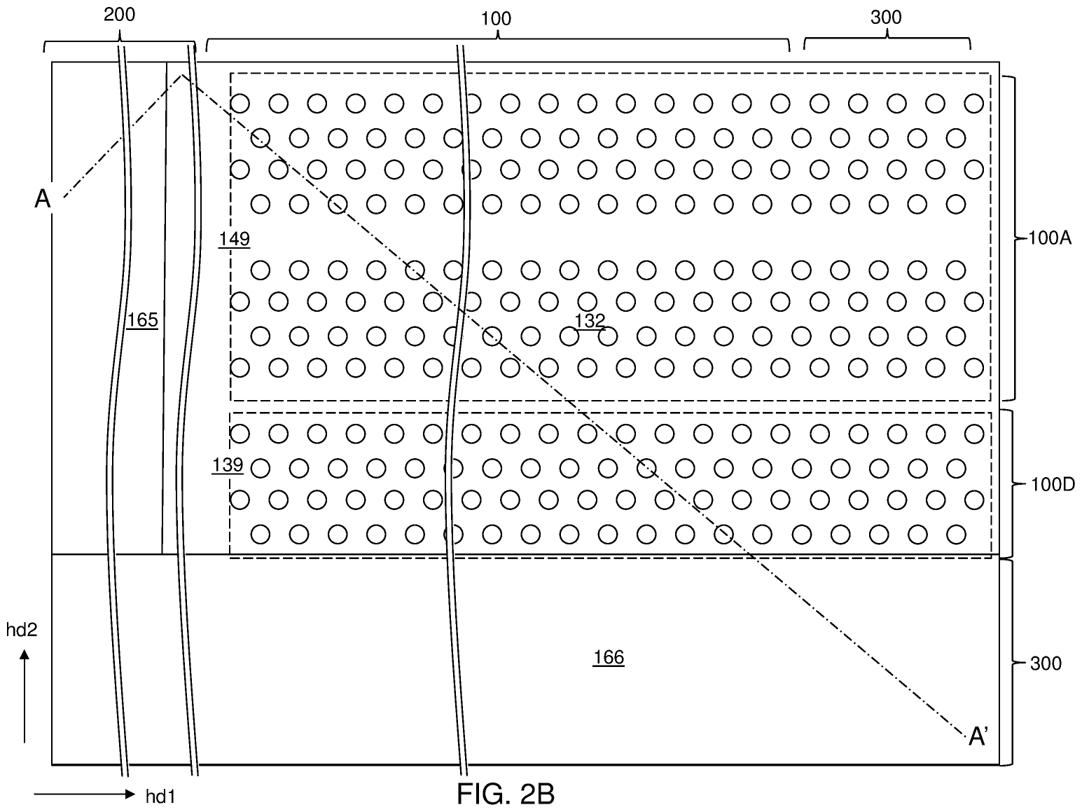

Referring to FIGS. 2A and 2B, an etch mask layer (not shown) can be formed over the first alternating stack (132, 142), and can be lithographically patterned to form various openings therein. An anisotropic etch process can be performed to transfer the pattern of the openings in the etch mask layer through the first alternating stack (132, 142). First-tier openings (149, 139) can be formed through the first alternating stack (132, 142). The first-tier openings (149, 139) may comprise first-tier memory openings 149 through each layer within the first alternating stack (132, 142), first-tier connection opening 139 that are formed through the first alternating stack (132, 142), and additional first-tier openings such as first-tier support openings (not illustrated) that are formed in the staircase region 200 and subsequently employed to form support pillar structures. In one embodiment, the first-tier memory openings 149 may be formed in rows that laterally extend along a first horizontal direction hd1. The rows of first-tier memory openings 149 may be arranged along a second horizontal direction hd1 that is perpendicular to the first horizontal direction hd1.

The first-tier memory openings 149 may be located in an active memory block area 100A of the memory array region 100. Active memory blocks are used to store data during operation of the memory device. The first-tier connection openings 139 may be formed between the first-tier memory openings 149 and the first field dielectric material portion 166. The first-tier connection openings 139 may be located in a dummy memory block area 100D of the memory array region 100. Dummy memory blocks are not used to store data during operation of the memory device. The etch mask layer can be subsequently removed.

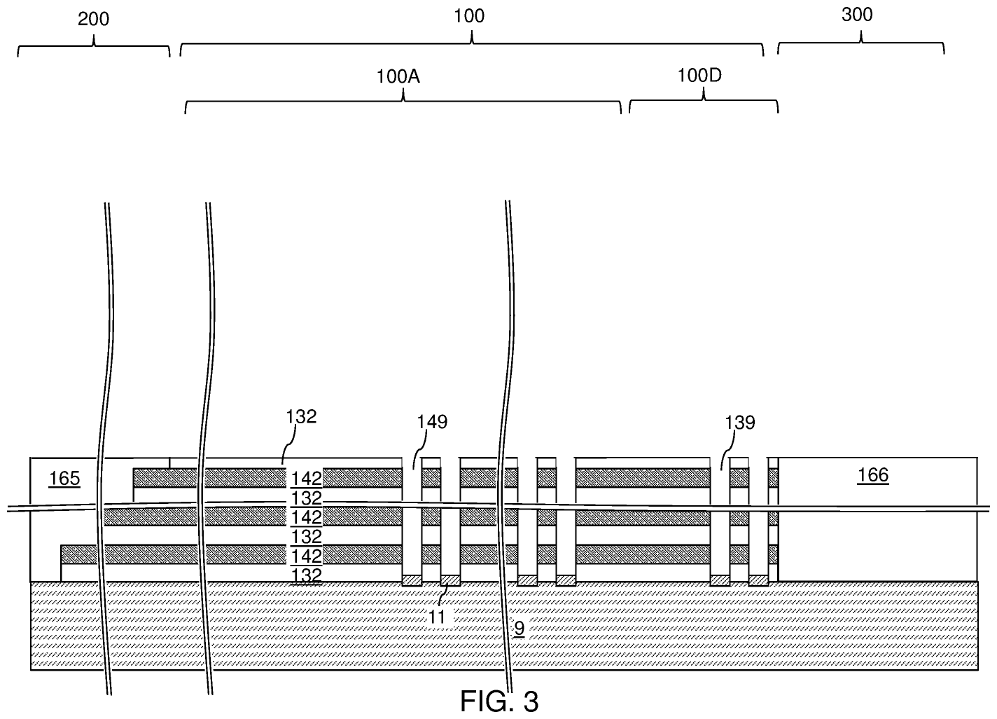

Referring to FIG. 3, sacrificial pillar structures 11 can be formed at the bottom of each of the first-tier openings (149, 139). The sacrificial pillar structures 11 may comprise a sacrificial material that can conduct electricity and that can be subsequently removed. Thus, the sacrificial pillar structures 11 comprise a doped semiconducting material or a conductive material, such as single crystal silicon, polysilicon, etc. For example, the sacrificial pillar structures 11 can comprise a semiconductor (e.g., silicon) material, and can be formed by selective growth of the semiconductor material from physically exposed surfaces of the carrier substrate 9.

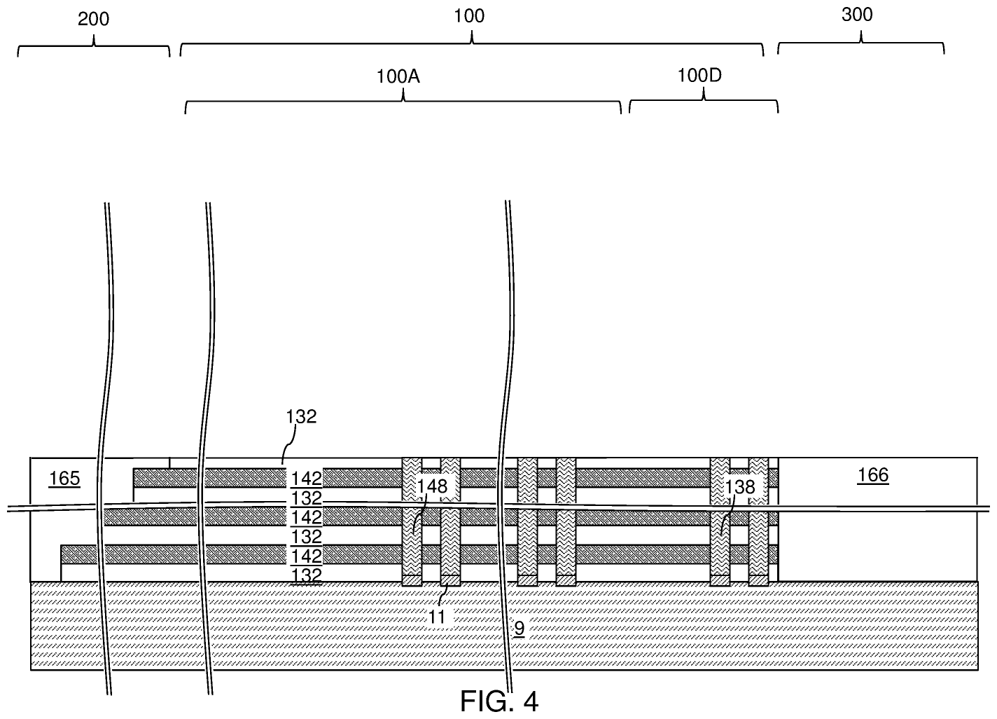

Referring to FIG. 4, a first sacrificial fill material may be deposited in the remaining unfilled volumes of the first-tier openings (149, 139). Excess portions of the first sacrificial fill material can be removed from above the horizontal plane including the top surface of the topmost first insulating layer 132 by performing a planarization process. Each remaining portion of the first sacrificial fill material constitutes a first-tier sacrificial opening fill structure (148, 138). The first-tier sacrificial opening fill structure (148, 138) comprises first-tier sacrificial memory opening fill structures 148 that are formed in the first-tier memory openings 149, and first-tier sacrificial connection opening fill structures 138 that are formed in the first-tier connection openings 139. The first sacrificial fill material may comprise carbon (e.g., amorphous carbon or diamond-like carbon), a semiconductor material (e.g., amorphous silicon), organosilicate glass, a polymer material, or any other material that can be subsequently removed selective to materials of the first alternating stack (132, 142) and the sacrificial pillar structures 11.

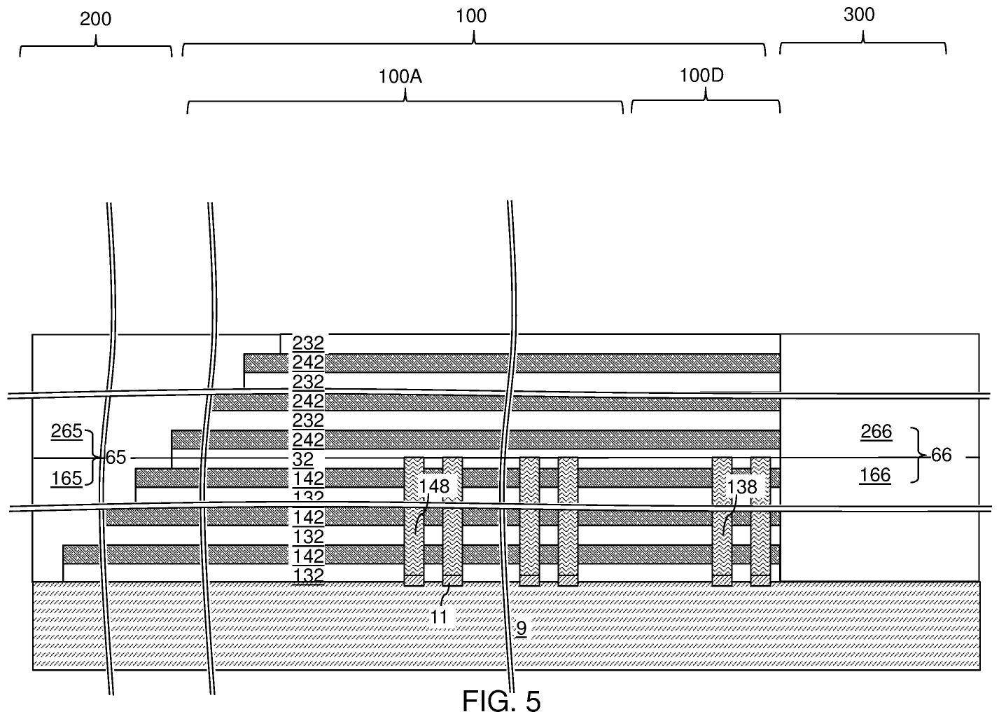

Referring to FIG. 5, a second alternating stack (232, 242) of second insulating layers 232 and second sacrificial material layers 242 can be formed over the first alternating stack (132, 232). The second insulating layers 232 comprise an insulating material such as undoped silicate glass or a doped silicate glass, and the second sacrificial material layers 242 comprise a sacrificial material such as silicon nitride or a silicon-germanium alloy. The second alternating stack (232, 242) may comprise multiple repetitions of a unit layer stack including a second insulating layer 232 and a second sacrificial material layer 242. The total number of repetitions of the unit layer stack within the second alternating stack (232, 242) may be, for example, in a range from 8 to 2,024, such as from 32 to 256, although lesser and greater number of repetitions may also be employed. Each of the second insulating layers 232 other than the bottommost second insulating layer 232 may have a thickness in a range from 20 nm to 200 nm, such as from 30 nm to 60 nm, although lesser and greater thicknesses may also be employed. Each of the second sacrificial material layers 242 may have a thickness in a range from 20 nm to 200 nm, such as from 30 nm to 60 nm, although lesser and greater thicknesses may also be employed. In one embodiment, the bottommost second insulating layer 232 may have a thickness of about one half of the thickness of other second insulating layers 232.

Second stepped surfaces may be formed in the staircase region 200 by patterning a side of the second alternating stack (232, 242) that is adjacent to the first stepped surfaces. Another side of the second alternating stack (232, 242) may optionally be removed in the peripheral region 300 to provide a straight sidewall that extends from a bottommost surface to a topmost surface of the second alternating stack (232, 242). Alternatively, dummy stepped surfaces may be formed on the side of the second alternating stack that faces the peripheral region 300. A dielectric fill material such as undoped silicate glass or a doped silicate glass can be deposited over the second alternating stack (232, 242), and excess portions of the dielectric fill material may be removed from above the horizontal plane including the top surface of the topmost second insulating layer 232 by a planarization process, which may employ a chemical mechanical polishing process and/or a recess etch process. A second retro-stepped dielectric material portion 265 may be formed over the second stepped surfaces in the staircase region 200. A second field dielectric material portion 266 may be formed over a top surface of the carrier substrate 9 adjacent to a sidewall of the second alternating stack (232, 242) in the peripheral region 300. The second retro-stepped dielectric material portion 265 and the second field dielectric material portion 266 are herein collectively referred to as second dielectric material portions (265, 266).

Each of the first insulating layers 132 other than the topmost first insulating layer 132 may have a thickness in a range from 20 nm to 100 nm, such as from 30 nm to 60 nm, although lesser and greater thicknesses may also be employed. Each of the first sacrificial material layers 142 may have a thickness in a range from 20 nm to 100 nm, such as from 30 nm to 60 nm, although lesser and greater thicknesses may also be employed. In one embodiment, the topmost first insulating layer 132 may have a thickness of about one half of the thickness of other first insulating layers 132.

While an embodiment is described in which the first spacer material layers are formed as first sacrificial material layers 142, in an alternative embodiment, the first spacer material layers may be formed as first electrically conductive layers. Generally, the spacer material layers may be formed as, or may be subsequently replaced at least partly with, electrically conductive layers.

In one embodiment, first stepped surfaces may be formed in a staircase (i.e., contact) region 200 by patterning one side of the first alternating stack (132, 142). Another side of the first alternating stack (132, 142) in a peripheral region 300 may optionally be removed to provide a straight sidewall that extends from a bottommost surface to a topmost surface of the first alternating stack (132, 142). Alternatively, dummy stepped surfaces may be formed in the peripheral region 300. The remaining portion of the first alternating stack (132, 142) is located in a memory array region 100. A dielectric fill material such as undoped silicate glass or a doped silicate glass can be deposited over the first alternating stack (132, 142), and excess portions of the dielectric fill material may be removed from above the horizontal plane including the top surface of the topmost first insulating layer 132 by a planarization process, which may employ a chemical mechanical polishing process and/or a recess etch process. A first retro-stepped dielectric material portion 165 may be formed over the first stepped surfaces in the staircase region 200. A first field dielectric material portion 166 may be formed in peripheral region 300 over a top surface of the carrier substrate 9 adjacent to sidewall(s) of the first alternating stack (132, 142). The first retro-stepped dielectric material portion 165 and the first field dielectric material portion 166 are herein collectively referred to as first dielectric material portions (165, 166).

Referring to FIGS. 2A and 2B, an etch mask layer (not shown) can be formed over the first alternating stack (132, 142), and can be lithographically patterned to form various openings therein. An anisotropic etch process can be performed to transfer the pattern of the openings in the etch mask layer through the first alternating stack (132, 142). First-tier openings (149, 139) can be formed through the first alternating stack (132, 142). The first-tier openings (149, 139) may comprise first-tier memory openings 149 through each layer within the first alternating stack (132, 142), first-tier connection opening 139 that are formed through the first alternating stack (132, 142), and additional first-tier openings such as first-tier support openings (not illustrated) that are formed in the staircase region 200 and subsequently employed to form support pillar structures. In one embodiment, the first-tier memory openings 149 may be formed in rows that laterally extend along a first horizontal direction hd1. The rows of first-tier memory openings 149 may be arranged along a second horizontal direction hd1 that is perpendicular to the first horizontal direction hd1.

The first-tier memory openings 149 may be located in an active memory block area 100A of the memory array region 100. Active memory blocks are used to store data during operation of the memory device. The first-tier connection openings 139 may be formed between the first-tier memory openings 149 and the first field dielectric material portion 166. The first-tier connection openings 139 may be located in a dummy memory block area 100D of the memory array region 100. Dummy memory blocks are not used to store data during operation of the memory device. The etch mask layer can be subsequently removed.

Referring to FIG. 3, sacrificial pillar structures 11 can be formed at the bottom of each of the first-tier openings (149, 139). The sacrificial pillar structures 11 may comprise a sacrificial material that can conduct electricity and that can be subsequently removed. Thus, the sacrificial pillar structures 11 comprise a doped semiconducting material or a conductive material, such as single crystal silicon, polysilicon, etc. For example, the sacrificial pillar structures 11 can comprise a semiconductor (e.g., silicon) material, and can be formed by selective growth of the semiconductor material from physically exposed surfaces of the carrier substrate 9.

Referring to FIG. 4, a first sacrificial fill material may be deposited in the remaining unfilled volumes of the first-tier openings (149, 139). Excess portions of the first sacrificial fill material can be removed from above the horizontal plane including the top surface of the topmost first insulating layer 132 by performing a planarization process. Each remaining portion of the first sacrificial fill material constitutes a first-tier sacrificial opening fill structure (148, 138). The first-tier sacrificial opening fill structure (148, 138) comprises first-tier sacrificial memory opening fill structures 148 that are formed in the first-tier memory openings 149, and first-tier sacrificial connection opening fill structures 138 that are formed in the first-tier connection openings 139. The first sacrificial fill material may comprise carbon (e.g., amorphous carbon or diamond-like carbon), a semiconductor material (e.g., amorphous silicon), organosilicate glass, a polymer material, or any other material that can be subsequently removed selective to materials of the first alternating stack (132, 142) and the sacrificial pillar structures 11.

Referring to FIG. 5, a second alternating stack (232, 242) of second insulating layers 232 and second sacrificial material layers 242 can be formed over the first alternating stack (132, 232). The second insulating layers 232 comprise an insulating material such as undoped silicate glass or a doped silicate glass, and the second sacrificial material layers 242 comprise a sacrificial material such as silicon nitride or a silicon-germanium alloy. The second alternating stack (232, 242) may comprise multiple repetitions of a unit layer stack including a second insulating layer 232 and a second sacrificial material layer 242. The total number of repetitions of the unit layer stack within the second alternating stack (232, 242) may be, for example, in a range from 8 to 2,024, such as from 32 to 256, although lesser and greater number of repetitions may also be employed.

Each of the second insulating layers 232 other than the bottommost second insulating layer 232 may have a thickness in a range from 20 nm to 200 nm, such as from 30 nm to 60 nm, although lesser and greater thicknesses may also be employed. Each of the second sacrificial material layers 242 may have a thickness in a range from 20 nm to 200 nm, such as from 30 nm to 60 nm, although lesser and greater thicknesses may also be employed. In one embodiment, the bottommost second insulating layer 232 may have a thickness of about one half of the thickness of other second insulating layers 232.

Second stepped surfaces may be formed in the staircase region 200 by patterning a side of the second alternating stack (232, 242) that is adjacent to the first stepped surfaces. Another side of the second alternating stack (232, 242) may optionally be removed in the peripheral region 300 to provide a straight sidewall that extends from a bottommost surface to a topmost surface of the second alternating stack (232, 242). Alternatively, dummy stepped surfaces may be formed on the side of the second alternating stack that faces the peripheral region 300. A dielectric fill material such as undoped silicate glass or a doped silicate glass can be deposited over the second alternating stack (232, 242), and excess portions of the dielectric fill material may be removed from above the horizontal plane including the top surface of the topmost second insulating layer 232 by a planarization process, which may employ a chemical mechanical polishing process and/or a recess etch process. A second retro-stepped dielectric material portion 265 may be formed over the second stepped surfaces in the staircase region 200. A second field dielectric material portion 266 may be formed over a top surface of the carrier substrate 9 adjacent to a sidewall of the second alternating stack (232, 242) in the peripheral region 300. The second retro-stepped dielectric material portion 265 and the second field dielectric material portion 266 are herein collectively referred to as second dielectric material portions (265, 266).

The first retro-stepped dielectric material portion 165 and the second retro-stepped dielectric material portion 265 are hereafter collectively referred to as a retro-stepped dielectric material portion 65. The first field dielectric material portion 166 and the second field dielectric material portion 266 are hereafter collectively referred to as a field dielectric material portion 66. The retro-stepped dielectric material portion 65 and the field dielectric material portion 66 are collectively referred to a dielectric material portions (65, 66).

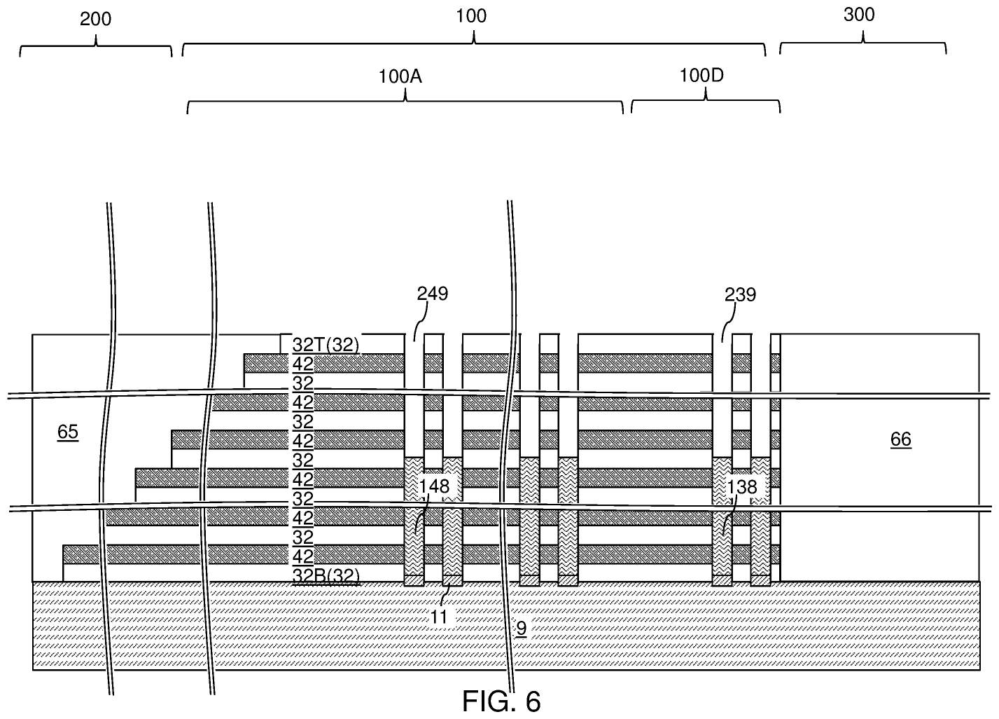

Referring to FIG. 6, an etch mask layer (not shown) can be formed over the second alternating stack (232, 242), and can be lithographically patterned to form various openings therein. An anisotropic etch process can be performed to transfer the pattern of the openings in the etch mask layer through the second alternating stack (232, 242). Second-tier openings (249, 239) can be formed through the second alternating stack (232, 242). The second-tier openings (249, 239) may comprise second-tier memory openings 249 through each layer within the second alternating stack (232, 242), second-tier connection opening 239 that are formed through the second alternating stack (232, 242), and additional second-tier openings such as second-tier support openings (not illustrated) located in the staircase region 200 that are subsequently employed to form support pillar structures. Each of the second-tier memory openings 249 can be formed directly above a respective one of the first-tier sacrificial memory opening fill structures 148 in the active memory block area 100A. Each of the second-tier connection openings 239 can be formed directly above a respective one of the first-tier sacrificial connection opening fill structures 138 in the dummy memory block area 100D. The etch mask layer can be subsequently removed.

The first insulating layers 132 and the second insulating layers 232 are hereafter collectively referred to as insulating layers 32. The topmost one of the insulating layers 32 is hereafter referred to as a topmost insulating layer 32T. The first sacrificial material layers 142 and the second sacrificial material layers 242 are hereafter collectively referred to as second sacrificial material layers 42.

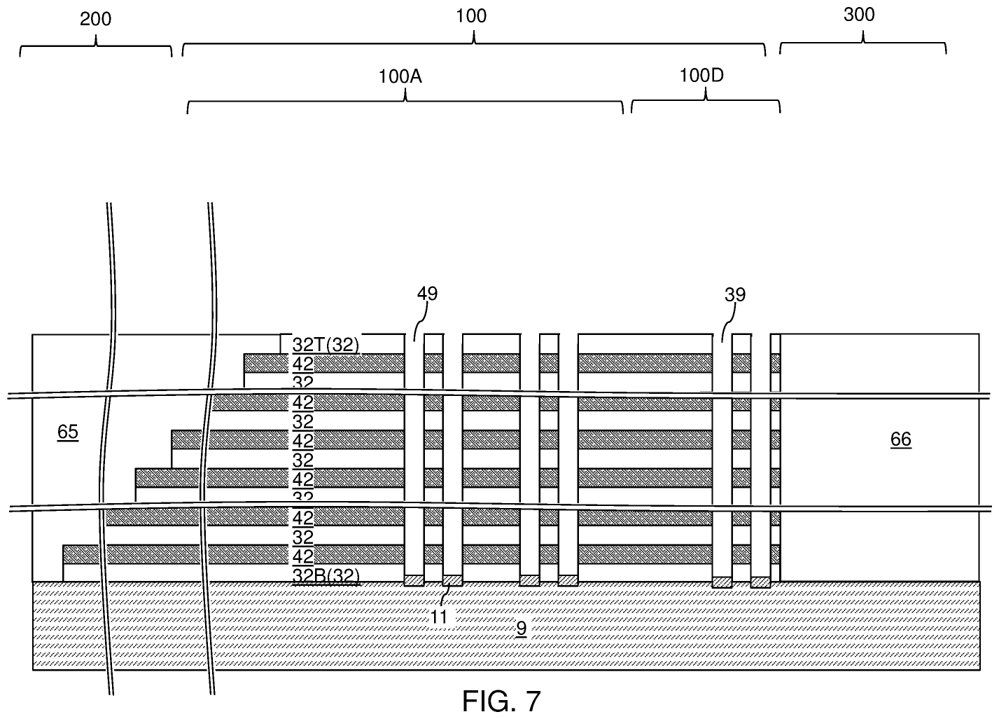

Referring to FIG. 7, the first-tier sacrificial memory opening fill structures 148 and the first-tier sacrificial connection opening fill structures 138 are selectively removed by ashing (for carbon sacrificial material) or selective etching (for other sacrificial material) to expose the first-tier memory openings 149 and the first-tier connection opening 139. A combined volume of each combination of a first-tier memory opening 149 and an overlying second-tier memory opening 249 comprises a memory opening 49. The memory openings 49 located in the active memory block area 100A are also referred to as inter-tier memory openings. A combined volume of each combination of a first-tier connection opening 139 and an overlying second-tier connection opening 239 comprises a connection opening 39. The connection openings 39 are located in the dummy memory block area 100D.

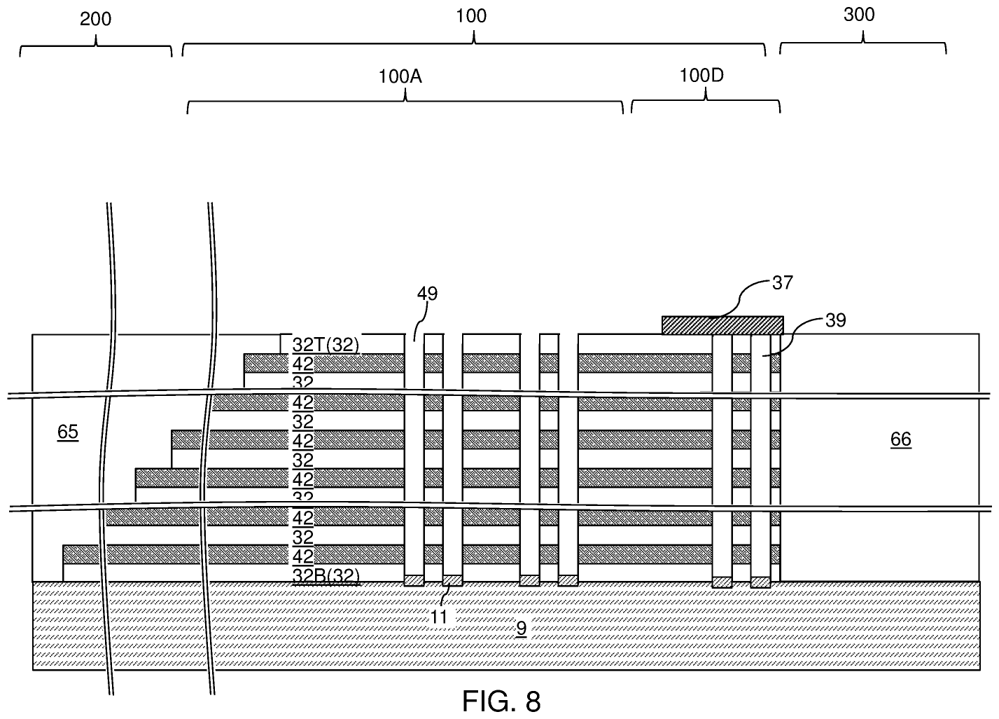

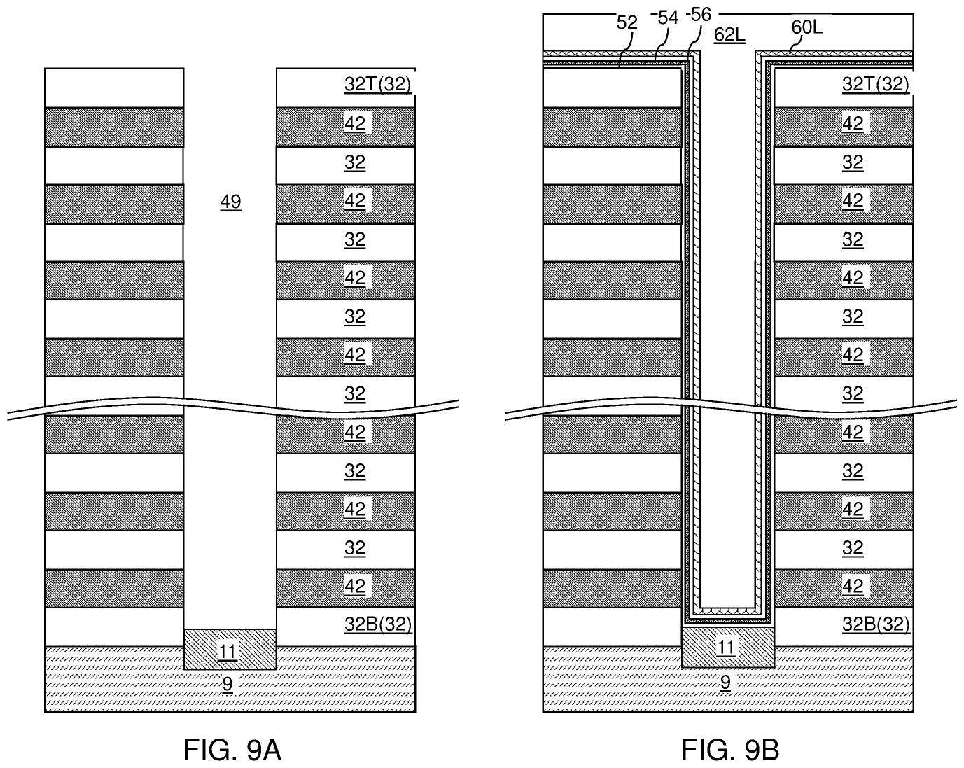

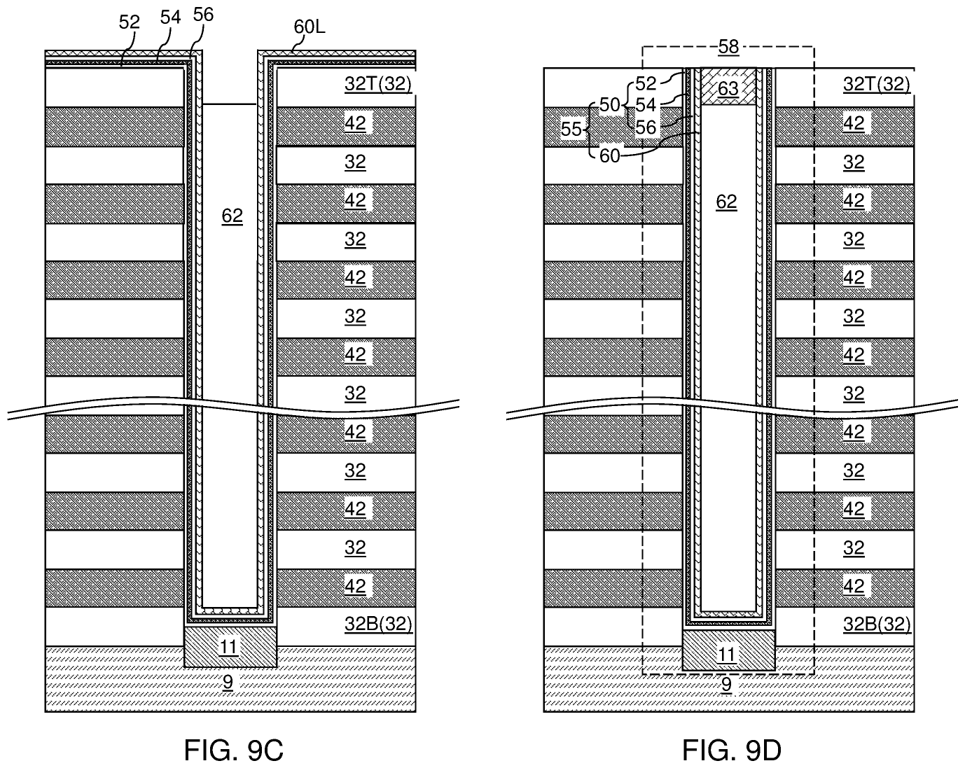

Referring to FIGS. 8 and 9A, a hard mask 37 is formed over the alternating stack (32, 42) in the dummy memory block area 100D. The hard mask 37 may comprise any suitable hard mask material, such as silicon oxide, silicon nitride, silicon oxynitride, amorphous silicon, polysilicon, etc. The hard mask 37 may be formed by a non-conformal deposition of the hard mask material layer over the alternating stack (32, 42) followed by forming a photoresist layer over the hard mask material layer. The photoresist layer is patterned by photolithography and then used as an etch mask to etch the hard mask material layer to form the hard mask 37. The photoresist layer is then removed by ashing or another suitable method.

Referring to FIG. 9B, a layer stack including a memory material layer 54 can be conformally deposited in the memory openings 49 and over the hard mask 37 and the topmost insulating layer 32T. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprise a charge storage material, the optional dielectric liner 56 may comprise a tunneling dielectric layer.

A semiconductor channel material layer 60L can be deposited by a conformal deposition process over the layer stack (52, 54, 56) in the memory openings 49 and over the hard mask 37 and the topmost insulating layer 32T. If the semiconductor channel material layer 60L is doped, the semiconductor channel material layer 60L may have a doping of a first conductivity type, which may be p-type or n-type. A dielectric core layer 62L comprising a dielectric fill material can be deposited in remaining volumes of the memory openings 49.

Referring to FIG. 9C, the dielectric core layer 62L can be vertically recessed such that each remaining portion of the dielectric core layer 62L has a top surface at, or about, the horizontal plane including the bottom surface of the topmost insulating layers 32T. Each remaining portion of the dielectric core layer 62L constitutes a dielectric core 62.

Referring to FIG. 9D, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type, a horizontal portion of the semiconductor channel layer 60L and the horizontal portion of the layer stack (52, 54, 56) are removed from above the horizontal plane including the top surface of the topmost insulating layer 32T for example, by chemical mechanical planarization (CMP) or a recess etch process. During the CMP or recess etch, the hard mask 37 is also removed from above the topmost insulating layer 32T. Each remaining portion of the doped semiconductor material having a doping of the second conductivity type constitutes a drain region 63. Each remaining portion of the semiconductor channel layer 60L (which has a doping of the first conductivity type) constitutes a vertical semiconductor channel 60. Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56.

Each contiguous combination of a memory film 50 and a vertical semiconductor channel 60 constitutes a memory stack structure 55. Each combination of a sacrificial pillar structure 11 (if present), a memory stack structure 55, a dielectric core 62, and a drain region 63 within a memory opening 49 constitutes a memory opening fill structure 58. Each memory opening fill structure 58 comprises a respective vertical stack of memory elements, which may be embodied as portions of the memory material layer 54 located at levels of the sacrificial material layers 42, or generally speaking, at levels of spacer material layers that may be formed as, or may be subsequently replaced at least partly with, electrically conductive layers.

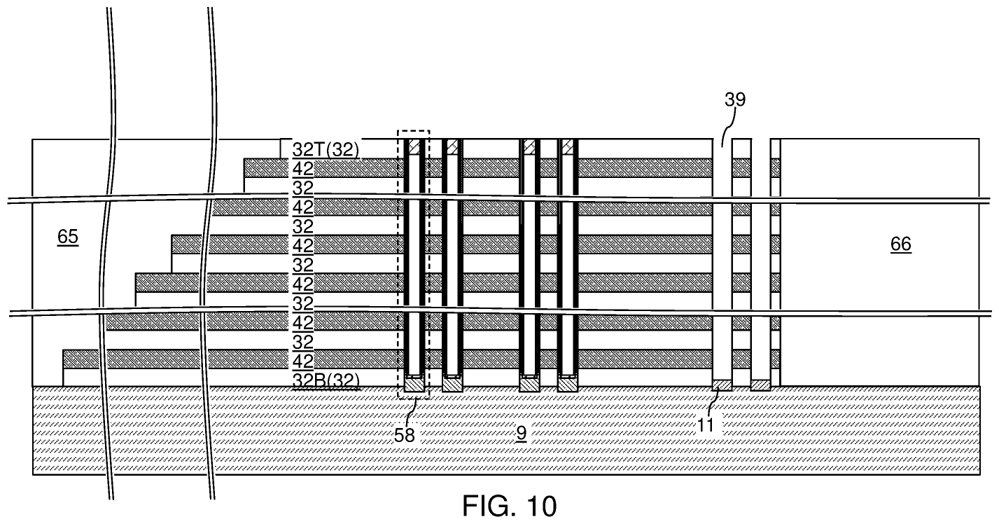

Referring to FIG. 10, the first exemplary structure is illustrated after formation of memory opening fill structures 58 within the memory openings 49 and the concurrent removal of the hard mask 37. Optionally, support pillar structures (not shown) may be formed through the alternating stack (32, 42) in the staircase region 200 concurrently with formation of the memory opening fill structures 58 such that each of the support pillar structures has a substantially same structure as a memory opening fill structure 58. Alternatively or additionally, dielectric support pillar structures may be formed in support openings through the alternating stack (32, 42) prior to or after formation of the memory opening fill structures 58.

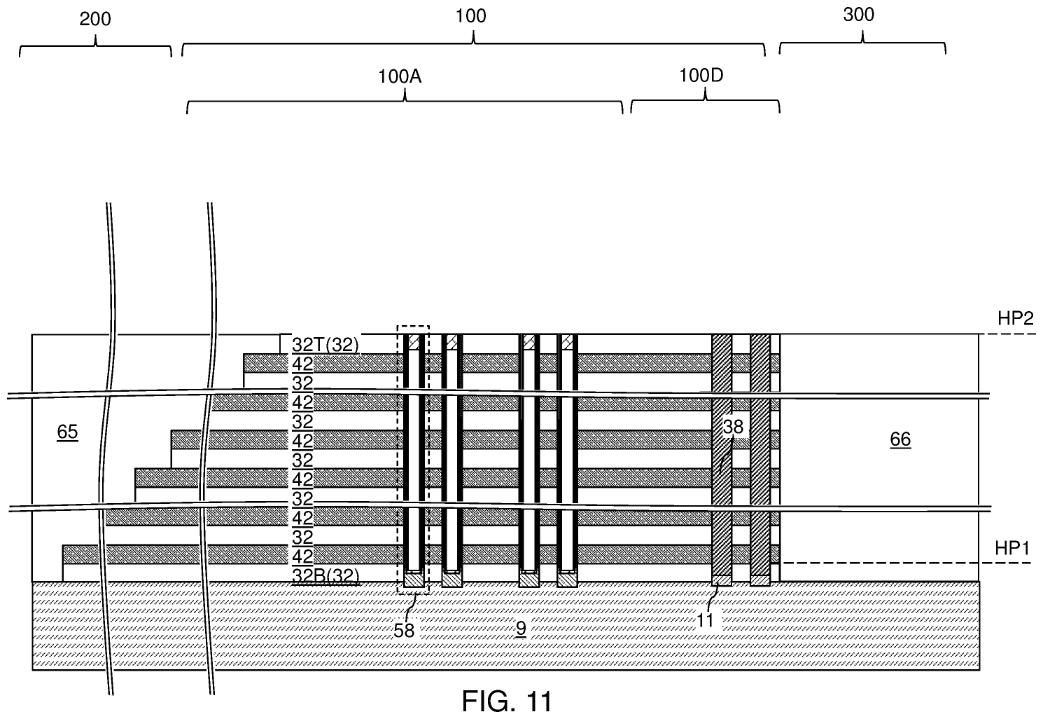

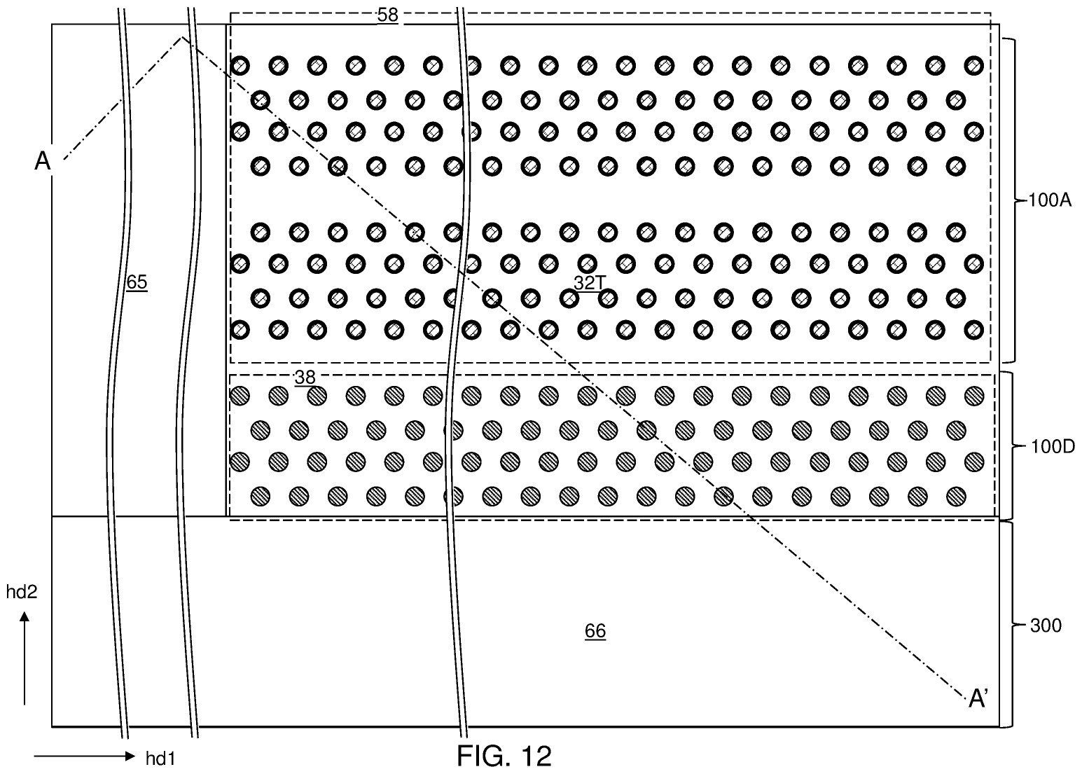

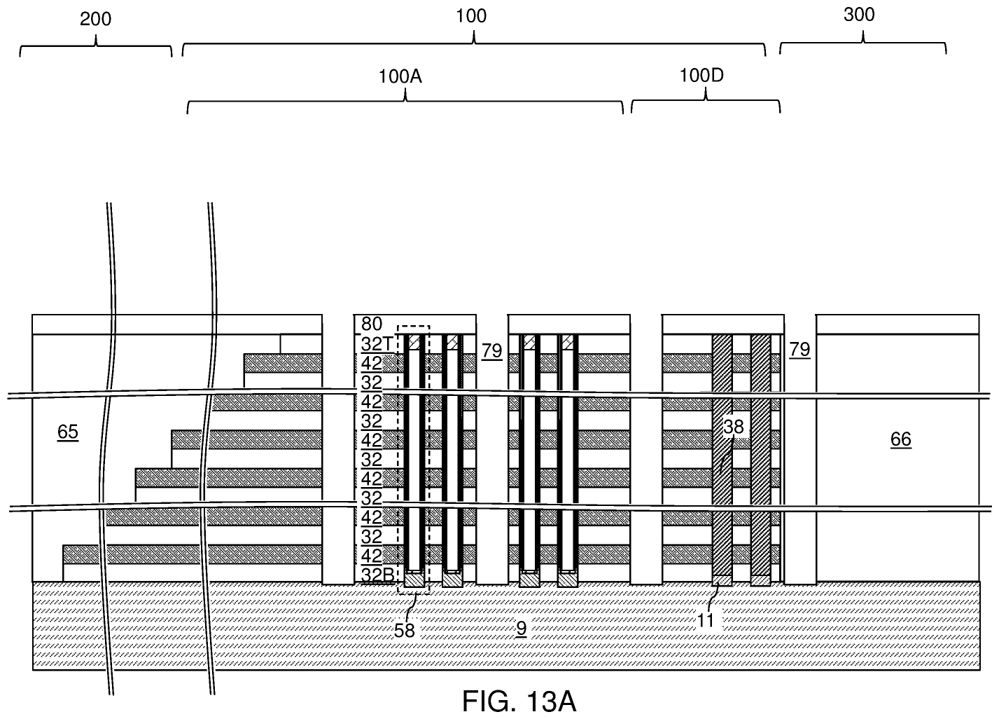

Referring to FIGS. 11 and 12, a conductive fill material can be deposited in the connection openings 39. In one embodiment, the conductive fill material may be a material that forms a dielectric oxide material upon oxidation. In an illustrative example, the conductive fill material may comprise a heavily doped semiconductor material, such as heavily doped silicon or a heavily doped silicon-germanium material. For example, the conductive fill material may comprise p-type (e.g., boron doped) polysilicon having a p-type dopant (e.g., boron) concentration of at least 1.0×10¹⁹/cm³, such as 5.0×10¹⁹/cm³ to 2.0×10²¹/cm³. In one embodiment, the conductive fill material may comprise polysilicon having electrical conductivity greater than 1.0×10⁵ S/m, or amorphous silicon that may be subsequently converted into polysilicon having electrical conductivity greater than 1.0×10⁵ S/m after a suitable thermal anneal process. Excess portions of the conductive fill material may be removed from above the horizontal plane including the topmost surface of the alternating stack (32, 42) by a planarization process, which may comprise a chemical mechanical polishing process and/or a recess etch process. Each remaining portion of the conductive fill material that fills a respective connection opening 39 constitutes a conductive via structure 38. Each conductive via structure 38 may be formed directly on a respective sacrificial pillar structure 11. Alternatively, in case the sacrificial pillar structures 11 are omitted, each conductive via structure 38 may be formed directly on the carrier substrate 9, which comprises a semiconductor material or a conductive material.

In one embodiment, each conductive via structure 38 vertically extends through and is laterally surrounded by each spacer material layer (such as each sacrificial material layer 42) within the alternating stack (32, 42). In one embodiment, each conductive via structure 38 vertically extends at least from a first horizontal plane HP1 including a top surface of a bottommost insulating layer 32B within the alternating stack (32, 42) to a second horizontal plane HP2 including a top surface of a topmost insulating layer 32T within the alternating stack (32, 42). In one embodiment, the conductive via structures 38 comprise a doped semiconductor material.

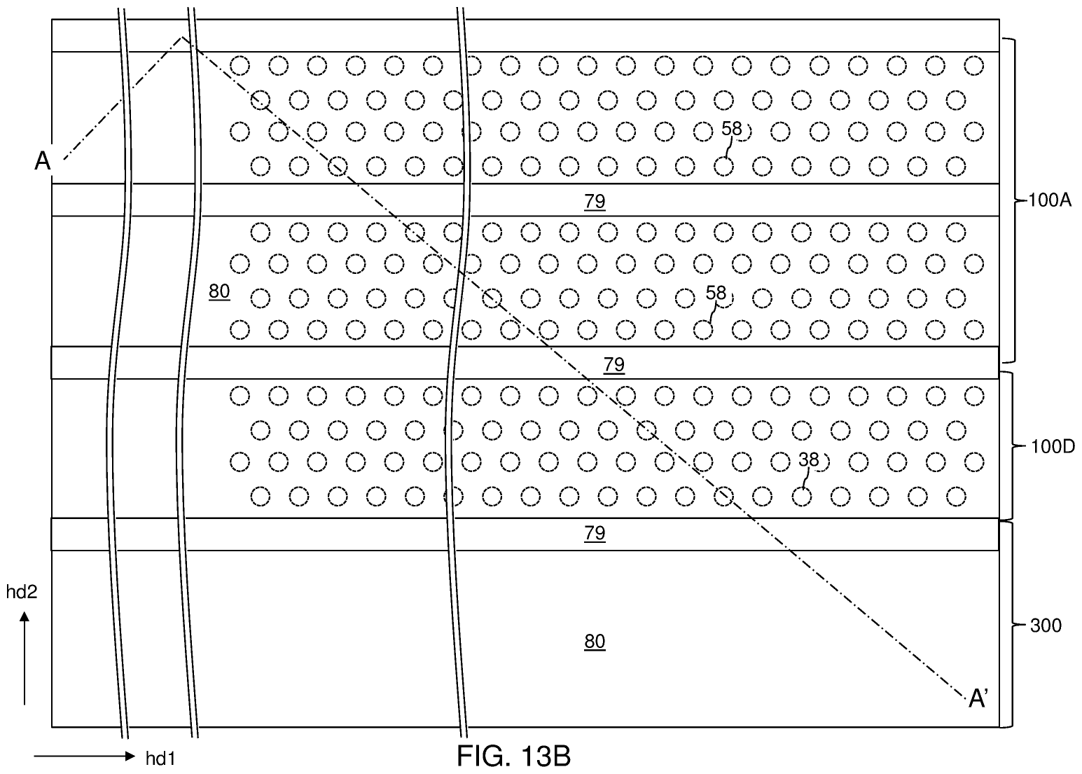

Referring to FIGS. 13A and 13B, a contact-level dielectric layer 80 can be formed over the alternating stack (32, 42). A photoresist layer (not shown) can be applied over the contact-level dielectric layer 80, and can be lithographically patterned to form elongated openings that laterally extend along the first horizontal direction (e.g., word line direction) hd1 between neighboring clusters of memory opening fill structures 58 in the and between the conductive via structures 38 and the memory opening fill structures 58. An anisotropic etch process can be performed to transfer the pattern of the openings in the photoresist layer through the contact-level dielectric layer 80, the alternating stack (32, 42), and the dielectric material portions (65, 66). Backside trenches 79 laterally extending along the first horizontal direction hd1 can be formed through the alternating stack (32, 42), the dielectric material portions (65, 66), and the contact-level dielectric layer 80. Each of the backside trenches 79 may comprise a respective pair of lengthwise sidewalls that are parallel to the first horizontal direction hd1 and vertically extend from the carrier substrate 9 to the top surface of the contact-level dielectric layer 80. A top surface of the carrier substrate 9 can be physically exposed underneath each backside trench 79. The photoresist layer can be subsequently removed, for example, by ashing.

As shown in FIG. 13B, plural active memory blocks are formed in the active memory block area 100A. Each active memory block is located between the adjacent pairs of the backside trenches 79. Furthermore, a backside trench 79 separates the active memory block area 100A from the dummy memory block area 100D. The dummy memory block area 100D may contain one or more than one dummy memory blocks. While one dummy memory block is shown in the embodiment of FIG. 13B, in alternative embodiments, two or more dummy memory blocks may be located in the dummy memory block area 100D. In the alternative embodiments, one or more backside trenches 79 extends through the dummy memory block area 100D to separate adjacent dummy memory blocks.

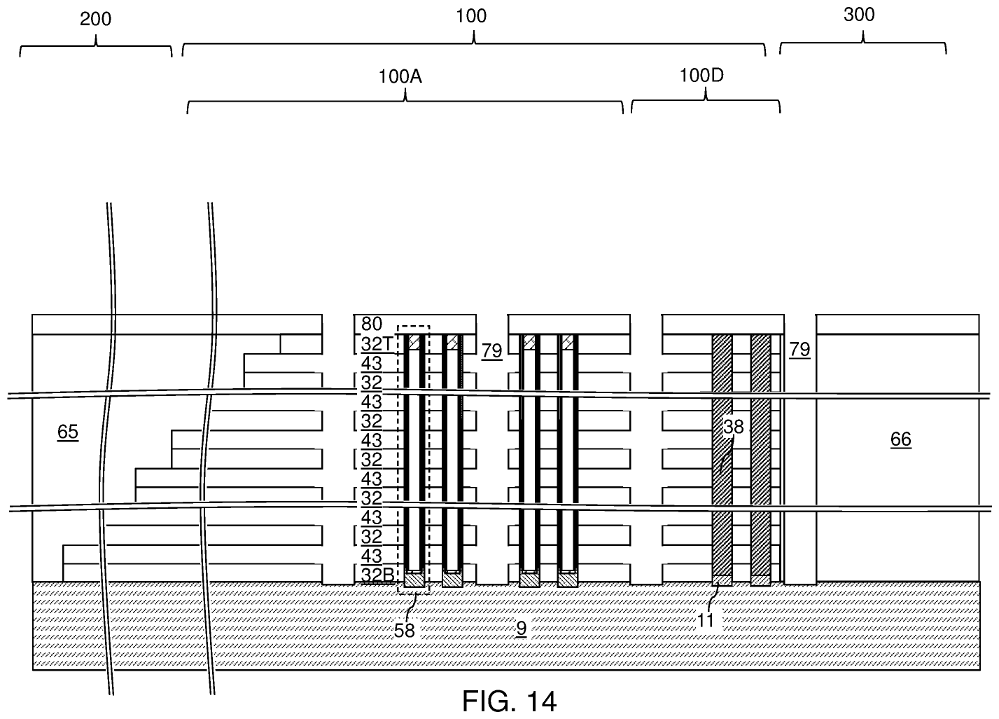

Referring to FIG. 14, an isotropic etch process can be performed to remove the sacrificial material layers 42 selective to the insulating layers 32, the memory opening fill structures 58, the conductive via structures 38, and the carrier substrate 9. The etching liquid or gas is provided into the backside trenches 79 to selectively remove the sacrificial material layers 42. Backside recesses 43 can be formed in volumes from which the sacrificial material layers 42 are removed. Sidewall surface segments of the memory opening fill structures 58 and the conductive via structures 38 can be physically exposed to the backside recesses 43. In an illustrative example, if the sacrificial material layers 42 comprise silicon nitride, then the isotropic etch process may comprise a wet etch process employing hot phosphoric acid.

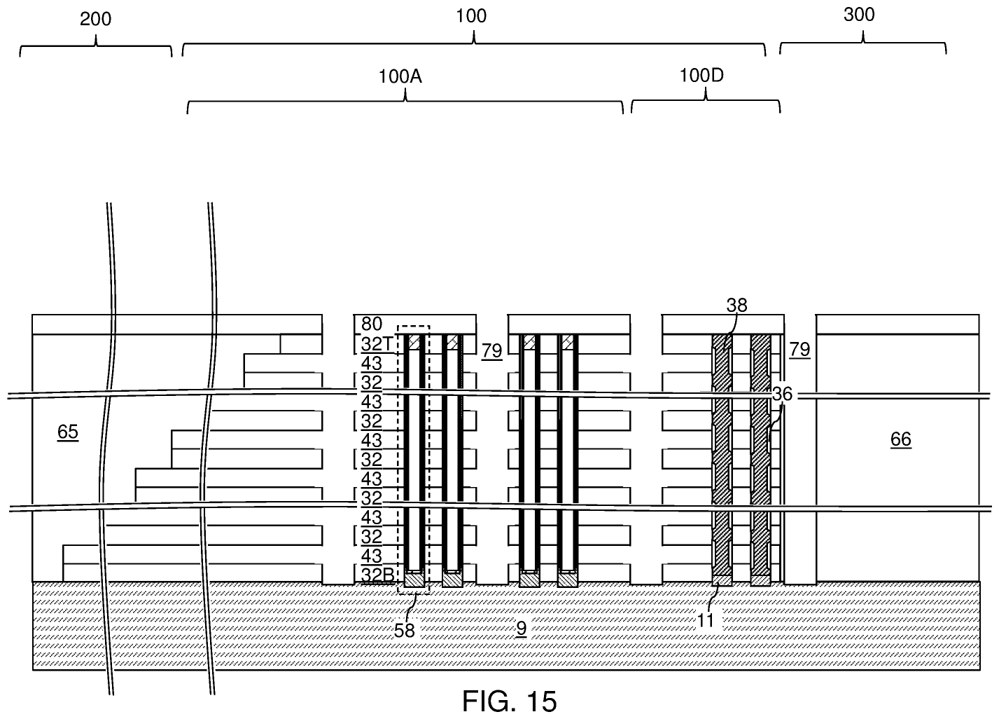

Referring to FIG. 15, an oxidation process can be performed to convert surface portions of the conductive via structures 38 that are exposed to the backside recesses 43 into dielectric semiconductor oxide portions. Generally, a vertical stack of cylindrical dielectric semiconductor oxide portions 36 can be formed on each conducive via structure 38 by oxidizing surface portions of the conductive via structures 38. For example, exposed surfaces of silicon (e.g., polysilicon) conductive via structures 38 are converted to dielectric semiconductor oxide portions 36 which comprise silicon oxide sidewall spacers.

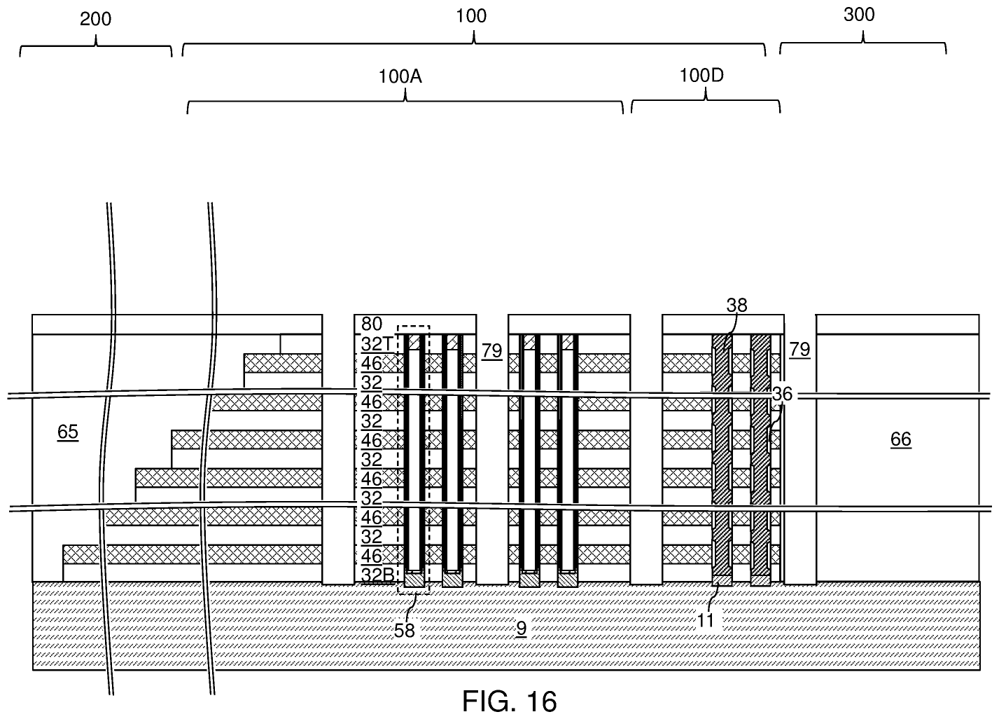

Referring to FIG. 16, a backside blocking dielectric layer (not shown) can be optionally formed in the backside recesses 43 by a conformal deposition process. The backside blocking dielectric layer may comprise aluminum oxide or silicon oxide, for example. At least one conductive material, such as at least one metallic material, can be conformally deposited in the backside recesses 43. The at least one conductive material may comprise, for example, a combination of a metallic barrier material and a metallic fill material. The metallic barrier material may comprise, for example, TiN, TaN, WN, MoN, TiC, TaC, WC, or a combination thereof. The metallic fill material may comprise, for example, Ti, Ta, Mo, Co, Ru, W, Cu, other transition metals, and/or alloys or layer stacks thereof. Excess portions of the at least one conductive material that are deposited in the backside trenches 79 or above the contact-level dielectric layer 80 can be removed by performing an etch-back process, which may comprise an isotropic etch process and/or an anisotropic etch process. Each remaining portion of the at least one conductive material filling a respective one of the backside recesses 43 constitutes an electrically conductive layer 46. An alternating stack of insulating layers 32 and electrically conductive layers 46 can be formed between each neighboring pair of backside trenches 79 over the carrier substate 9. Each vertical stack of cylindrical dielectric semiconductor oxide portions 36 laterally surrounds a respective conductive via structure 38. The cylindrical dielectric semiconductor oxide portions 36 is laterally surrounded by and is contacted by a respective set of electrically conductive layers 46. A plurality of alternating stacks of insulating layers 32 and electrically conductive layers 46 can be laterally spaced apart among one another by the backside trenches 79. The electrically conductive layers 46 comprise word lines and select gate electrodes.

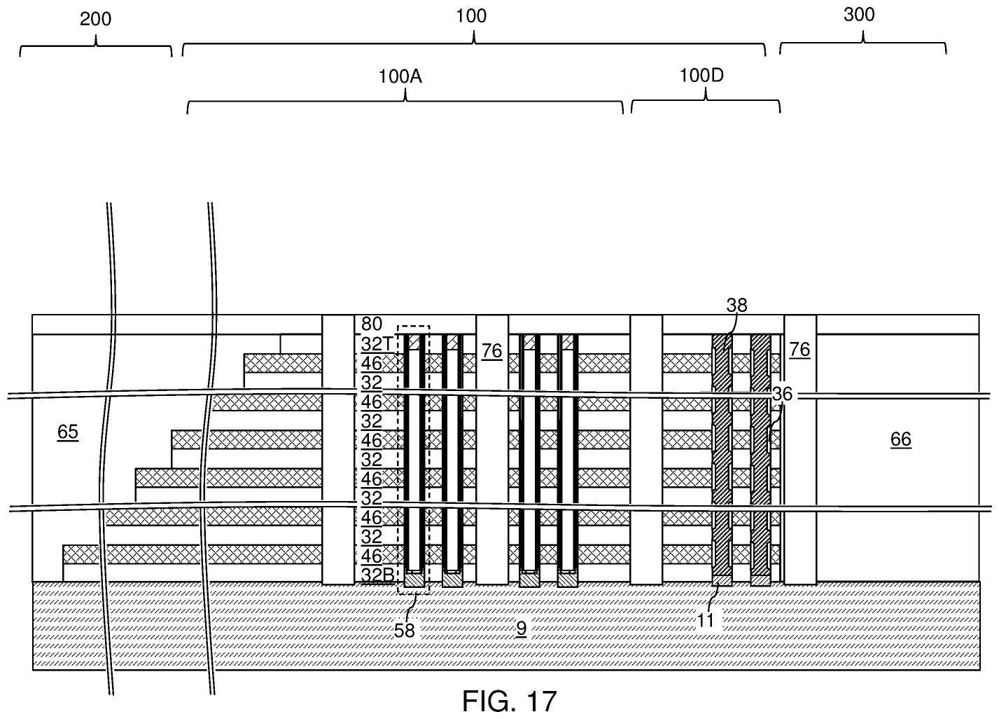

Referring to FIG. 17, at least one dielectric fill material, such as silicon oxide, can be deposited in the backside trenches 79 to form backside trench fill structures 76. Alternatively, one, a plurality or each of the backside trench fill structures 76 may comprise a combination of an insulating spacer and a backside contact via structure that is laterally surrounded by the insulating spacer.

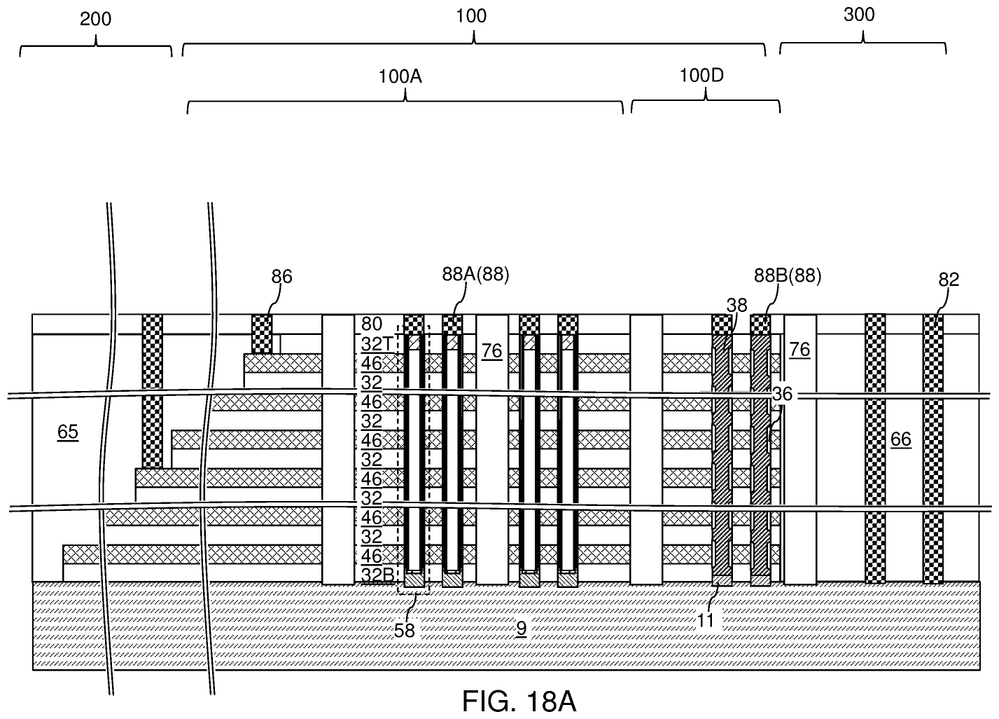

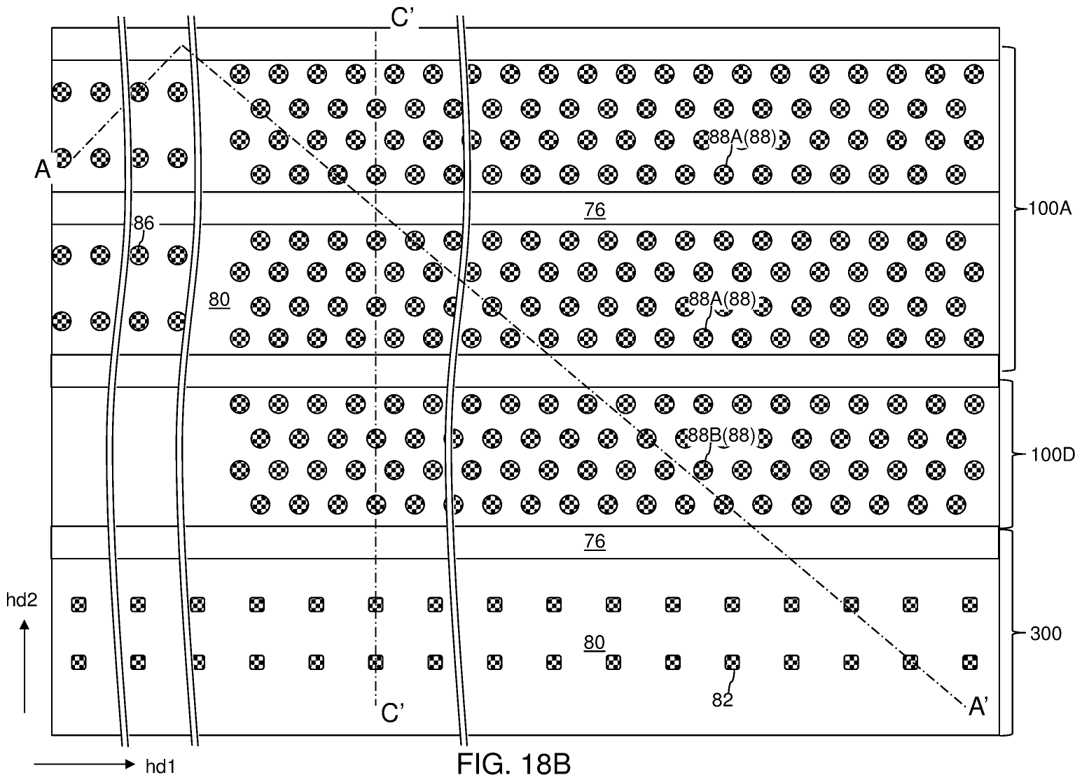

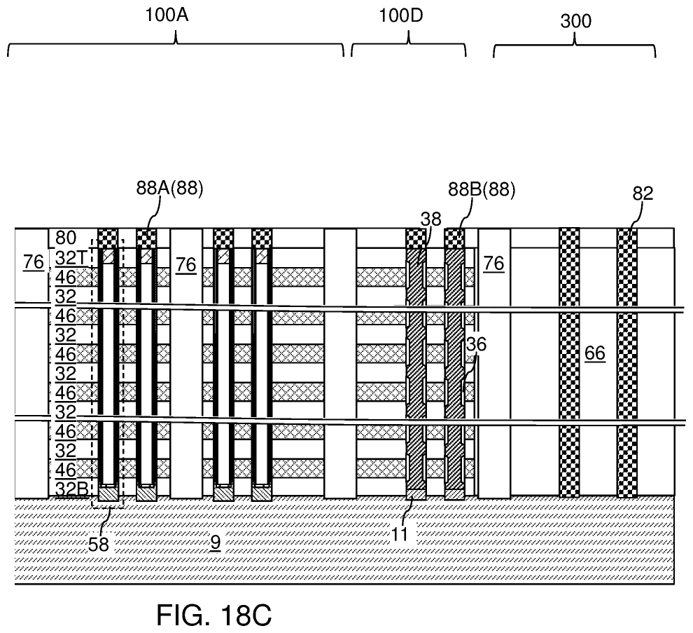

Referring to FIGS. 18A-18C, a photoresist layer (not shown) can be applied over the contact-level dielectric layer 80, and can be lithographically patterned to form openings therethrough. An anisotropic etch process can be performed to transfer the pattern of the openings in the photoresist layer through the contact-level dielectric layer 80 and optionally through the dielectric material portions (65, 66). Various contact via cavities can be formed through the contact-level dielectric layer 80 and the dielectric material portions (65, 66). The photoresist layer can be subsequently removed, for example, by ashing.

At least one conductive material, such as a combination of a metallic barrier material and a metallic fill material, can be deposited in the contact via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the various contact via cavities constitute various contact via structures (86, 88, 82). The various contact via structures (86, 88, 82) may comprise layer contact via structures (e.g., word line contact via structures) 86 vertically extending through the contact-level dielectric layer 80 and the retro-stepped dielectric material portion 65 and contacting a respective one of the electrically conductive layers 46, drain contact via structures 88A contacting a top surface of a respective one of the drain regions 63, discharge-path contact via structures 88B contacting a top surface of a respective one of the conductive via structures 38, and through-memory-level via structures 82 that vertically extend through the contact-level dielectric layer 80 and the field dielectric material portion 66 and contacting a top surface of the carrier substrate 9. The drain contact via structures 88A and the discharge-path contact via structures 88B may have the same height as the thickness of the contact-level dielectric layer 80, and are herein collectively referred to as through-contact-level via structures 88.

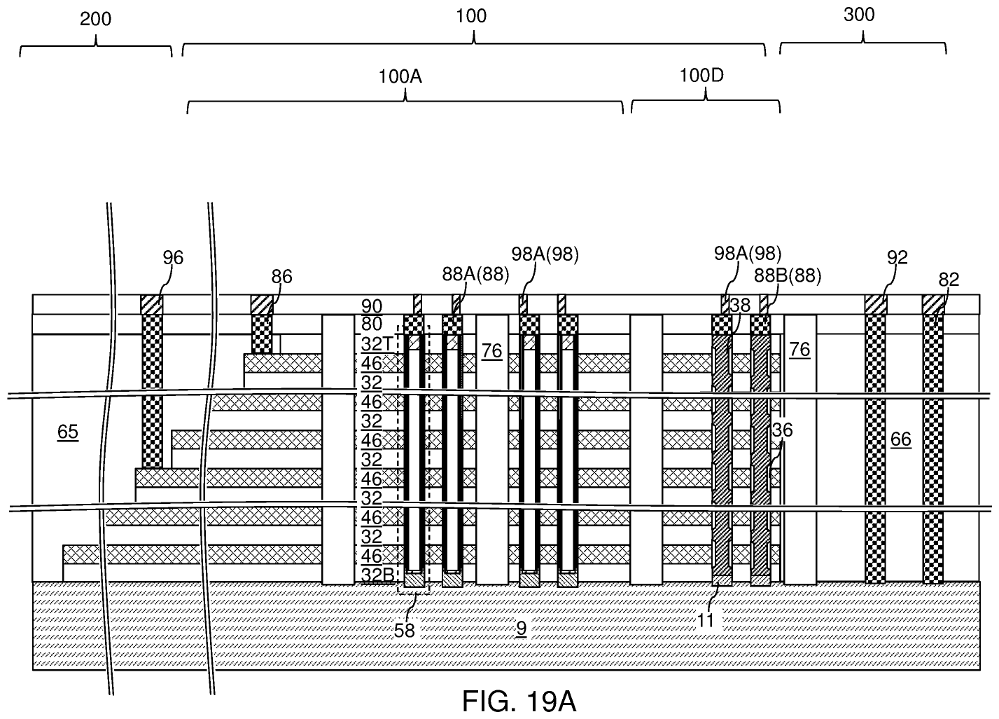

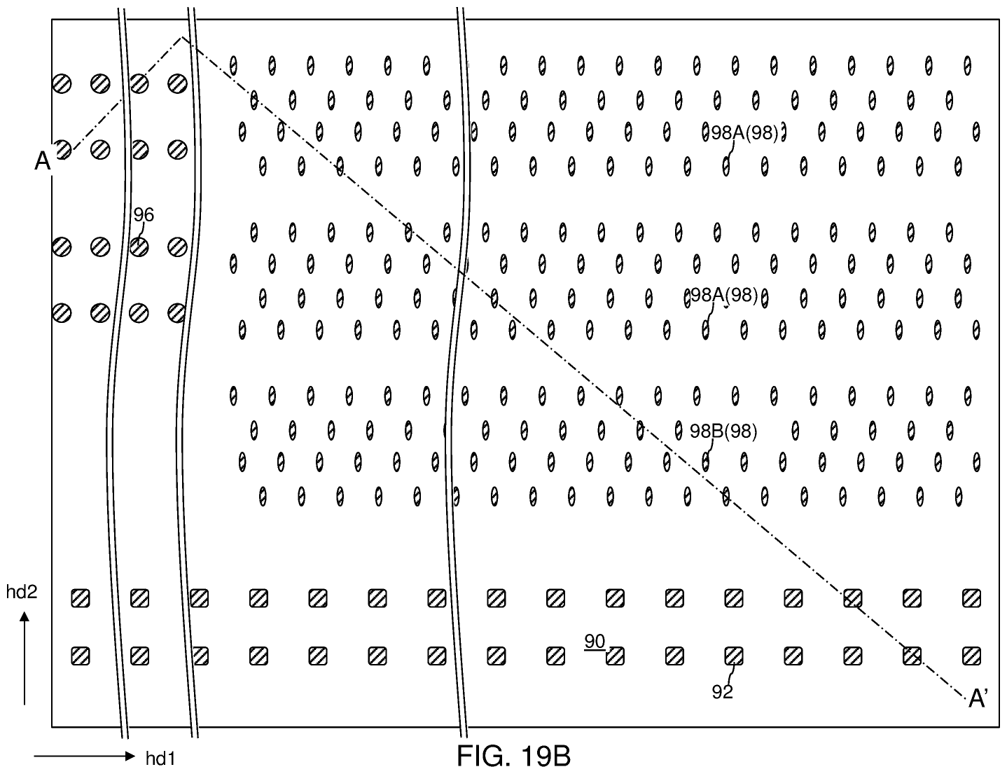

Referring to FIGS. 19A and 19B, a connection-level dielectric layer 90 can be formed over the contact-level dielectric layer 80 by deposition of a dielectric material such as silicon oxide. Connection via structures (98A, 98B, 96, 92) can be formed through the connection-level dielectric layer 90 on a respective one of the contact via structures (86, 88, 82). For example, bit-line-connection via structures 98A can be formed on the drain contact via structures 88A, discharge-path connection via structures 98B can be formed on the discharge-path contact via structures 88B, layer connection via structures 96 can be formed on the layer contact via structures 86, and peripheral connection via structures 92 that are formed on through-memory-level via structures 82. The bit-line-connection via structures 98A and the discharge-path connection via structures 98B are herein collectively referred to as array-connection via structures 98.

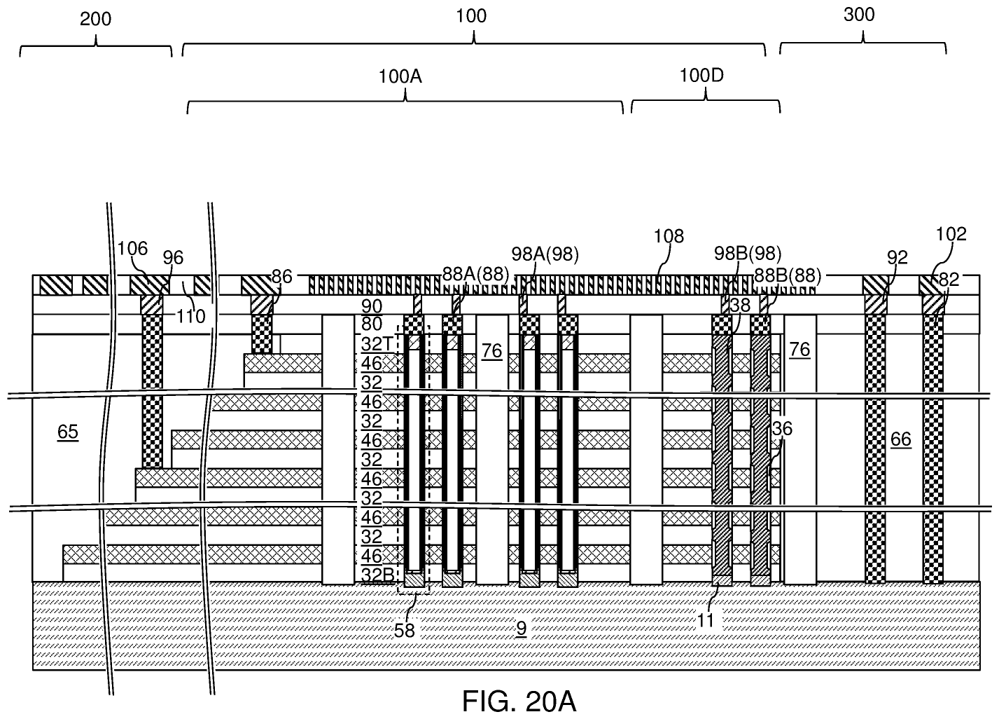

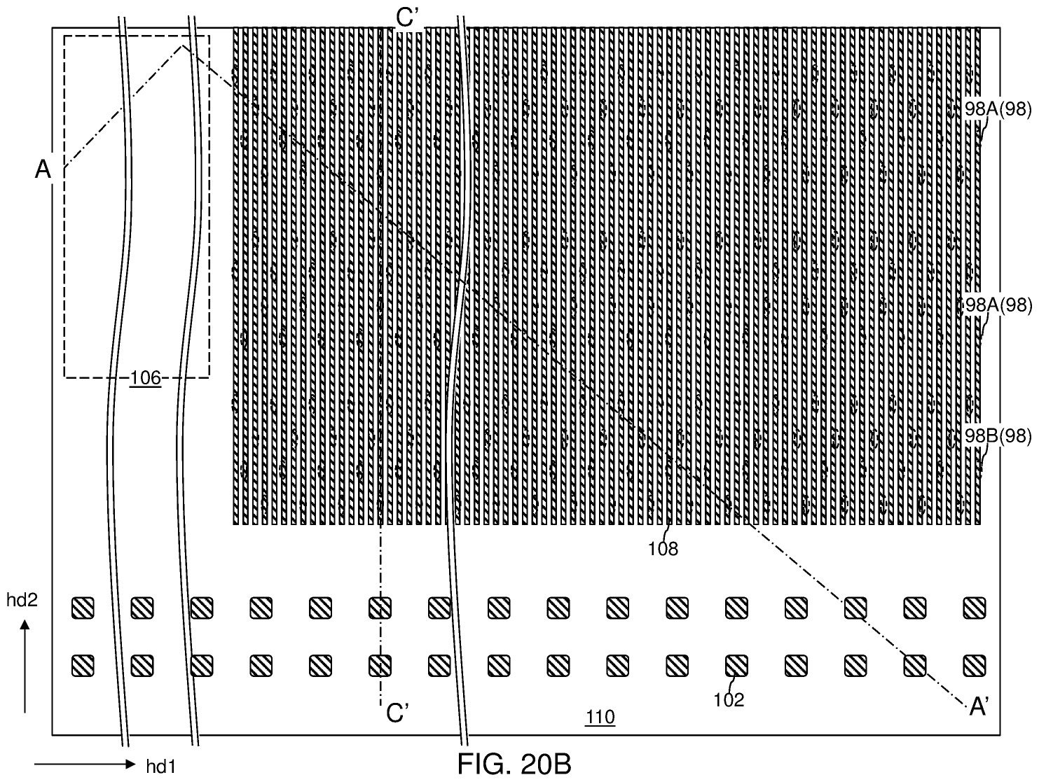

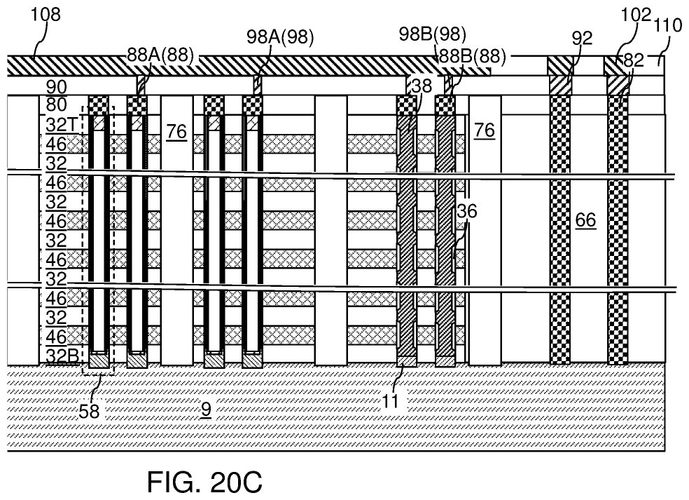

Referring to FIGS. 20A-20C, a line-level dielectric layer can be formed over the connection-level dielectric layer 90. The line-level dielectric layer is herein referred to as a bit-line-level dielectric layer 110 or a first-metal-line-level dielectric layer 110. First-level metal lines (108, 106, 102) can be formed in the bit-line-level dielectric layer 110. The first-level metal lines (108, 106, 102) may include bit lines 108, first word-line-connection metal lines 106, and first peripheral-connection metal lines 102. The bit lines 108 can be parallel to each other, and can laterally extend along the second horizontal direction (i.e., bit line direction) hd2 that is perpendicular to the lengthwise direction of the backside trench fill structures 76. For example, if the backside trench fill structures 76 laterally extend along the first horizontal direction hd1, then the bit lines 108 may laterally extend along the second horizontal direction hd2. In one embodiment, the bit lines 108 are laterally spaced from each other along the first horizontal direction hd1 with a first pitch and laterally extend along the second horizontal direction hd2.

Each bit line 108 can be electrically connected to a respective subset of the drain regions 63 through a respective subset of the drain contact via structures 88A and a respective subset of the bit-line-connection via structures 98A. According to an aspect of the present disclosure, each bit line 108 can be electrically connected to at least one conductive via structure 38 through at least one discharge-path contact via structure 88B and at least one discharge-path connection via structure 98B. The first word-line-connection metal lines 106 can be formed on the layer connection via structures 96. The first peripheral-connection metal lines 108 can be formed on the peripheral connection via structures 92.

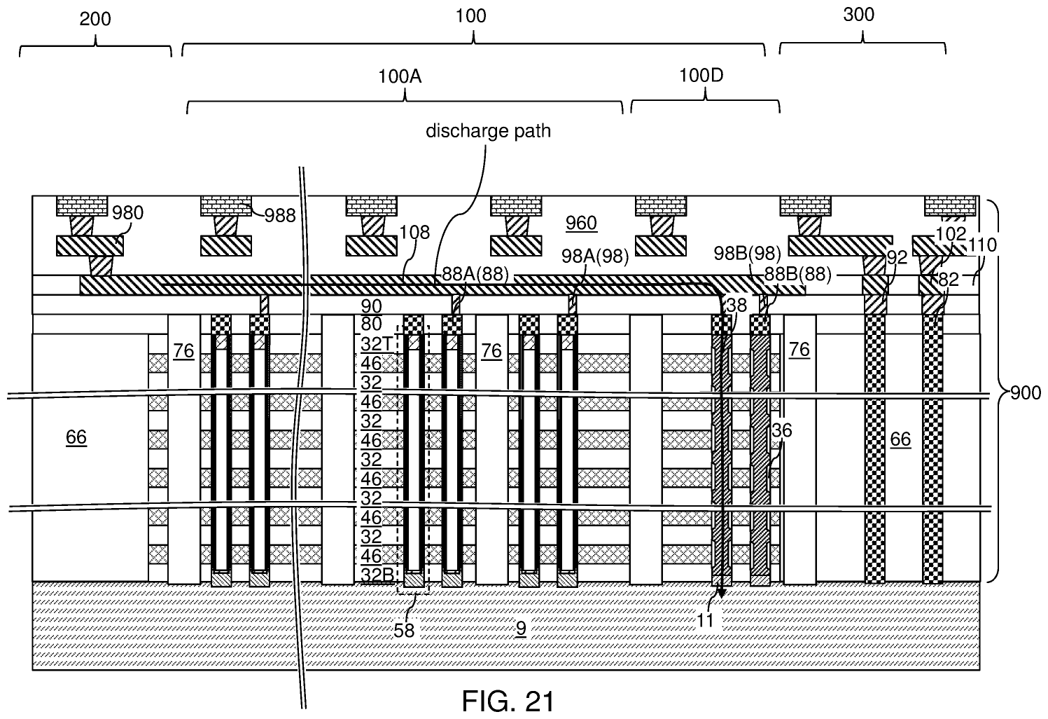

Referring to FIG. 21, additional dielectric material layers 960 and additional metal interconnect structures 980 can be formed over the bit-line-level dielectric layer 110. The additional dielectric material layers may include at least one via-level dielectric layer, at least one additional line-level dielectric layer, and/or at least one additional line-and-via-level dielectric layer. The additional metal interconnect structures 980 may comprise metal via structures, metal line structures, and/or integrated metal line-and-via structures. Metal bonding pads, which are herein referred to as memory-side bonding pads 988, may be formed at the topmost level of the additional dielectric material layers 960. The memory-side bonding pads 988 may be electrically connected to the additional metal interconnect structures 980 and various nodes of the three-dimensional memory array including the alternating stacks of insulating layers 32 and electrically conductive layers 46 and the memory opening fill structures 58.

The set of all metal interconnect structures formed in, or above, the contact-level dielectric layer 80 is herein referred to as memory-side metal interconnect structures (88, 86, 82, 98, 96, 92, 102, 106, 108, 980). The set of all dielectric material layers formed above the alternating stacks (32, 46) is herein referred to as memory-side dielectric material layers (80, 90, 110, 960). The memory-side dielectric material layers (80, 90, 110, 960) are formed over the alternating stacks (32, 46) and the conductive via structures 38. The memory-side metal interconnect structures (88, 86, 82, 98, 96, 92, 102, 106, 108, 980) comprise bit lines 108.

Each of the bit lines 108 can be electrically connected to top ends of a respective subset of the vertical semiconductor channels 60 through metallic via structures (88A, 98A), and can be electrically connected to a respective conductive via structure 38 through at least one additional metallic via structure (88B, 98B). Each drain region 63 can be electrically connected to a respective bit line 108 through at least one metallic via structure (88A, 98A). Each conductive via structure 38 can be electrically connected to a respective bit line 108 through at least one metallic via structure (88A, 98A). Thus, each conductive via structure 38 can be electrically connected to a respective set of drain regions 63 through a bit line 108.

The memory-side bonding pads 988 can be embedded within the memory-side dielectric material layers (80, 90, 110, 960), and specifically, within the topmost layer among the memory-side dielectric material layers (80, 90, 110, 960). The memory-side bonding pads 988 can be electrically connected to the memory-side metal interconnect structures (88, 86, 82, 98, 96, 92, 102, 106, 108, 980).

According to an aspect of the present disclosure, the combination of the bit lines 108, the discharge-path connection via structures 98B, the discharge-path contact via structures 88B, the conductive via structures 38, and a subset of the sacrificial via structures 11 that contact the conductive via structures 38 provide electrically conductive paths between each metal interconnect structure 980 that is electrically connected via the bit lines to the carrier substrate 9 throughout the processing steps employed to form the metal interconnect structures 980. A subset of the processing steps employed to form the metal interconnect structures 980 can be affected by lack of proper electrical grounding of the bit lines 108 or previously-formed metal interconnect structures 980. Such processing steps may comprise reactive ion etch steps, electroplating steps, etc.

In some embodiments, the memory films 50 may comprise at least one dielectric material layer (such as a blocking dielectric layer 52 or a dielectric liner 56) that prevents electrical connection between the vertical semiconductor channels 60 and the sacrificial pillar structures 11. In this case, the bit lines 108, the discharge-path connection via structures 98B, and the discharge-path contact via structures 88B, the conductive via structures 38, and a subset of the sacrificial via structures 11 that contact the conductive via structures 38 provide continuous electrically conductive paths. One exemplary discharge path including a bit line 108 is illustrated in FIG. 21.

These paths provide electrical grounding of the bit lines 108 and all other metal interconnect structures 980 that are electrically connected to the bit lines 108 to the carrier substrate 9 (which comprises a semiconducting or conductive material) during the processing steps employed to form the metal interconnect structures 980. For example, if the drain contact via structures 88A comprise tungsten and the bit lines 108 comprise copper, then a charge accumulation may occur due to a floating potential. The charge accumulation may result in a battery effect between dissimilar metals or diffusion of chlorine ions trapped in the electrically conductive layers 46 into the bit lines 108. The battery effect may cause voids in the drain contact via structures 88A, while the chlorine diffusion may cause voids in the bit lines 108. Such voids may cause open circuits. However, the conductive paths reduce the charge accumulation during processing, and thus reduce or eliminate the voids in various conductive structures.

The first exemplary structure if FIG. 21 includes at least one memory die 900, such as a two-dimensional array of memory dies 900 located on the carrier substrate 9.

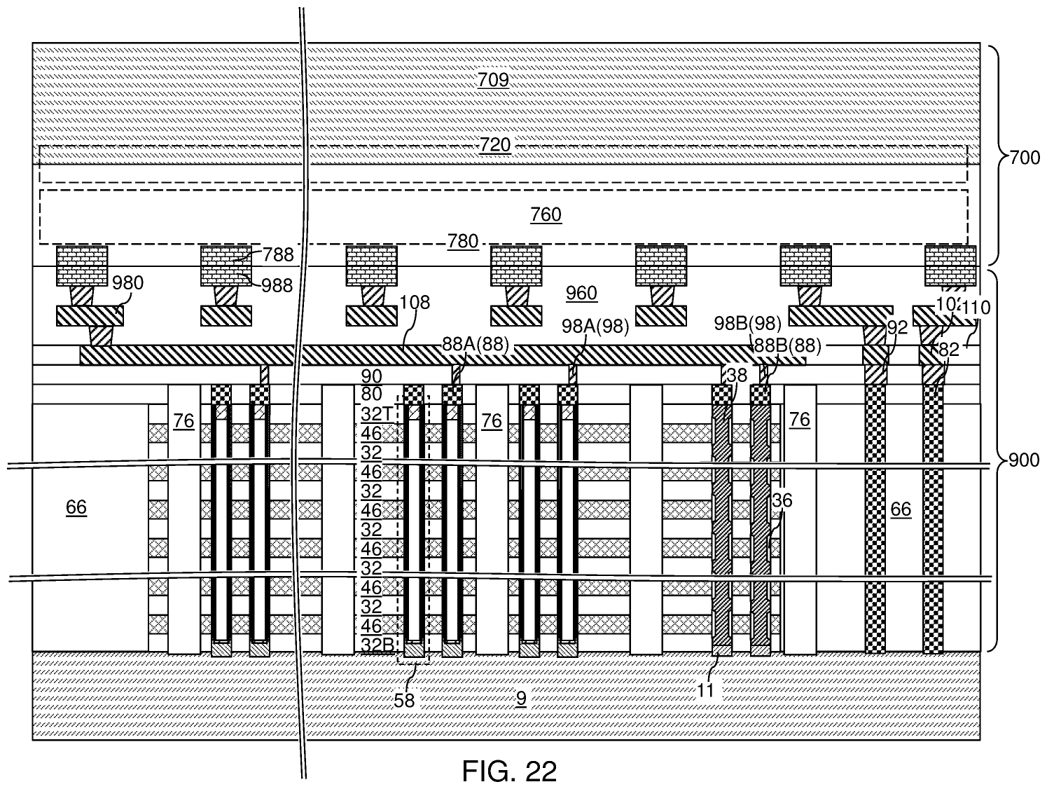

Referring to FIG. 22, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 778. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 53, and a source layer to be subsequently formed. The peripheral circuit 720 can be configured to control operation of the vertical stack of memory elements in the memory array in the memory die 900.

The logic die 700 can be attached to the memory die 900, for example, by bonding the logic-side bonding pads 778 to the memory-side bonding pads 988. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

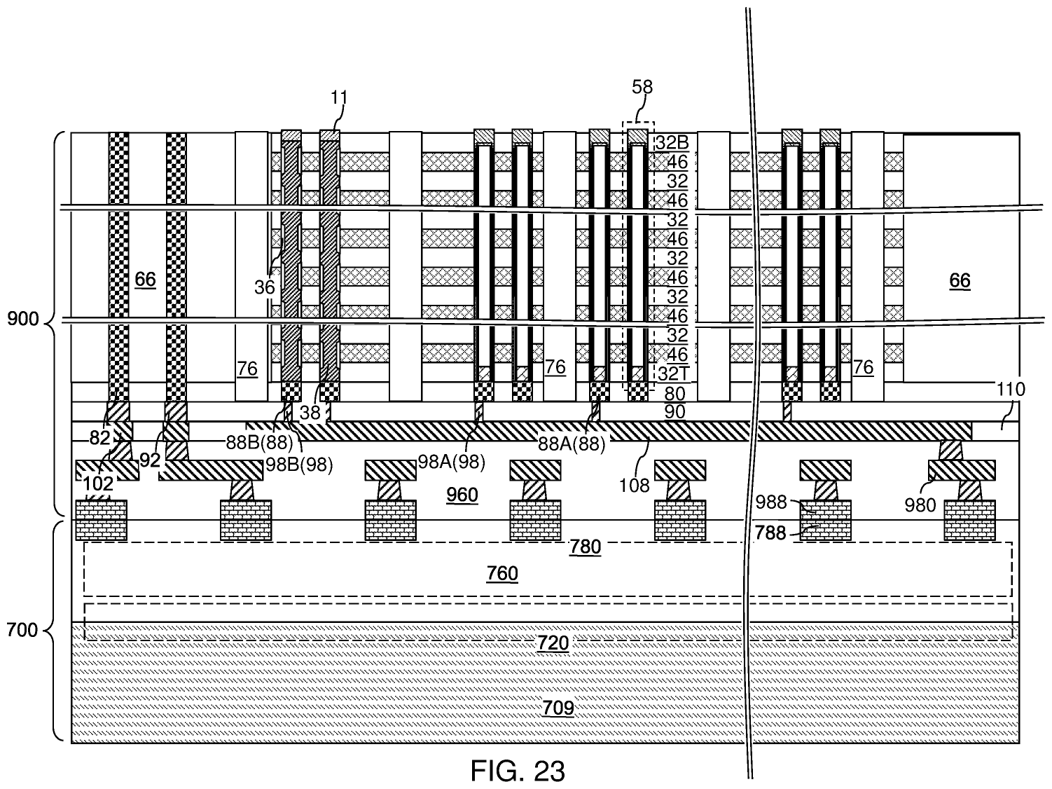

Referring to FIG. 23, the carrier substrate 9 can be removed, for example, by grinding, polishing, cleaving, an isotropic etch process, and/or an anisotropic etch process. The bottom surface of the bottommost insulating layer 32B within each alternating stack (32, 46) of insulating layers 32 and electrically conductive layers 46 can be physically exposed.

Further, the bottom surface of each sacrificial pillar structure 11 can be physically exposed. For example, if the carrier substrate 9 comprises a lightly doped p-type silicon wafer, then the carrier substrate 9 may be removed by a CMP and selective wet TMAH or KOH etching without removing the heavily doped p-type polysilicon conductive via structures 38 because TMAH and KOH selectively etch lightly doped p-type silicon at a higher rate compared to heavily doped p-type silicon.

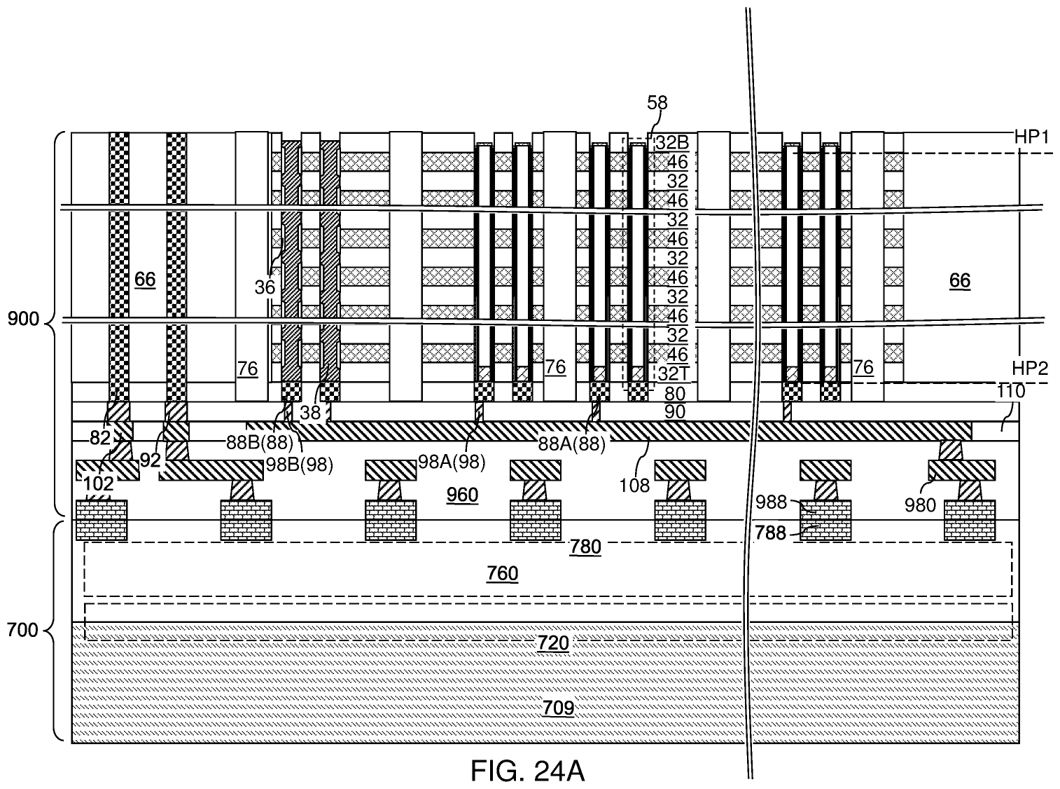

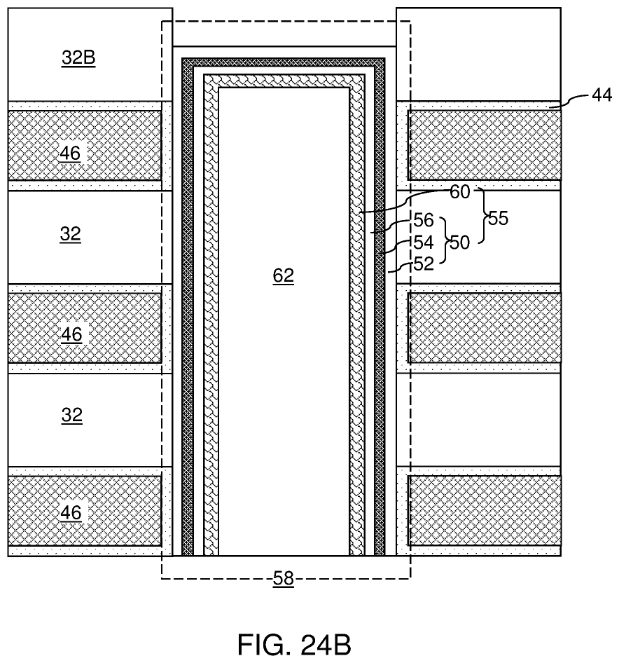

Referring to FIGS. 24A and 24B, a selective etch process can be performed to remove the sacrificial pillar structures 11 selective to the materials of the insulating layers 32, the dielectric material portions (65, 66), the memory films 50, and the conductive via structures 38. For example, if the sacrificial pillar structures 11 comprise a lightly doped p-type silicon, then the selective etch process may comprise a wet etch process employing tetramethyl ammonium hydroxide (TMAH). Horizontally-extending surfaces of the memory films 50 may be physically exposed underneath (or below, depending on the orientation of the first exemplary structure) remaining portions of the memory opening fill structures 58 and the contact via structures 38. Backside blocking dielectric layers 44 are illustrated in FIG. 24B, which can be deposited in the backside recesses 43 prior to formation of the electrically conductive layers 46 at the processing steps of FIG. 16.

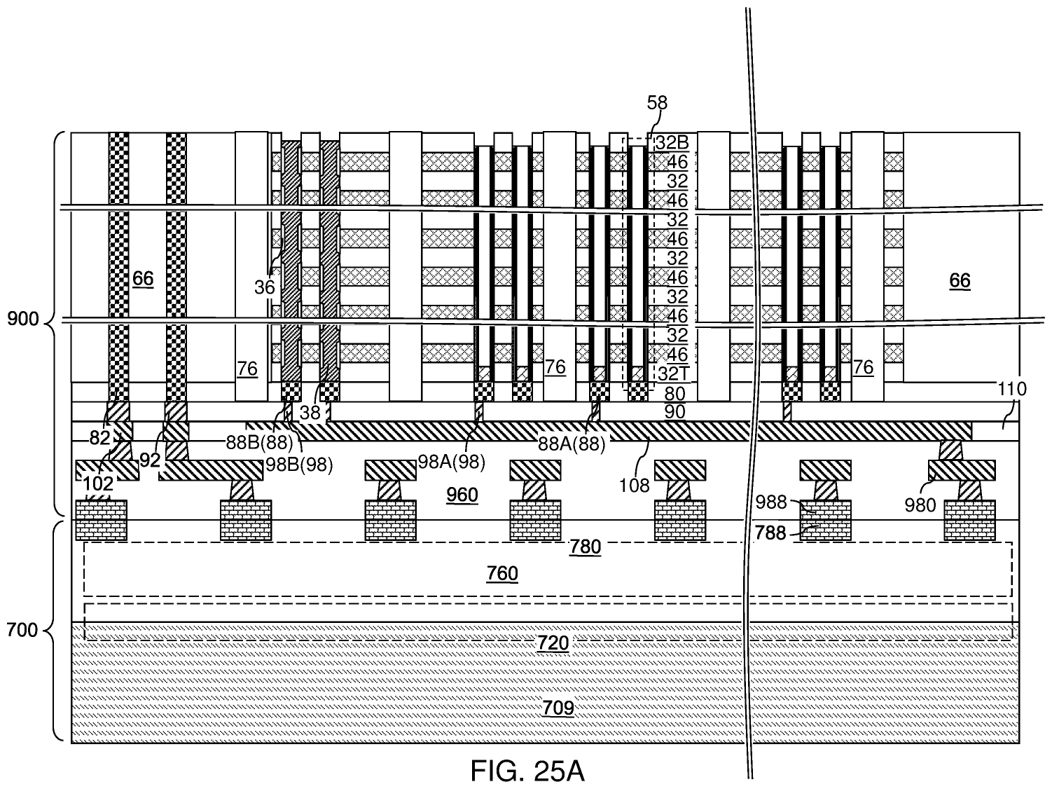

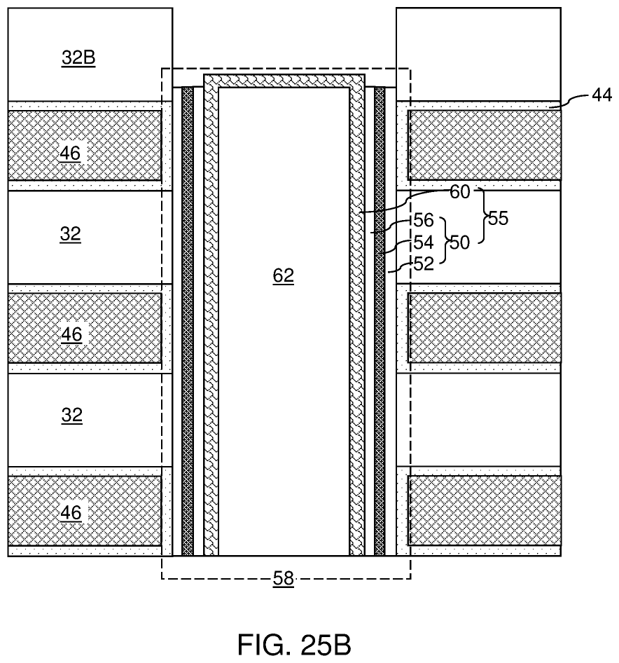

Referring to FIGS. 25A and 25B, a sequence of etch processes can be performed to etch the various layers within the memory films 50. For example, the blocking dielectric layer 52, the memory material layer 54, and the dielectric liner 56 can be sequentially etched by performing a series of wet etch processes. End portions of the vertical semiconductor channels 60 can be physically exposed.

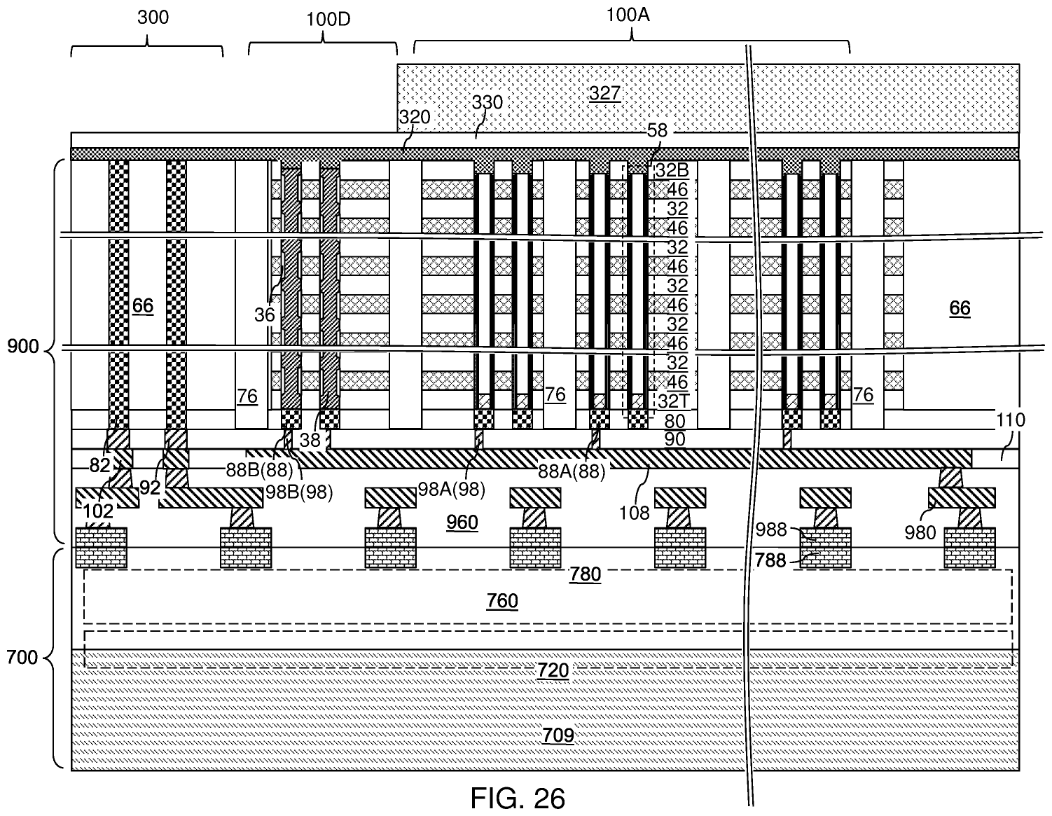

Referring to FIG. 26, a conductive material, such as a heavily doped semiconductor material having a doping of the second conductivity type or a metallic material (e.g., metal and/or conductive metal nitride), can be deposited on the physically exposed surfaces of the vertical semiconductor channels 60 to form a source layer 320. A dielectric cover layer 330 can be formed over the source layer 320 by deposition of a dielectric material such as silicon oxide. A photoresist layer 327 can be formed over the dielectric cover layer 330, and can be lithographically patterned to cover the memory opening fill structures 58 in the active memory block area 100A without covering the conductive via structures 38 in the dummy memory block area 100A or the through-memory-level via structures 82 in the peripheral area 300.

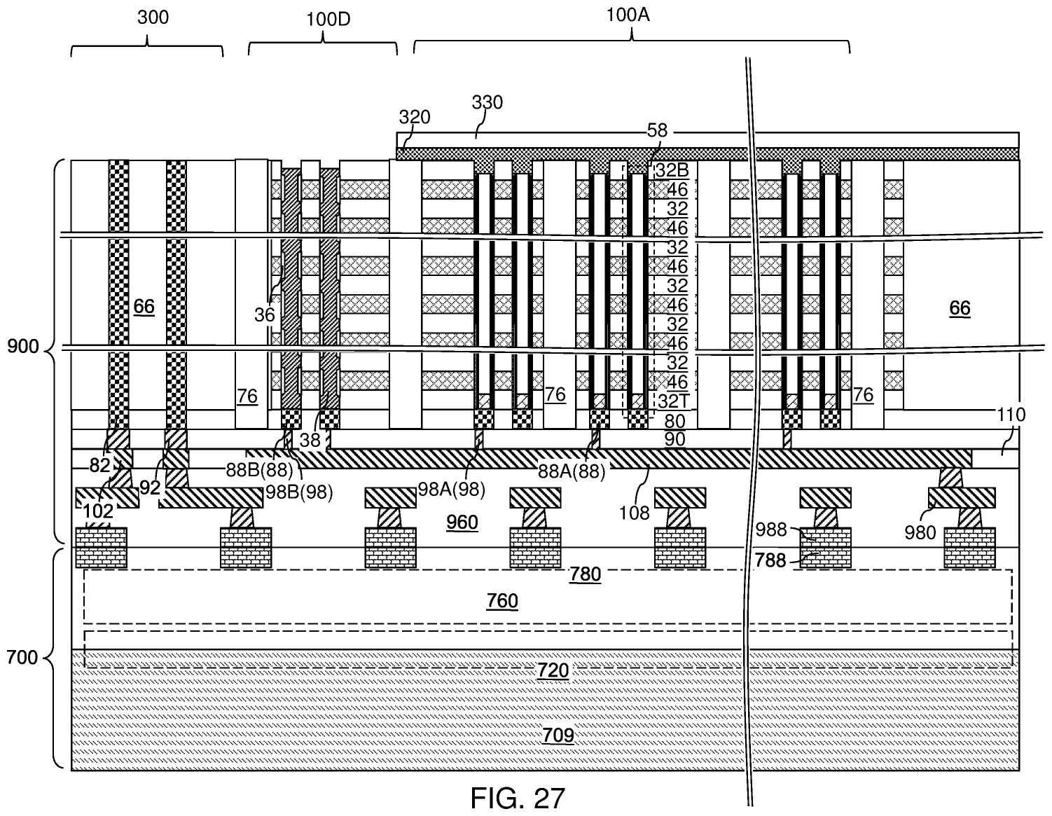

Referring to FIG. 27, etch processes can be performed to remove potions of the dielectric cover layer 330 and the source layer 320 in the dummy memory block area 100D and the peripheral region 300 that are not covered by the photoresist layer 327. End surfaces of the conductive via structures 38 and the through-memory-level via structures 82 can be physically exposed. The photoresist layer 327 can be subsequently removed, for example, by ashing.

Generally, the source layer 320 can be formed in the active memory block area 100A on a bottom end of the vertical semiconductor channel 60 after removing the carrier substrate 9 by depositing and patterning a conductive material or a semiconductor material. The source layer 320 is not in contact with the conductive via structures 38 in the dummy memory block area 100D upon patterning.

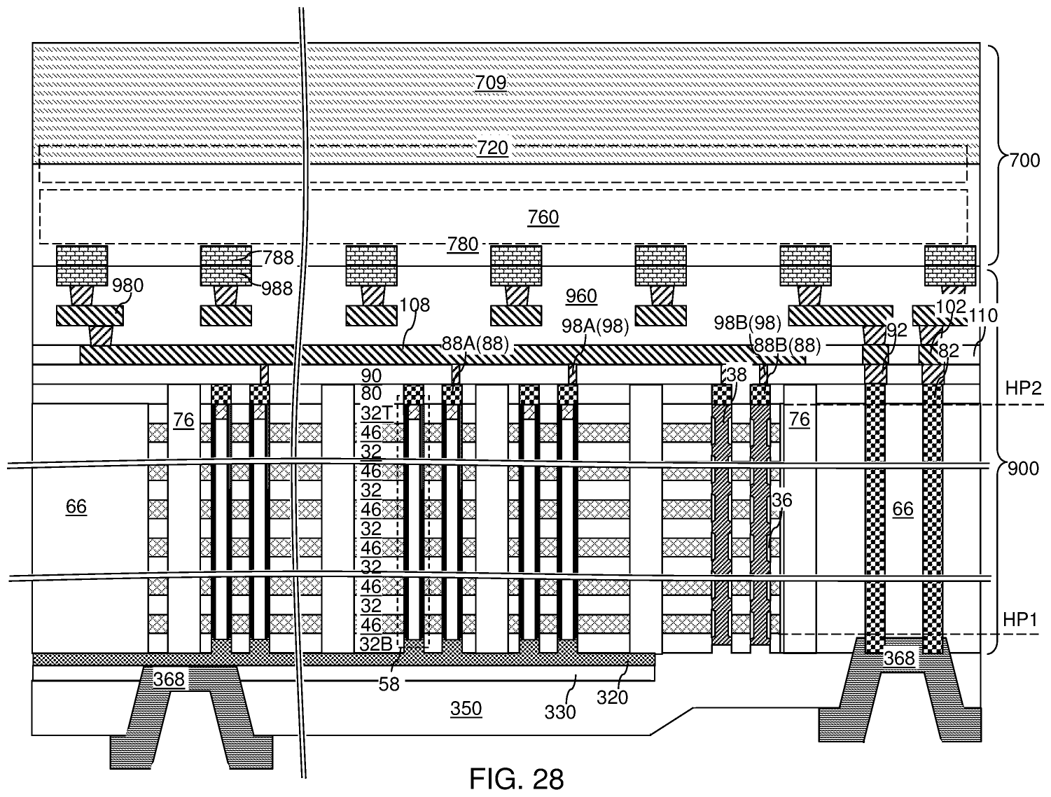

Referring to FIG. 28, an optional backside dielectric layer 350 can be formed on the backside of the dielectric cover layer 330 and over the physically exposed surfaces of the conductive via structures 38 and the through-memory-level via structures 82. The backside dielectric layer 350 can be formed underneath the alternating stacks (32, 46) and the conductive via structures 38. The backside dielectric material layer 350 is formed on a bottom side of the source layer 320. The entirety of each bottom surface of the conductive via structures 38 can be contacted by the backside dielectric layer 350. In one embodiment, the backside dielectric material layer 350 may have a contoured bottom surface such that a bottom surface of a first portion of the backside dielectric material layer 350 that underlies the memory opening fill structures 58 is recessed below a horizontal plane including a bottom surface of a second portion of the backside dielectric material layer 350 that underlies the conductive via structures 38. The second portion of the backside dielectric material layer 350 may have the same thickness as the first portion of the backside dielectric material layer 350.

The conductive via structures 38 vertically extending between one of the memory-side metal interconnect structures (88, 86, 82, 98, 96, 92, 102, 106, 108, 980) (such as a respective one of the discharge-path contact via structures 88B) and the backside dielectric material layer 350. The entirety of an end surface of each conductive via structure 38 can be in contact with the backside dielectric material layer 350. The conductive via structures 38 are not in direct contact with any conductive material or with any semiconductor material on a side of the alternating stacks (32, 46) (i.e., on the side of the source layer 320) relative to the first horizontal plane HP1 upon formation of the backside dielectric layer 350. The source layer 320 underlies the alternating stacks (32, 46), overlies a portion of the backside dielectric material layer 350, and contacts each bottom end of the vertical semiconductor channels 60.

Optionally, a photoresist layer can be formed over the backside dielectric material layer 350, and can be lithographically patterned to form openings therein. An anisotropic etch process can be performed to form openings through the backside dielectric material layer 350 and the dielectric cover layer 350 to form backside via cavities. A surface of the source layer 320 can be exposed underneath each backside via cavity within a first subset of the backside via cavities, and a surface of at least one through-memory-level via structure 82 can be exposed underneath each backside via cavity within a second subset of the backside via cavities. Optional backside bonding pads 368 can be formed in the backside via cavities. A first subset of the backside bonding pads 368 can be formed on the source layer 320. A second subset of the backside bonding pads 368 can be formed on the through-memory-level via structures 82.

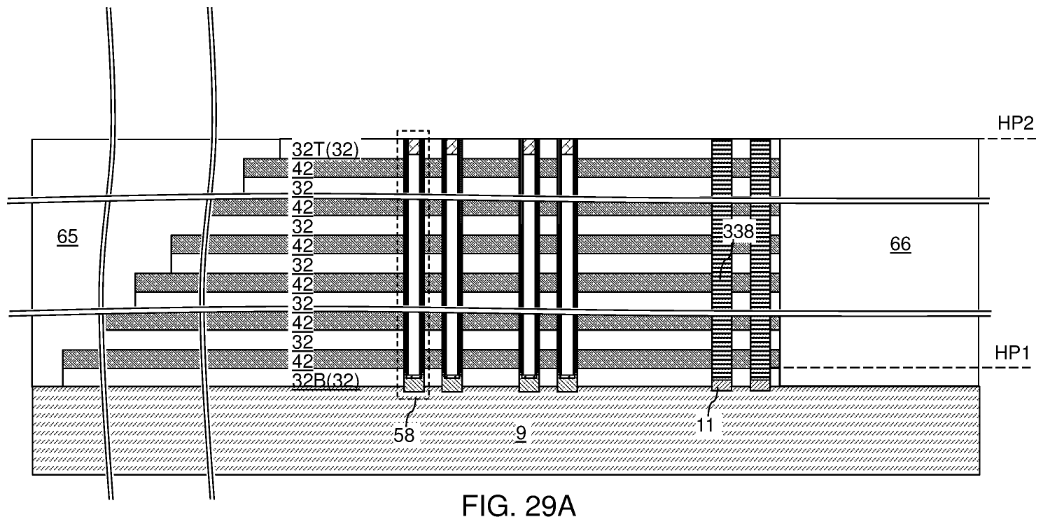

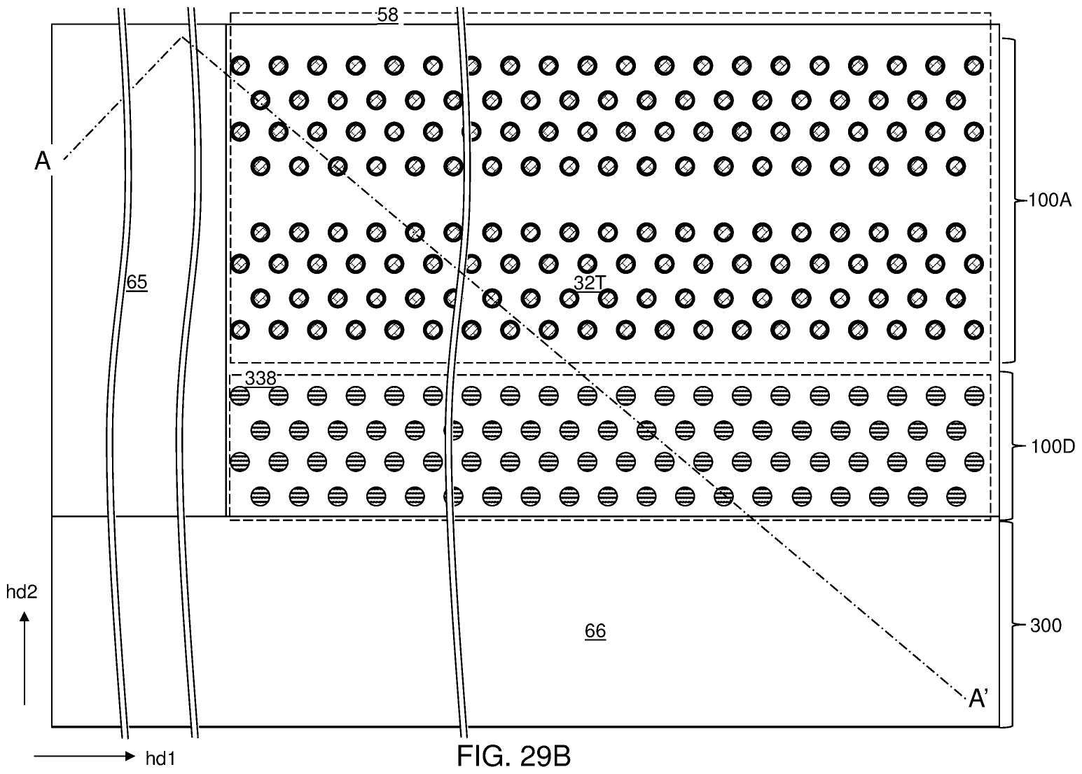

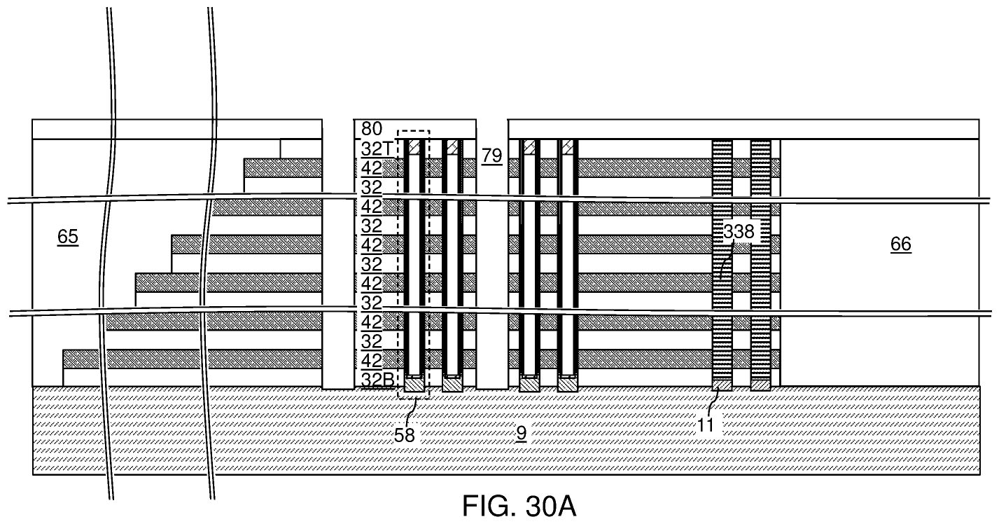

Referring to FIGS. 29A and 29B, a second exemplary according to a second embodiment of the present disclosure structure can be derived from the first exemplary structure illustrated in FIG. 11 by depositing at least one conductive material in the connection openings 39. Optionally, the layout of the memory openings 49 and connection openings 39 may be modified such that each of the memory opening fill structures 58 can be located within a predefined lateral distance (which is the lateral etch distance for formation of backside recesses) from areas of backside trenches 79 to be subsequently formed, while all of the connection openings 39 are laterally spaced from the areas of the backside trenches 79 to be subsequently formed by lateral distances that are greater than the predefined lateral distance. In other words, formation of the backside trenches 79 in the dummy memory block area 100D may be omitted in the second embodiment, as will be described below.

The at least one conductive material may comprise at least one metallic material and/or at least one heavily-doped semiconductor material having electrical conductivity greater than 1.0×10⁵ S/m. In one embodiment, the at least one conductive material may comprise a combination of an optional metallic barrier material (such as TiN, TaN, WN, MoN, TiC, TaC, WC, or other conductive metallic compounds) and a metal fill material (such as W, Ti, Ta, Co, Ru, Mo, Cu, etc.). Excess portions of the at least one conductive material can be removed from above the horizontal plane including the topmost surface of the alternating stack (32, 42). Each remaining portion of the at least one conductive material that fills the connection openings 39 in the dummy memory block area 100D constitutes a conductive via structure 338. The conductive via structures 338 are formed through the alternating stack (32, 42), and vertically extends at least from a first horizontal plane HP1 including a top surface of a bottommost insulating layer 32B within the alternating stack (32, 42) to a second horizontal plane HP2 including a top surface of a topmost insulating layer 32T within the alternating stack (32, 42).

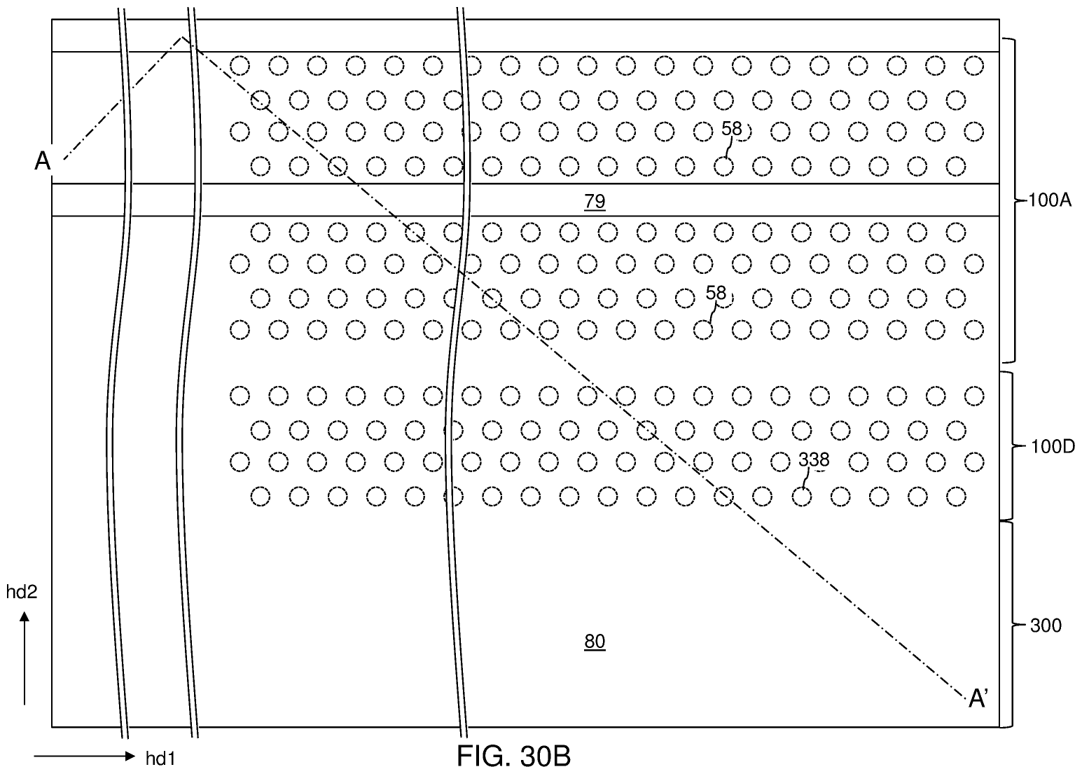

Referring to FIGS. 30A and 30B, a contact-level dielectric layer 80 can be formed over the alternating stack (32, 42). A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), and the retro-stepped dielectric material portion 65. Backside trenches 79 laterally extending along the first horizontal direction hd1 can be formed through the alternating stack (32, 42), the dielectric material portions (65, 66), and the contact-level dielectric layer 80.

The locations of the backside trenches 79 can be selected such that each of the memory opening fill structures 58 is located within a predefined lateral distance (which is the lateral etch distance for formation of backside recesses) from a most proximal of the backside trenches 79, while all of the conductive via structures 338 are laterally spaced from the backside trenches 79 by lateral distances that are greater than the predefined lateral distance. Preferably, the backside trenches 79 are not formed in or adjacent to the dummy memory block area 100D. Each of the backside trenches 79 may comprise a respective pair of lengthwise sidewalls that are parallel to the first horizontal direction hd1 and vertically extend from the carrier substrate 9 to the top surface of the contact-level dielectric layer 80. A top surface of the carrier substrate 9 can be physically exposed underneath each backside trench 79. The photoresist layer can be subsequently removed, for example, by ashing.

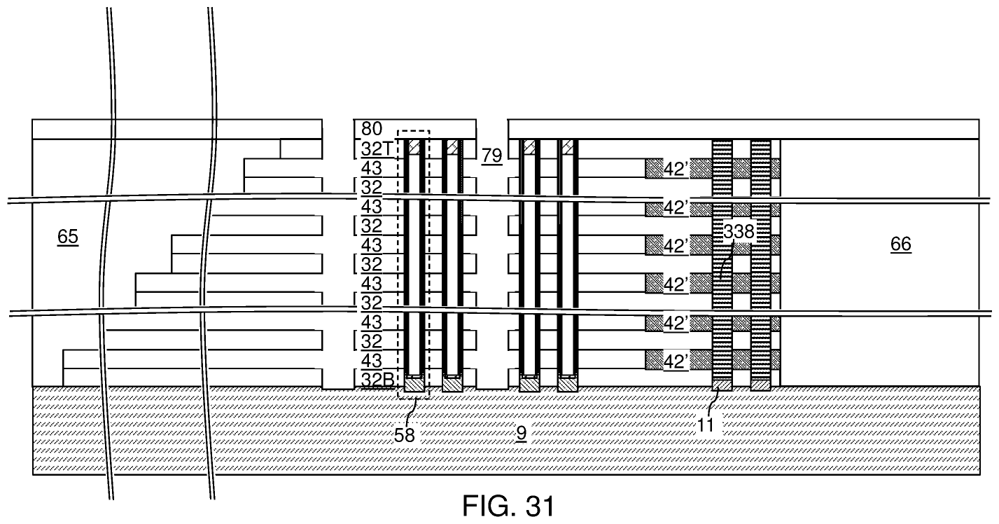

Referring to FIG. 31, an isotropic etch process can be performed through the backside trenches 79 to remove the sacrificial material layers 42 selective to the insulating layers 32, the memory opening fill structures 58, the conductive via structures 38, and the carrier substrate 8. Backside recesses 43 can be formed in volumes from which the sacrificial material layers 42 are removed.

The duration of the anisotropic etch process can be selected such that all of the memory opening fill structures 58 are laterally surrounded by a respective vertical stack of backside recesses 43, while each of the conductive via structures 338 is laterally surrounded by remaining portions of the sacrificial material layers 42. In one embodiment, the sacrificial material layers 42 comprise a dielectric material such as silicon nitride, and the remaining portions of the sacrificial material layers 42 comprise a vertical stack of dielectric material plates 42′. The vertical stack of dielectric material plates 42′ is interlaced with the insulating layers 32 within an alternating stack of insulating layers 32 and dielectric material plates 42′ along the vertical direction.

The conductive via structures 338 vertically extend through the vertical stack of dielectric material plates 42′ and each insulating layer 32 within the alternating stack (32, 42′) of dielectric material plates 42′ and insulating layers 32. In one embodiment, the conductive via structures 338 may comprise at least one metallic material, and may contact each dielectric material plate 42′ and each insulating layer 32 within the alternating stack (32, 42′) of dielectric material plates 42′ and insulating layers 32.

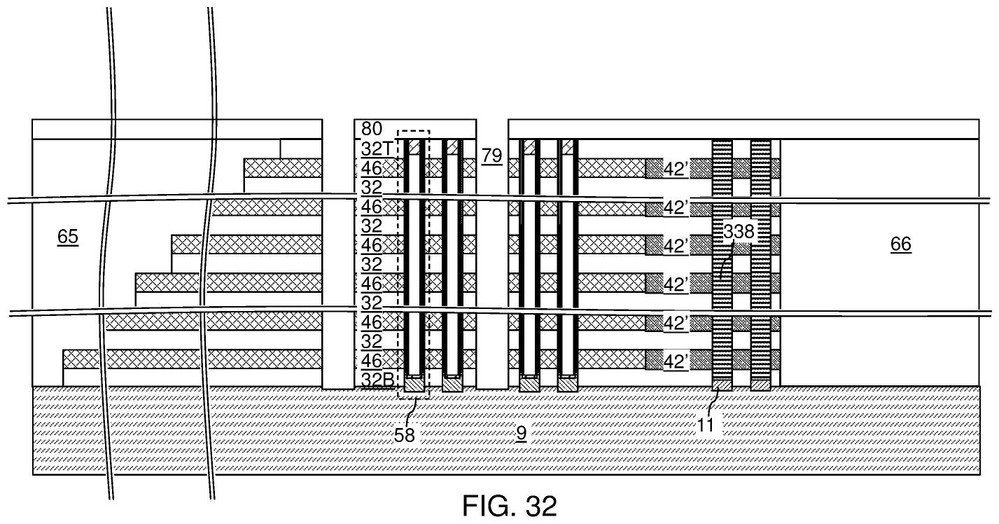

Referring to FIG. 32, the processing steps described with reference to FIG. 16 can be performed to form an optional backside blocking dielectric layer (not shown) and an electrically conductive layer 46 in each of the backside recesses 43. In the second embodiment, the spacer material layers can be formed as sacrificial material layers 42 comprising a dielectric material, first portions of the sacrificial material layers 42 can be replaced with the electrically conductive layers 46, while remaining second portions of the sacrificial material layers 42 comprise the dielectric material plates 42′. The conductive via structures 338 vertically extend through the dielectric material plates 42′. In one embodiment, each dielectric material plate 42′ within the vertical stack of dielectric material plates 42′ is located at a level of a respective electrically conductive layer 46 of electrically conductive layers 46. In one embodiment, each dielectric material plate 42′ may be in direct contact with a respective electrically conductive layer 46, or may be in direct contact with a backside blocking dielectric layer 44 that embeds the respective electrically conductive layer 46.

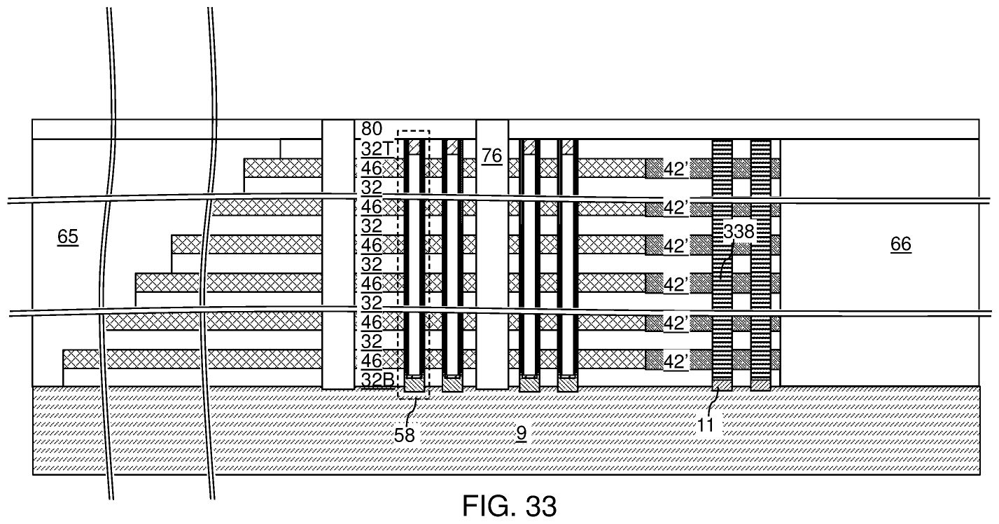

Referring to FIG. 33, at least one dielectric fill material such as silicon oxide can be deposited in the backside trenches 79 to form backside trench fill structures 76. Alternatively, one, a plurality or each of the backside trench fill structures 76 may comprise a combination of an insulating spacer and a backside contact via structure that is laterally surrounded by the insulating spacer.

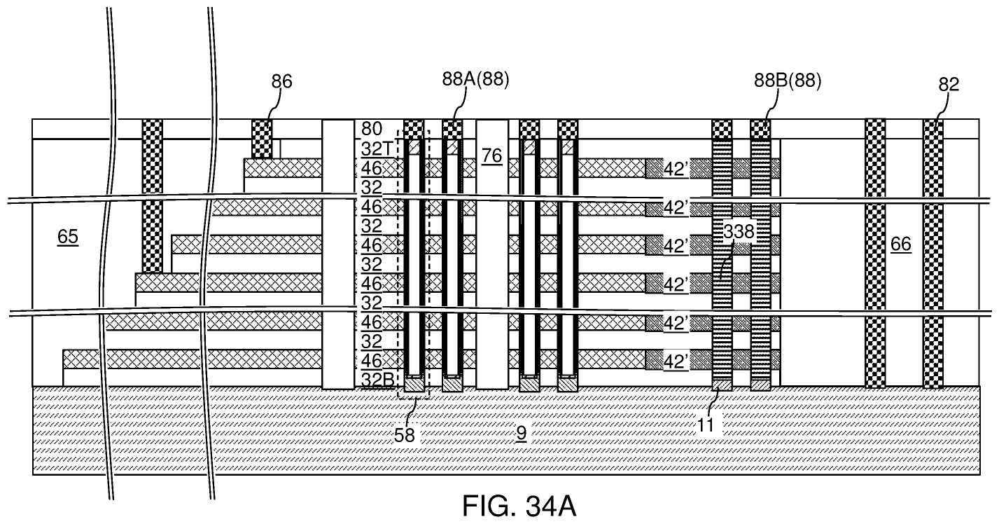

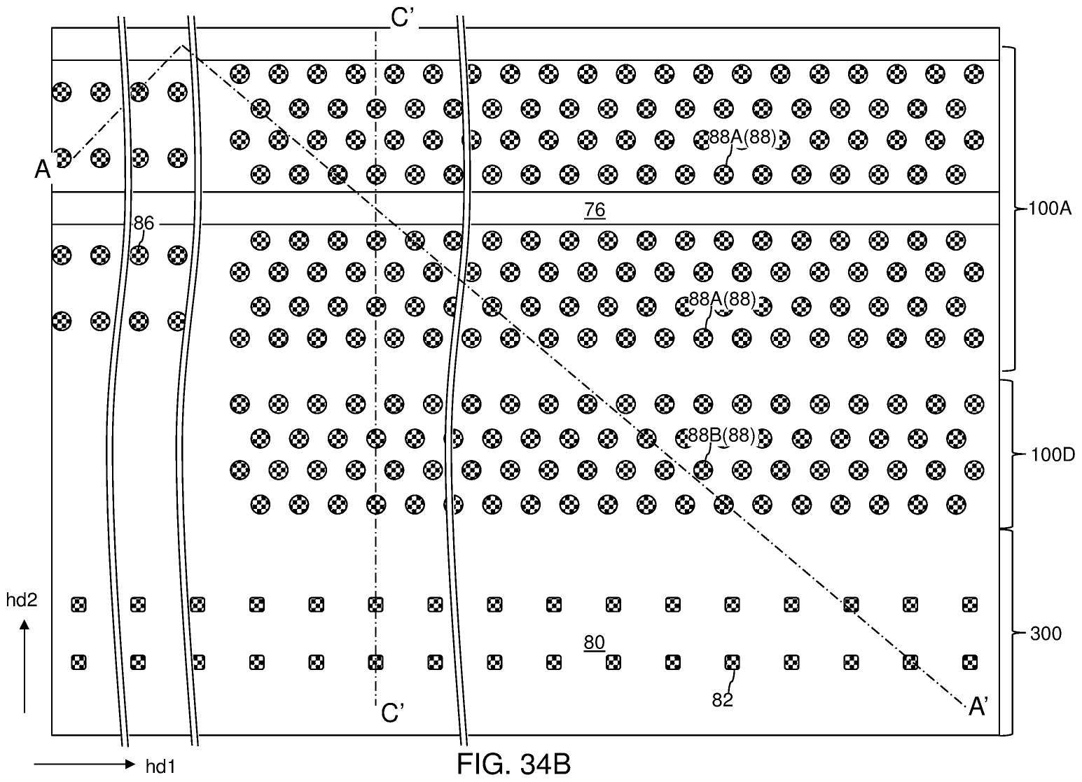

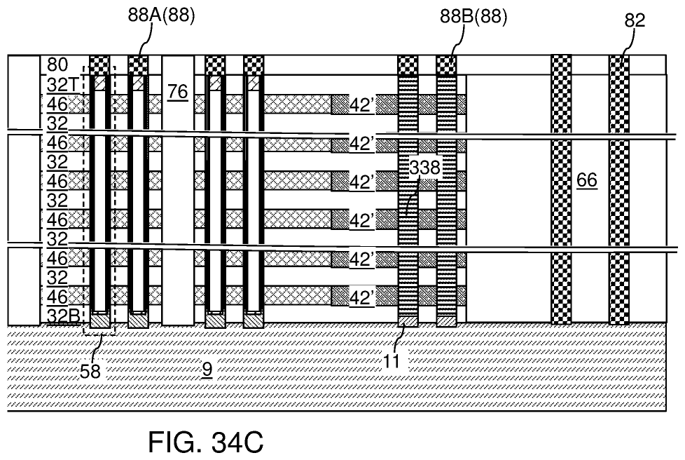

Referring to FIGS. 34A-34C, the processing steps described with reference to FIGS. 18A-18C can be performed to form various contact via structures (86, 88, 82). The various contact via structures (86, 88, 82) may comprise layer contact via structures 86 vertically extending through the contact-level dielectric layer 80 and the retro-stepped dielectric material portion 65 and contacting a respective one of the electrically conductive layers 46, drain contact via structures 88A contacting a top surface of a respective one of the drain regions 63, discharge-path contact via structures 88B contacting a top surface of a respective one of the conductive via structures 338, and optional through-memory-level via structures 82 that vertically extend through the contact-level dielectric layer 80 and the field dielectric material portion 66 and contacting a top surface of the carrier substrate 9. The drain contact via structures 88A and the discharge-path contact via structures 88B may have the same height as the thickness of the contact-level dielectric layer 80, and are herein collectively referred to as through-contact-level via structures 88.

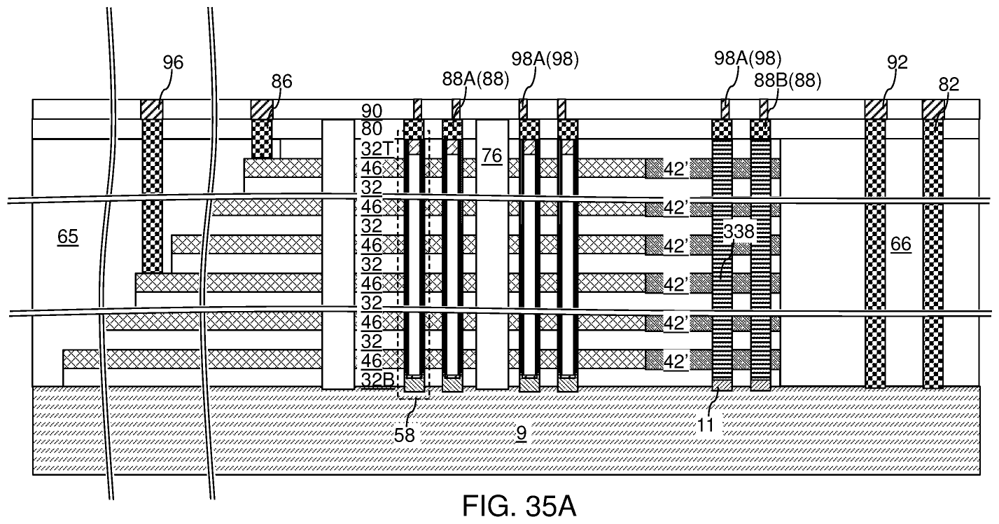

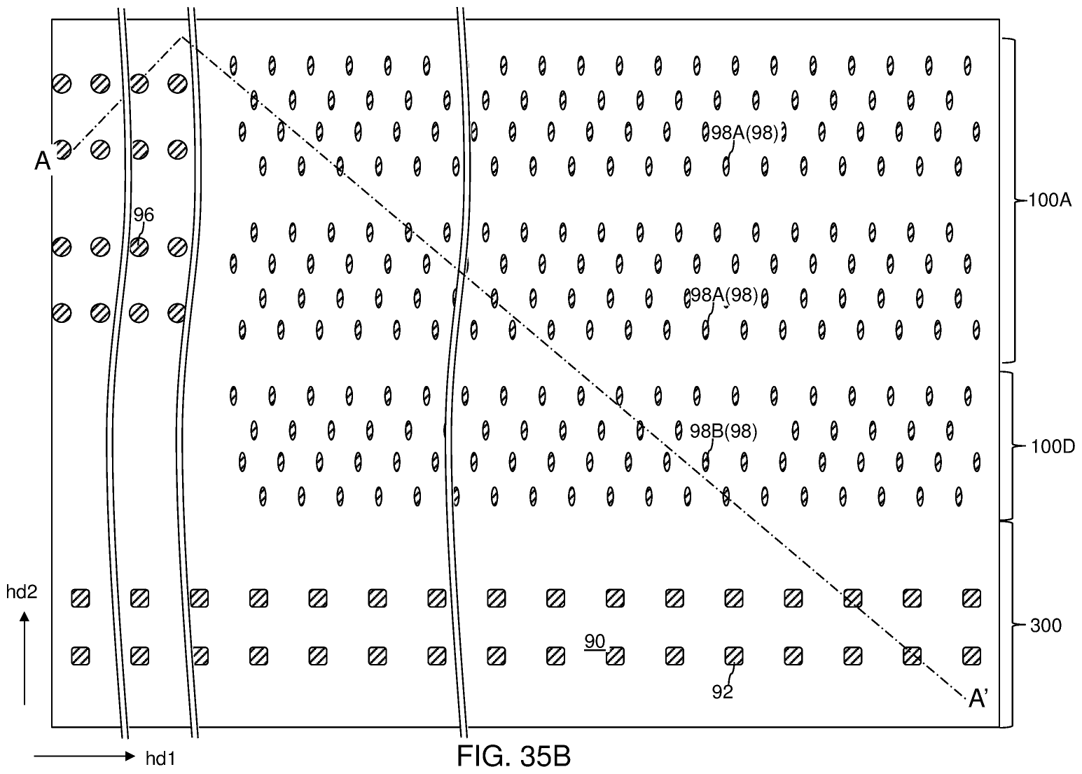

Referring to FIGS. 35A and 35B, a connection-level dielectric layer 90 can be formed over the contact-level dielectric layer 80 by deposition of a dielectric material such as silicon oxide. Connection via structures (98A, 98B, 96, 92) can be formed through the connection-level dielectric layer 90 on a respective one of the contact via structures (86, 88, 82), as described above with respect to FIGS. 19A-19B.

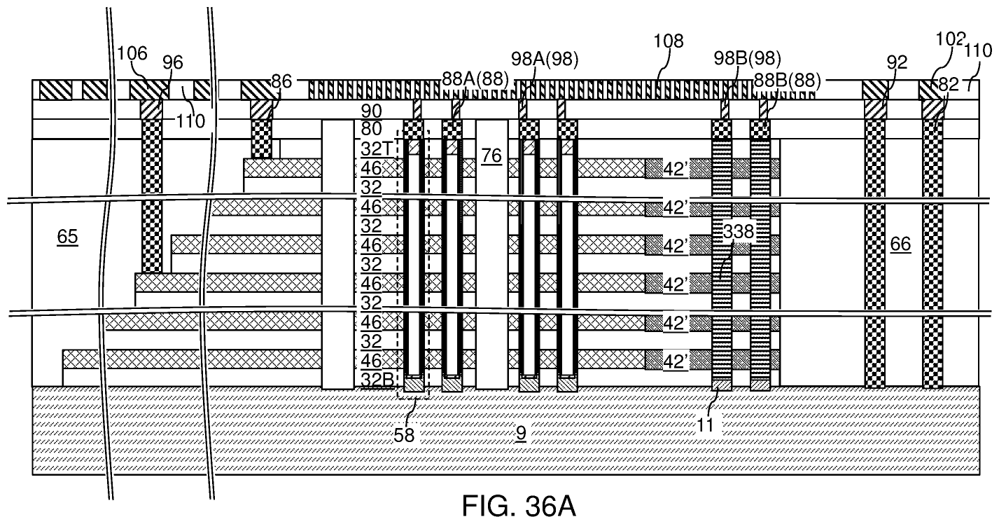

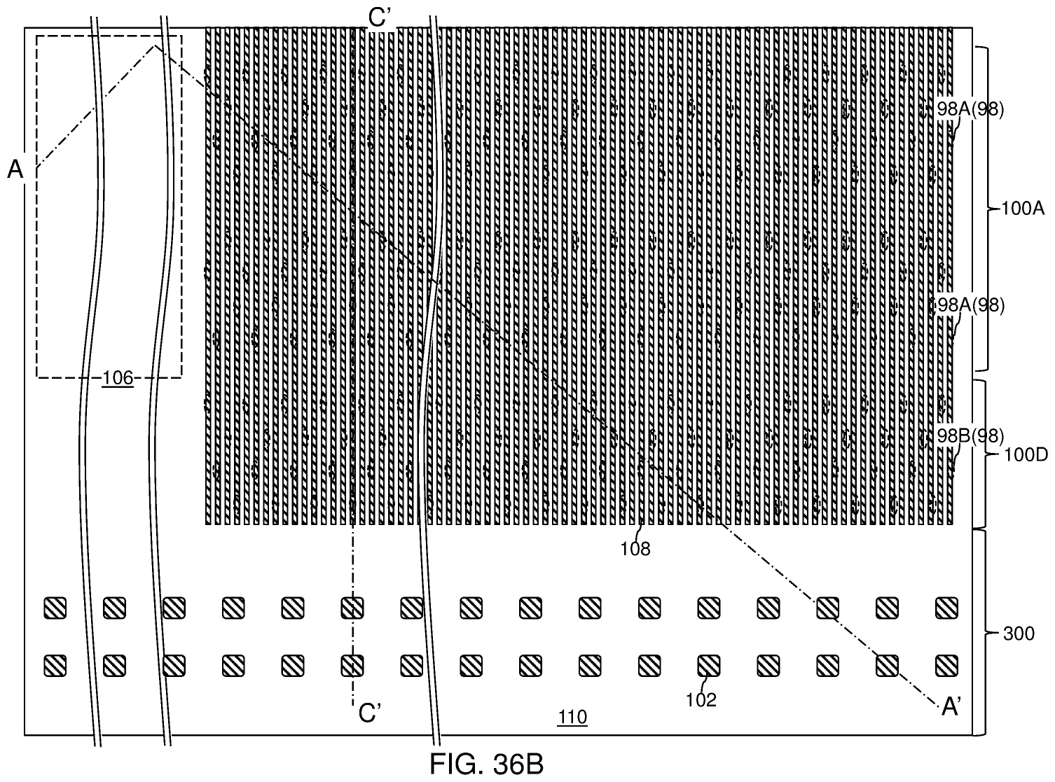

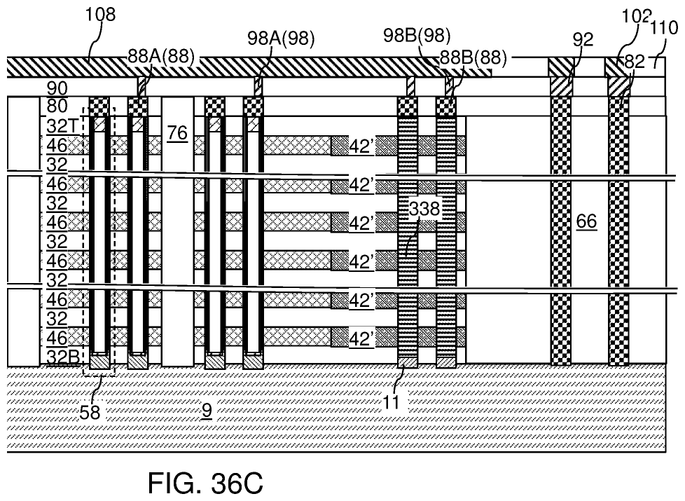

Referring to FIGS. 36A-36C, a line-level dielectric layer can be formed over the connection-level dielectric layer 90. The line-level dielectric layer is herein referred to as a bit-line-level dielectric layer 110 or a first-metal-line-level dielectric layer 110. First-level metal lines (108, 106, 102) can be formed in the bit-line-level dielectric layer 110, as described above with respect to FIGS. 20A-20C.

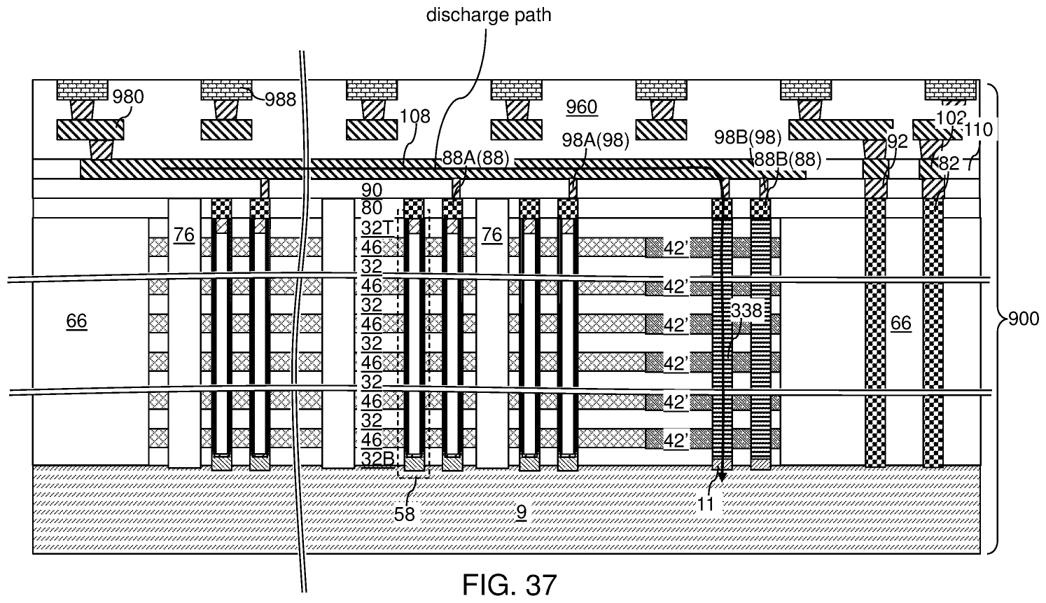

Referring to FIG. 37, additional dielectric material layers 960 and additional metal interconnect structures 980 can be formed over the bit-line-level dielectric layer 110, as described above with respect to FIG. 21. Each conductive via structure 338 can be electrically connected to a respective bit line 108 through at least one metallic via structure (88A, 98A). Thus, each conductive via structure 338 can be electrically connected to a respective set of drain regions 63 through a bit line 108. In the second embodiment, the above described discharge path passes through the bit lines 108, the discharge-path connection via structures 98B, the discharge-path contact via structures 88B, the conductive via structures 338, and a subset of the sacrificial via structures 11 that contact the conductive via structures 338.

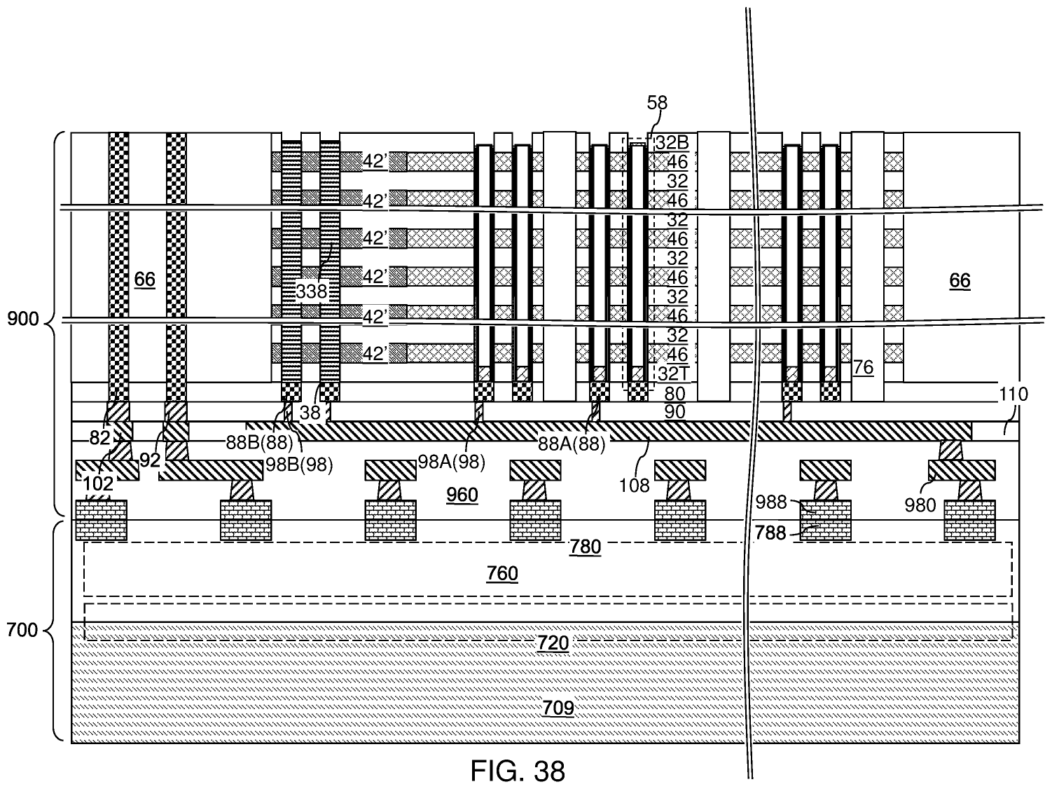

Referring to FIG. 38, the processing steps described with reference to FIGS. 22, 23, 24A and 24B, and 25A and 25B can be performed to bond a logic die 700 to each memory die 900, to remove the carrier substrate 9, to remove the sacrificial pillar structures 11, and to remove portions of the memory films 50 located on the bottom side of the alternating stacks (32, 46) and to physically expose end portions of the vertical semiconductor channels 60.

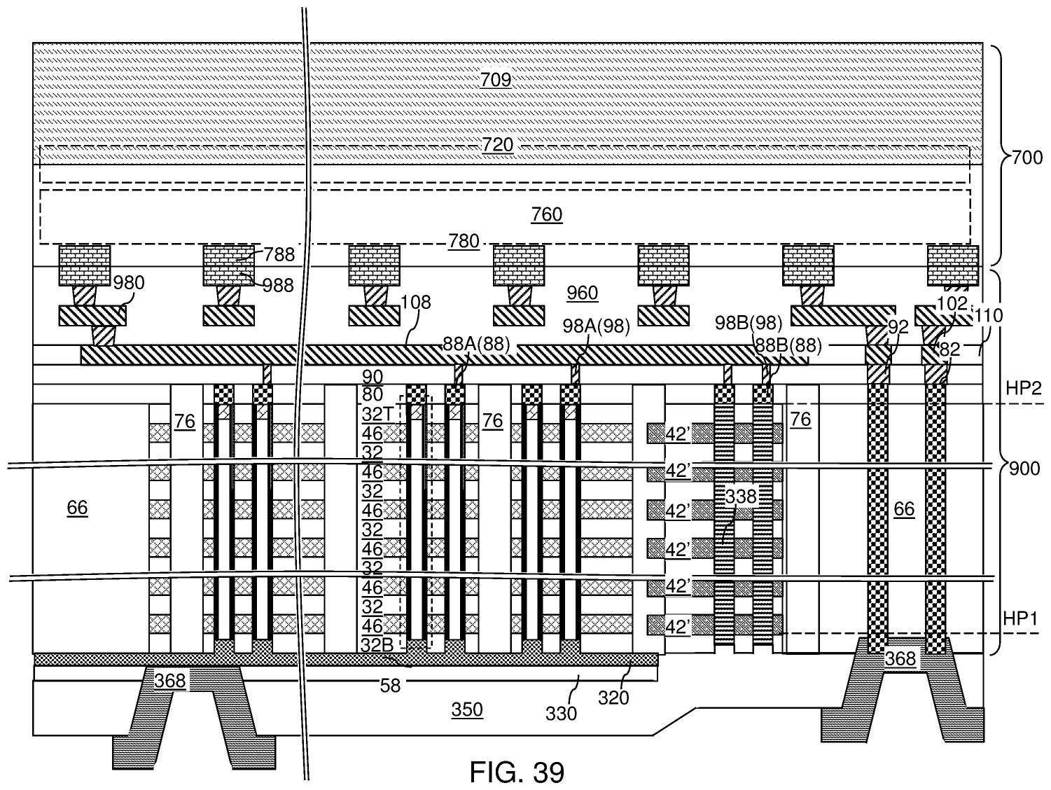

Referring to FIG. 39, the processing steps described with reference to FIG. 26 can be performed to form a source layer 320, a dielectric cover layer 330, a backside dielectric layer 350, and optional backside bonding pads 368. The entirety of each bottom surface of the conductive via structures 338 can be contacted by the backside dielectric layer 350. Thus, the second embodiment differs from the first embodiment by the presence of the dielectric material plates 42′ and omission of the backside trenches 79 in and adjacent to the dummy memory block area 100D.

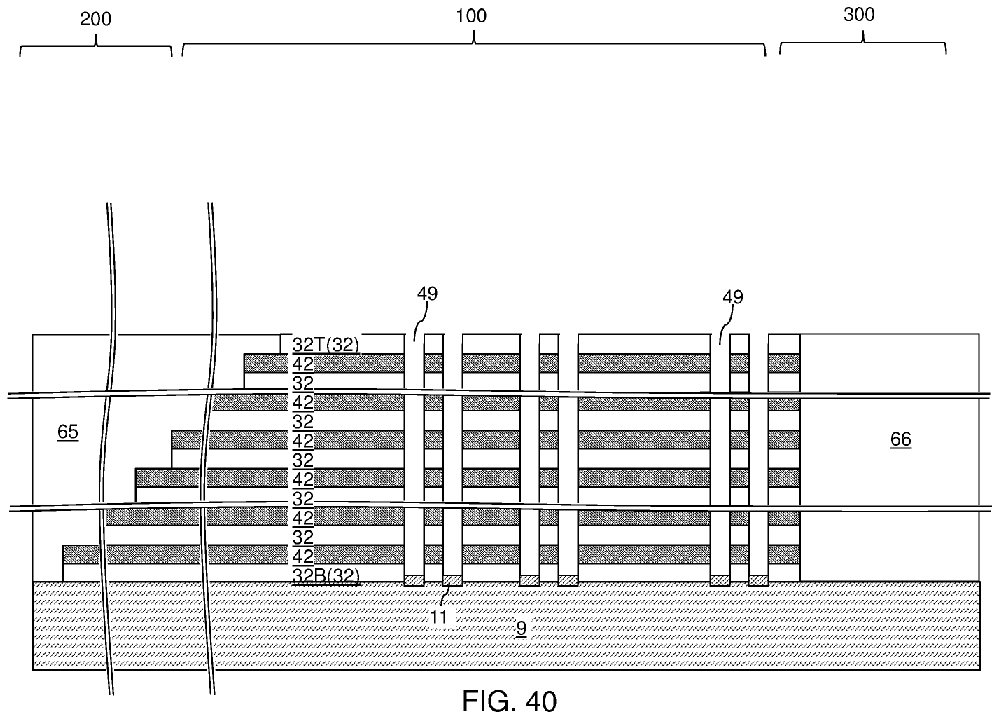

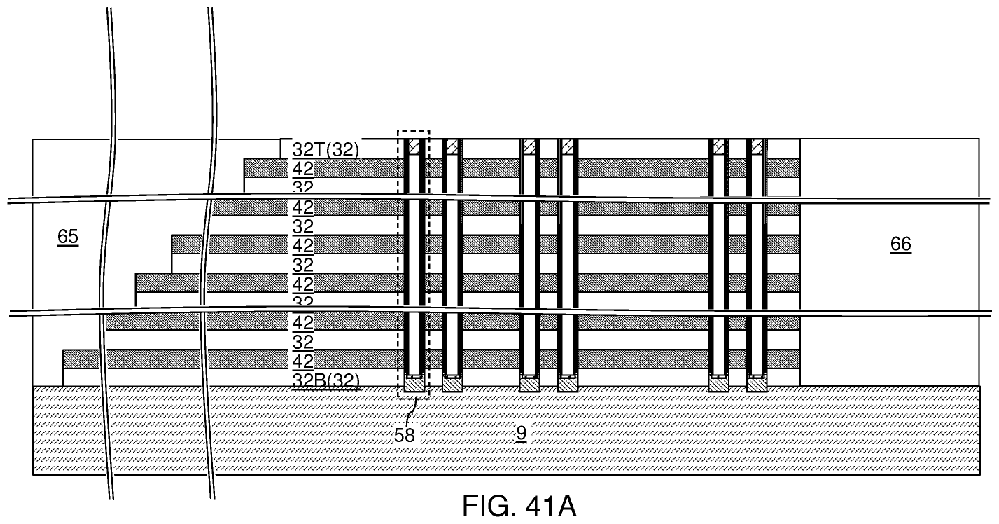

Referring to FIG. 40, a third exemplary structure according to the third embodiment of the present disclosure can be derived from the first exemplary structure illustrated in FIG. 8 by omitting formation of the connection openings 39. Accordingly, the first-tier sacrificial connection opening fill structures 138 are also omitted in the third exemplary structure. Furthermore, the dummy memory block area 100D may also be omitted and only active memory blocks may be formed in the memory array region 100 in the third embodiment. Alternatively, the dummy memory block area 100D may be retained in the third embodiment. However, the memory openings 49 are located in both the dummy memory block area 100D and the active memory block area 100.

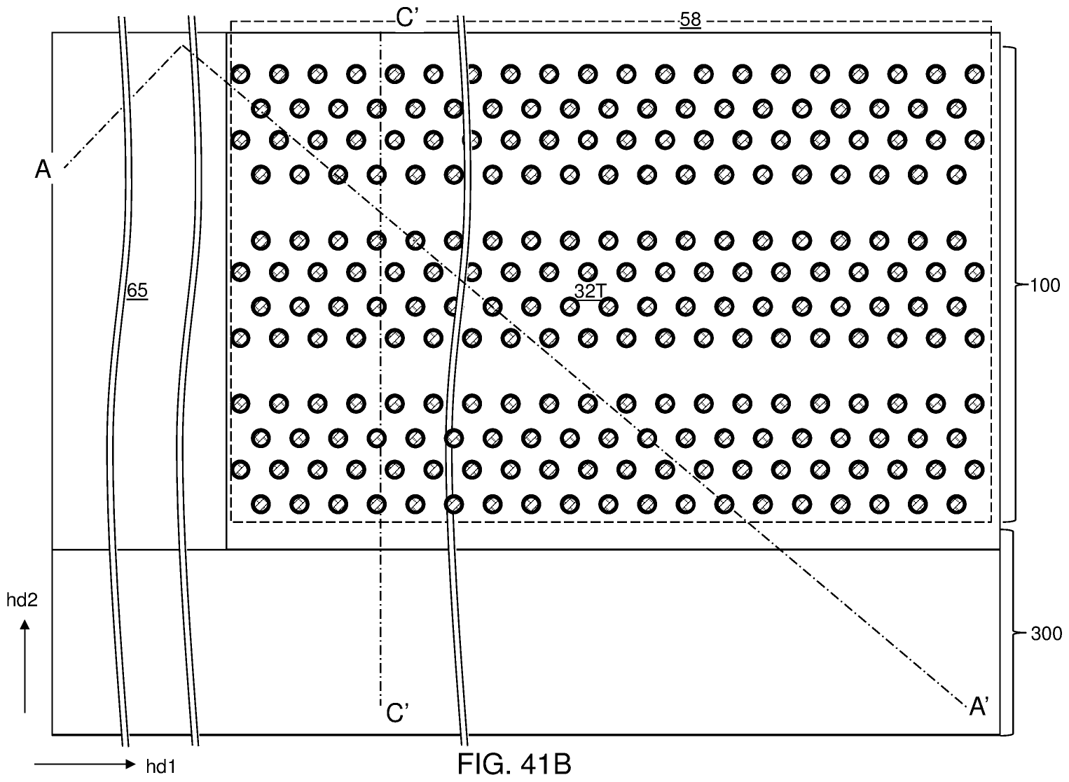

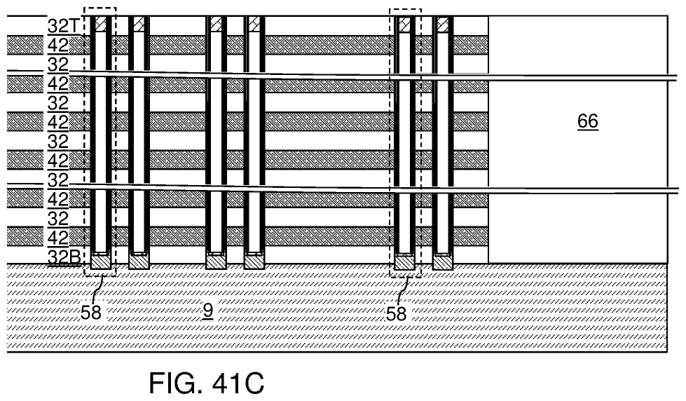

Referring to FIGS. 41A-41C, the processing steps described with reference to FIGS. 9B-9D can be performed to form memory opening fill structures 58 in the memory openings 49. If the dummy memory block area 100D is present in the third embodiment, then the memory opening fill structures 58 in the dummy memory block area 100D are not used to store data during operation of the memory device and comprise dummy memory opening fill structures 58.

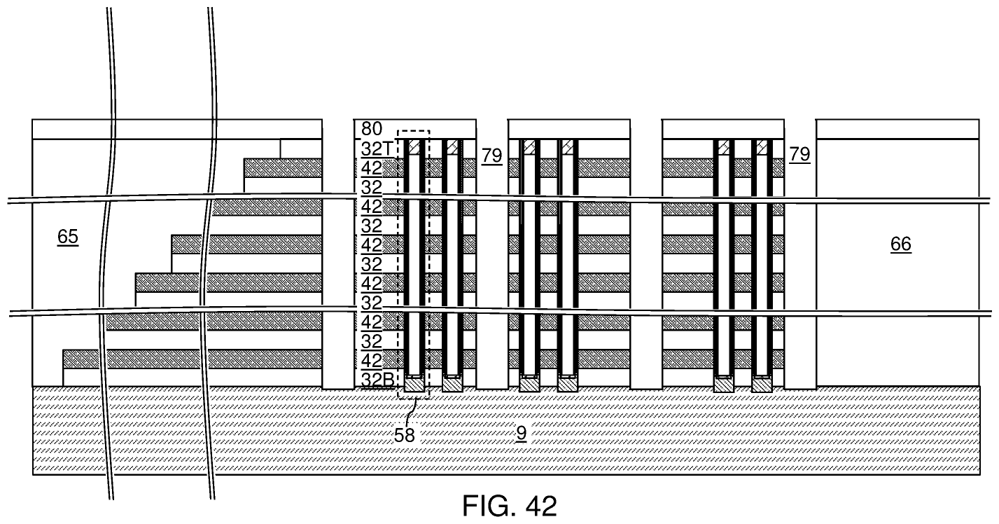

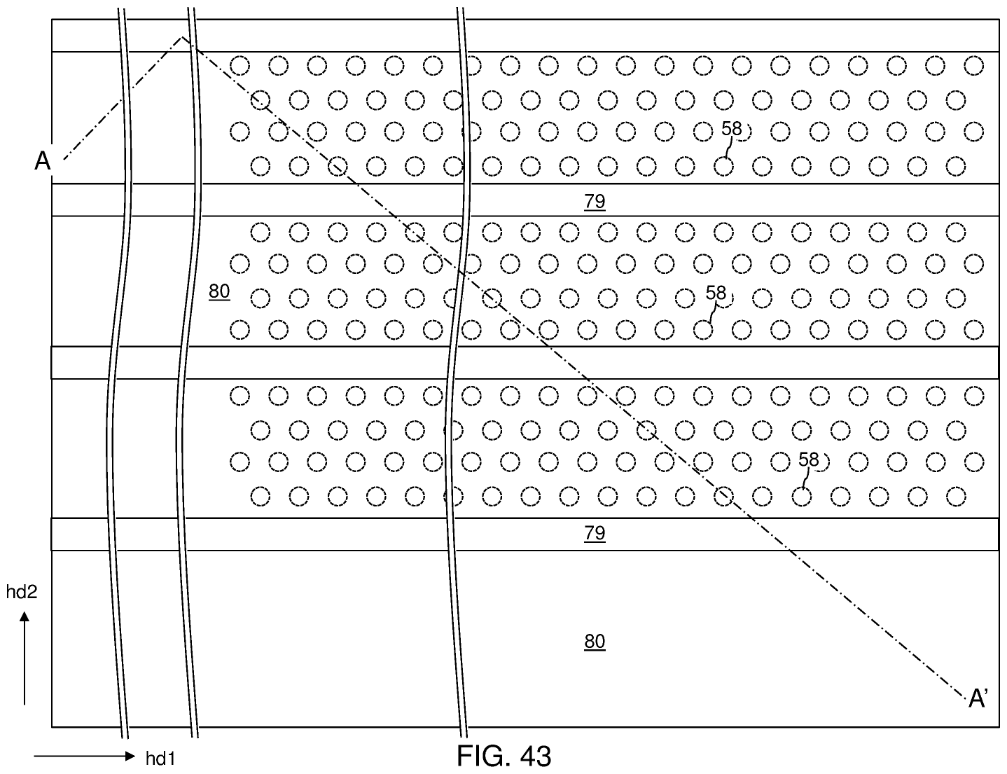

Referring to FIGS. 42 and 43, the processing steps described with reference to FIGS. 13A and 13B can be performed to form a contact-level dielectric layer 80 and backside trenches 79.

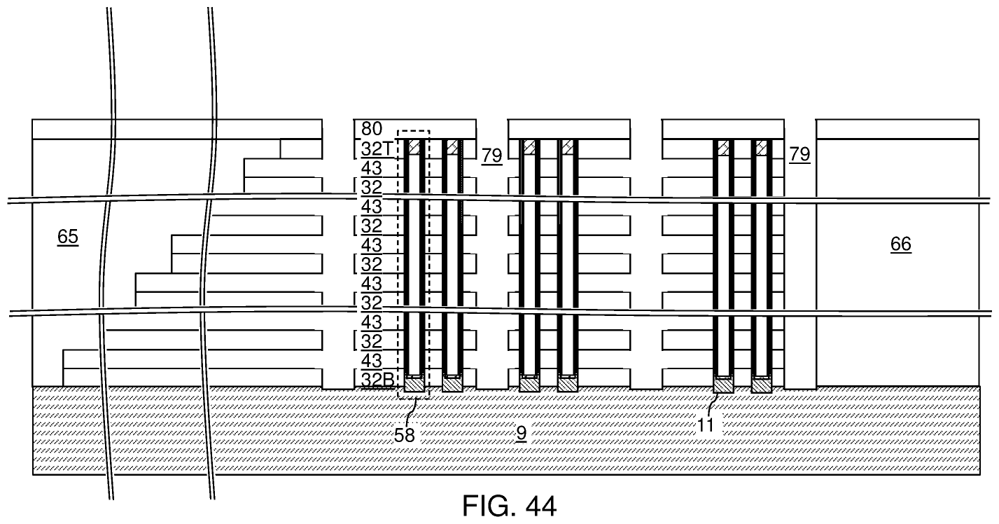

Referring to FIG. 44, the processing steps described with reference to FIG. 14 can be performed to form backside recesses 43. The backside recesses 43 can be formed in volumes from which the sacrificial material layers 42 are removed. Sidewall surface segments of the memory opening fill structures 58 can be physically exposed to the backside recesses 43.

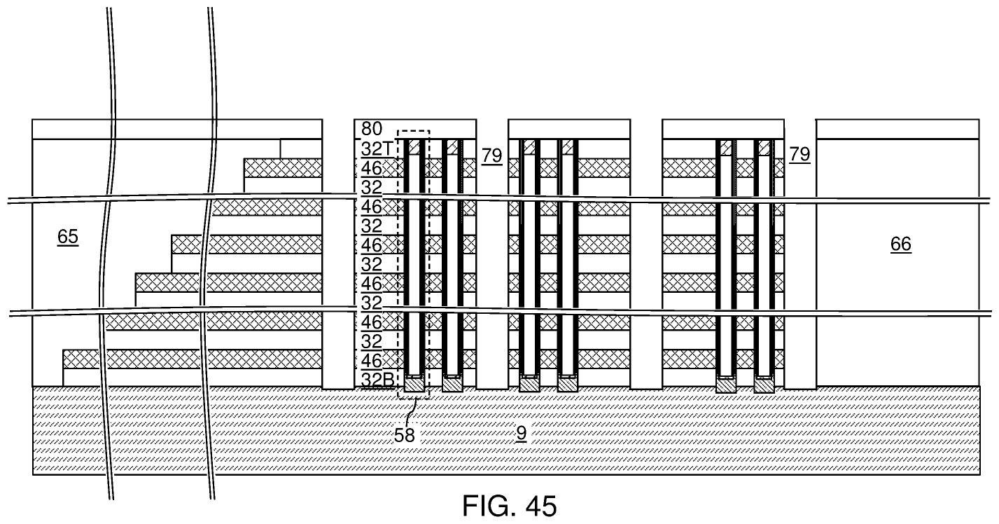

Referring to FIG. 45, the processing steps described with reference to FIG. 16 can be performed to form an optional backside blocking dielectric layer (not shown) and an electrically conductive layer 46 in each backside recess 43.

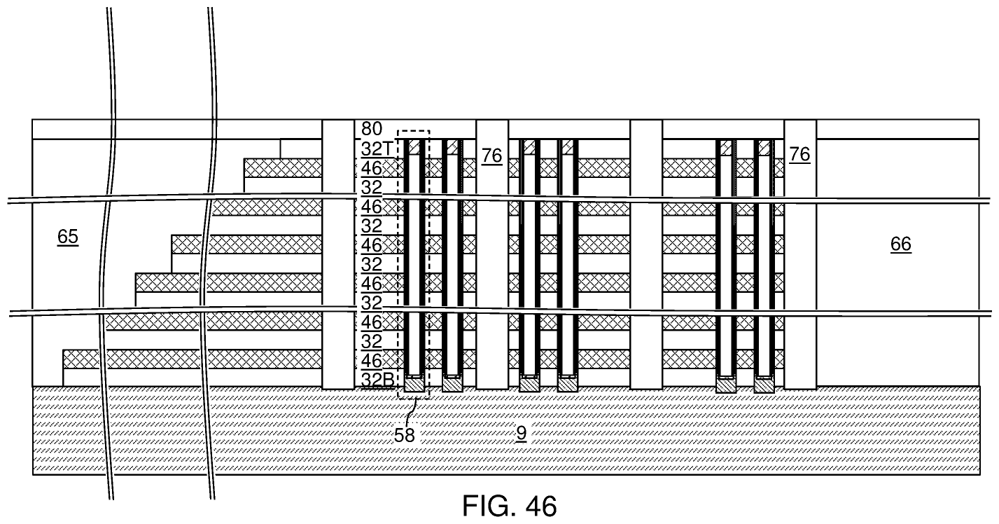

Referring to FIG. 46, the processing steps described with reference to FIG. 17 can be performed to form backside trench fill structures 76.

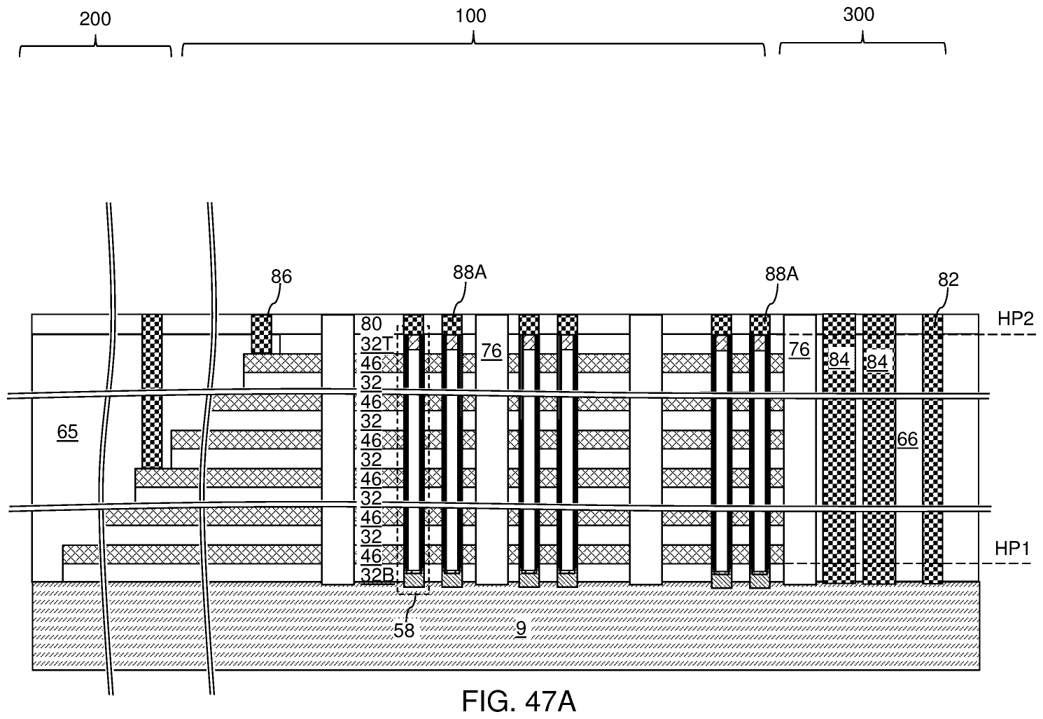

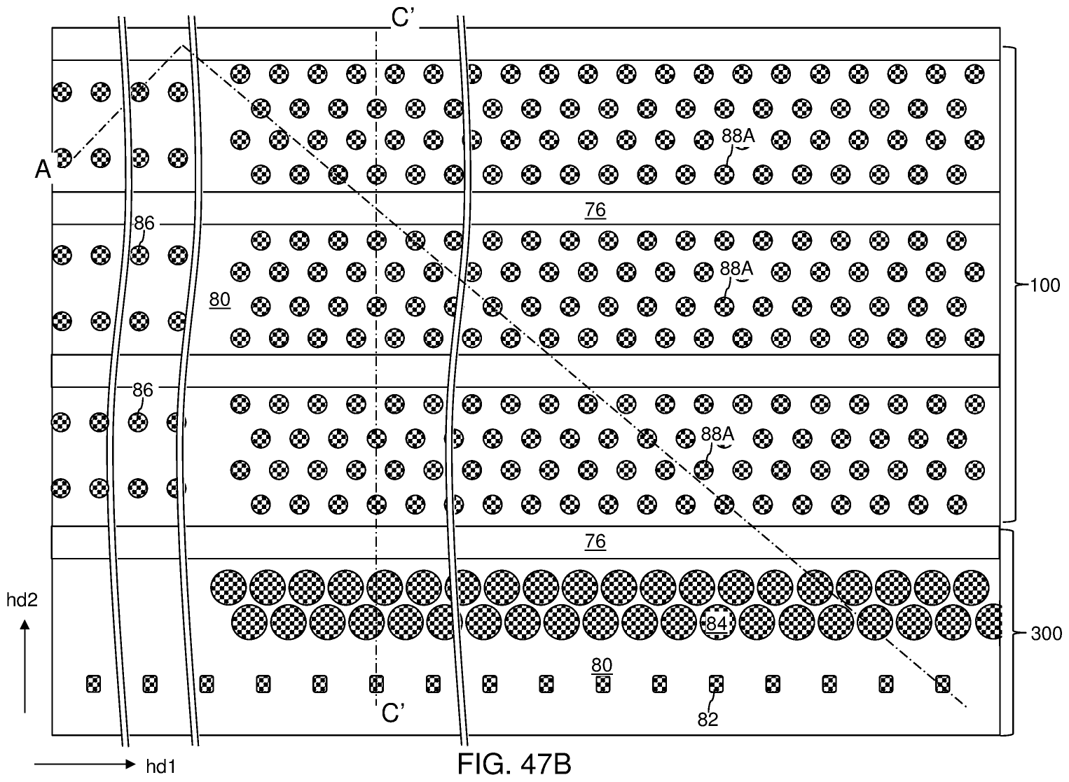

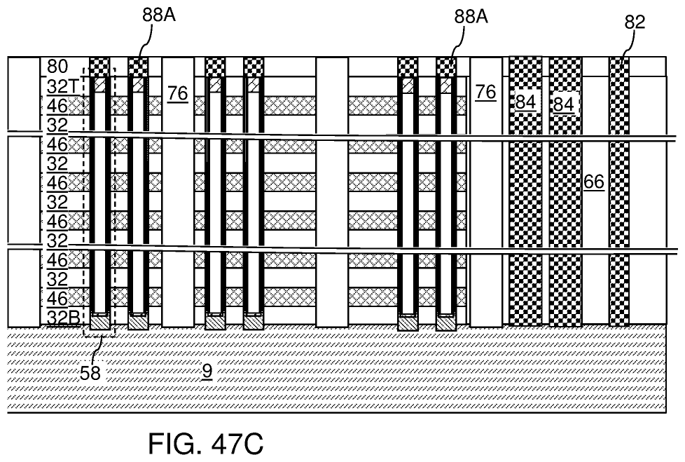

Referring to FIGS. 47A-47C, a photoresist layer (not shown) can be applied over the contact-level dielectric layer 80, and can be lithographically patterned to form openings therethrough in the peripheral region 300. An anisotropic etch process can be performed to transfer the pattern of the openings in the photoresist layer through the contact-level dielectric layer 80 and optionally through the dielectric material portions (65, 66). Various contact via cavities can be formed through the contact-level dielectric layer 80 and the dielectric material portions (65, 66). The photoresist layer can be subsequently removed, for example, by ashing.

At least one conductive material, such as a combination of a metallic barrier material and a metallic fill material, can be deposited in the contact via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the various contact via cavities constitute various contact via structures (86, 88A, 82, 84). The various contact via structures (86, 88A, 82, 84) may comprise layer contact via structures 86 vertically extending through the contact-level dielectric layer 80 and the retro-stepped dielectric material portion 65 and contacting a respective one of the electrically conductive layers 46 in the staircase region 200, drain contact via structures 88A contacting a top surface of a respective one of the drain regions 63 in the memory array region 100, and through-memory-level via structures 82 and conductive via structures 84 that vertically extend through the contact-level dielectric layer 80 and the field dielectric material portion 66 and contacting a top surface of the carrier substrate 9 in the peripheral region 300. The height of the through-memory-level via structures 82 and the conductive via structures 84 may be the same as the sum of the thickness of the field dielectric material portion 66 and the thickness of the contact-level dielectric layer 80. The through-memory-level via structures 82 are subsequently employed to provide electrically conductive paths between memory-side metal interconnect structures and backside bonding pads to be subsequently formed. The conductive via structures 84 are subsequently employed as components of temporary electrically conductive paths between the memory-side metal interconnect structures and the carrier substrate 9 during formation of the memory-side metal interconnect structures. In one embodiment, the lateral dimension of each conductive via structure 84 along the first horizontal direction hd1 may be greater than nearest-neighbor spacing between the memory opening fill structures 58 along the first horizontal direction hd1.

In the third exemplary structure, the conductive via structures 84 can be formed adjacent to the alternating stack (32, 46) of insulating layers 32 and electrically conductive layers 46. The conductive via structures 84 vertically extend at least from a first horizontal plane HP1 including a top surface of a bottommost insulating layer 32B within the alternating stack (32, 46) to a second horizontal plane HP2 including a top surface of a topmost insulating layer 32T within the alternating stack (32, 46). In one embodiment, a dielectric material portion (such as a field dielectric material portion 66) can be provided on a side of the alternating stack (32, 46), and the conductive via structures 84 can be formed through the field dielectric material portion 66 in the peripheral region 300. In one embodiment, such a dielectric material portion (e.g., the field dielectric material portion 66) may be located adjacent to the alternating stack (32, 46), and may have the same vertical extent as that alternating stack (32, 46). In one embodiment, the conductive via structures 84 vertically extend through and are in contact with the field dielectric material portion 66.

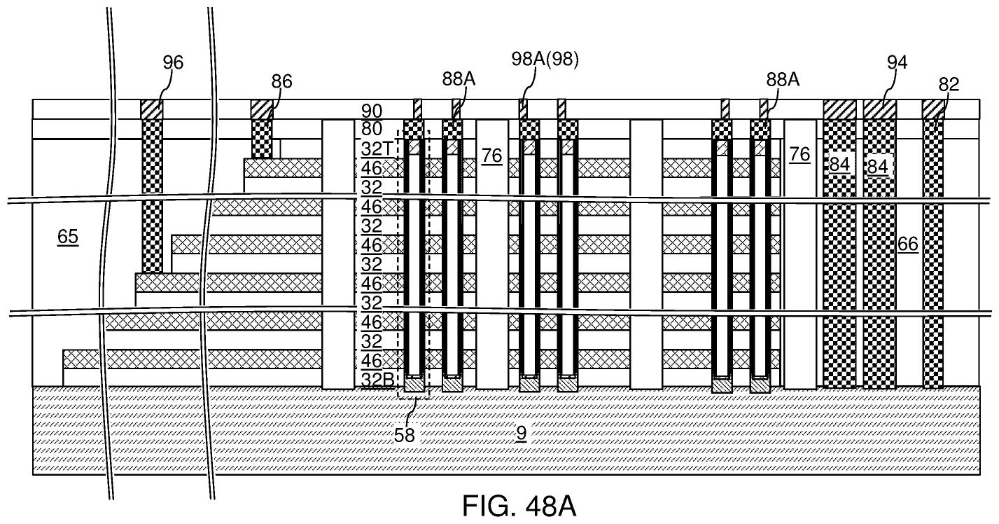

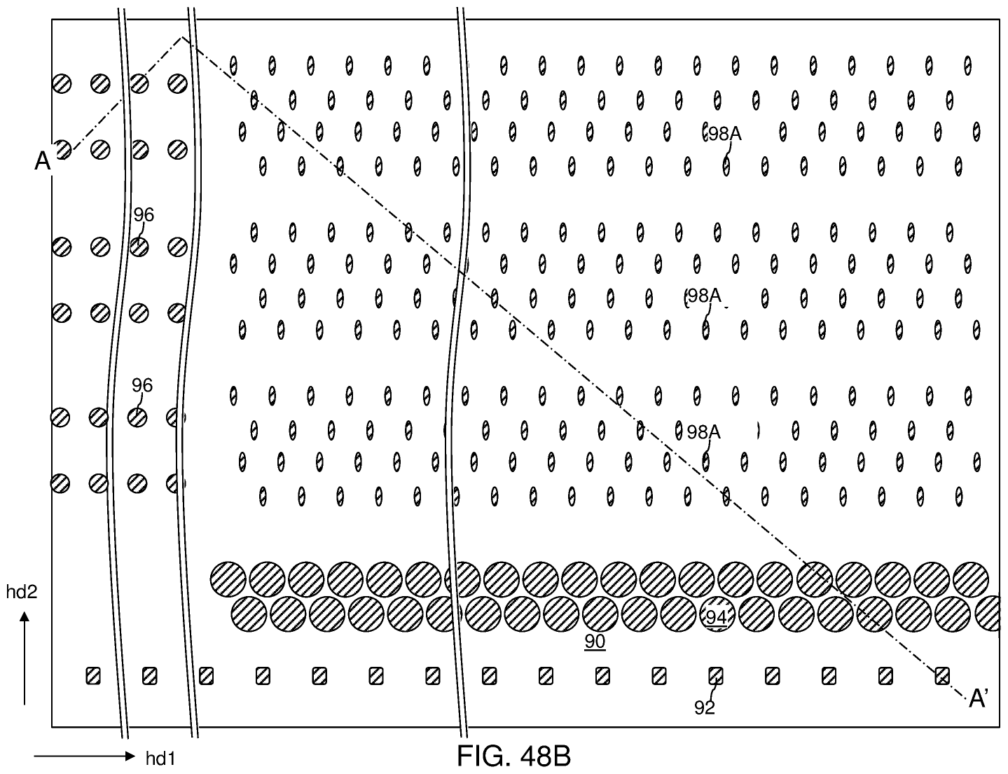

Referring to FIGS. 48A and 48B, a connection-level dielectric layer 90 can be formed over the contact-level dielectric layer 80 by deposition of a dielectric material such as silicon oxide. Connection via structures (98A, 94, 96, 92) can be formed through the connection-level dielectric layer 90 on a respective one of the contact via structures (86, 88, 84, 82). For example, bit-line-connection via structures 98A can be formed on the drain contact via structures 88A, discharge-path connection via structures 94 can be formed on the conductive via structures 84, layer connection via structures 96 can be formed on the layer contact via structures 86, and peripheral connection via structures 92 that are formed on through-memory-level via structures 82.

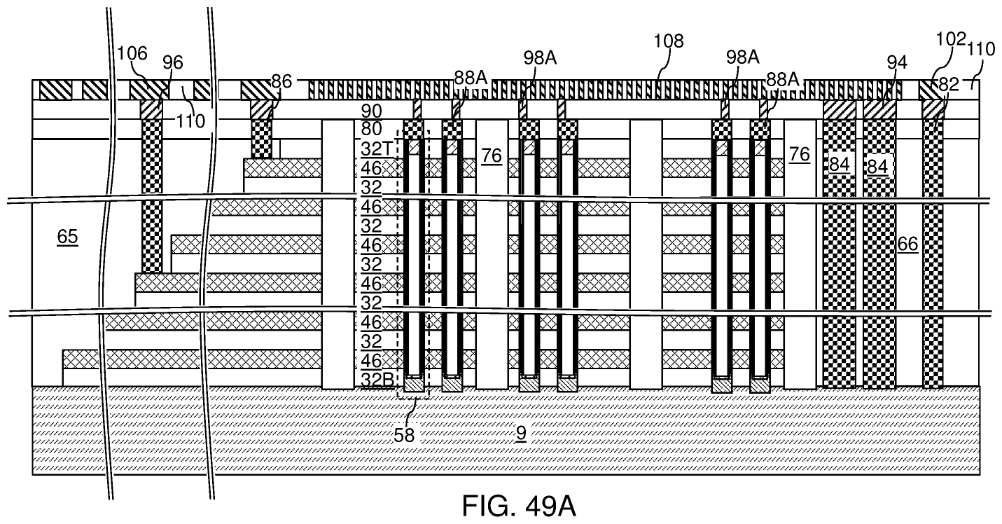

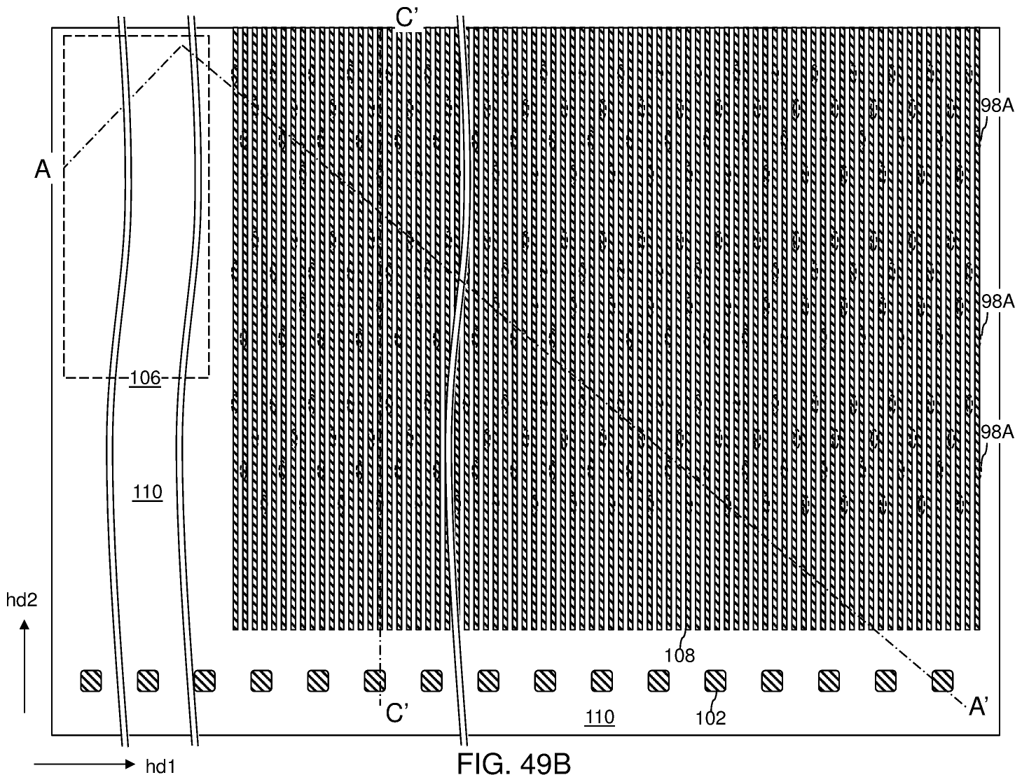

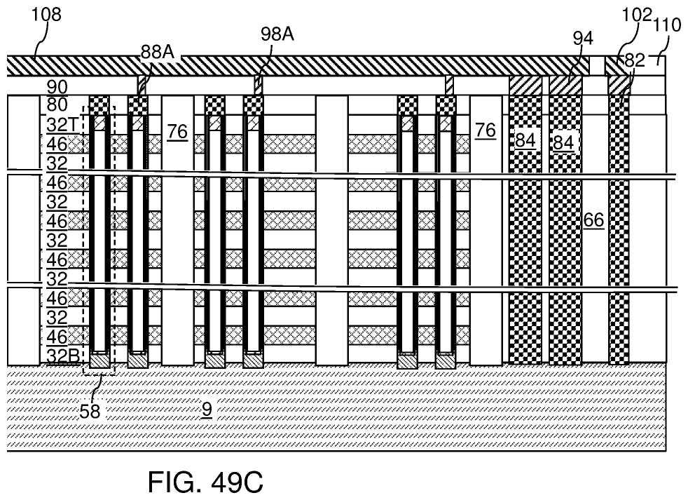

Referring to FIGS. 49A-49C, a line-level dielectric layer can be formed over the connection-level dielectric layer 90. The line-level dielectric layer is herein referred to as a bit-line-level dielectric layer 110 or a first-metal-line-level dielectric layer 110. The above described first-level metal lines (108, 106, 102) can be formed in the bit-line-level dielectric layer 110.

The first-level metal lines (108, 106, 102) may include bit lines 108. Each bit line 108 can be electrically connected to a respective subset of the drain regions 63 through a respective subset of the drain contact via structures 88A and a respective subset of the bit-line-connection via structures 98A. In the third embodiment, each bit line 108 is also electrically connected to a conductive via structure 84 through a discharge-path connection via structure 94. The first word-line-connection metal lines 106 can be formed on the layer connection via structures 96. The first peripheral-connection metal lines 108 can be formed on the peripheral connection via structures 92.

In one embodiment, the lateral dimension of the discharge-path connection via structures 94 along the first horizontal direction hd1 may be greater than the nearest-neighbor spacing between the memory opening fill structures 58 along the first horizontal direction, and a plurality of bit lines 108 may contact a discharge-path connection via structure 94. Thus, a plurality of bit lines 108 may be electrically connected (i.e., shorted) to each other through at least one discharge-path connection via structure 94. In one embodiment, a bit line 108 may contact a plurality of discharge-path connection via structures 94 that are laterally offset from each other along the second horizontal direction hd2.

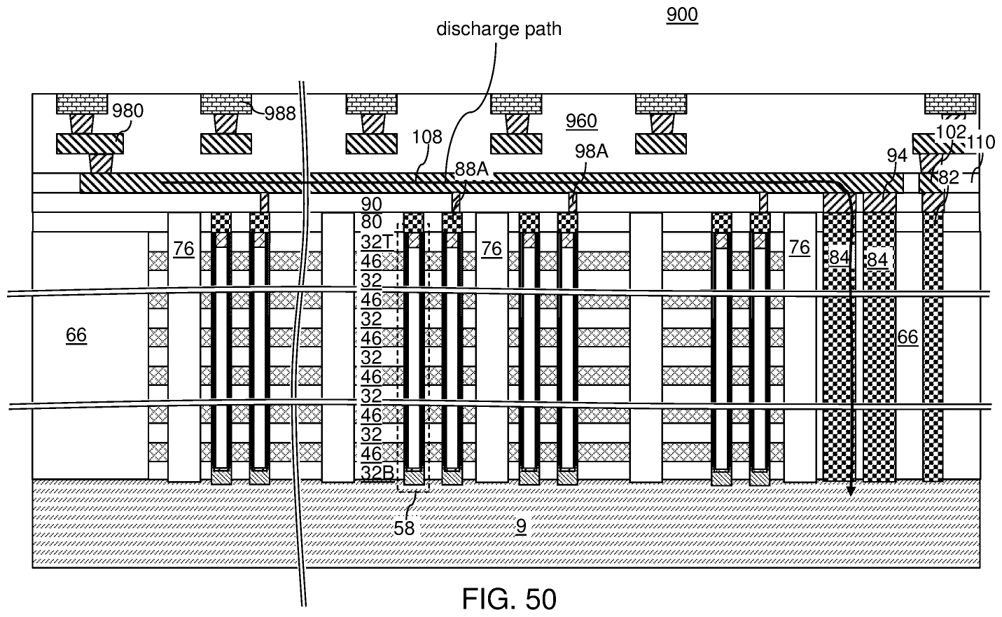

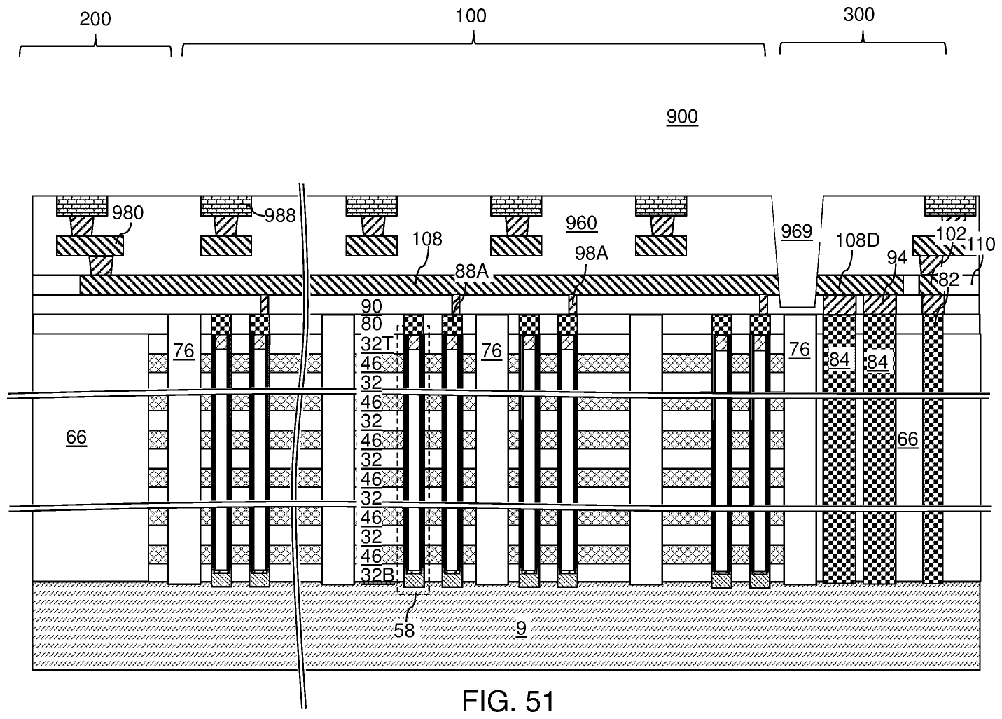

Referring to FIG. 50, additional dielectric material layers 960 and additional metal interconnect structures 980 can be formed over the bit-line-level dielectric layer 110, as described above with respect to FIG. 21. The set of all metal interconnect structures formed in, or above, the contact-level dielectric layer 80 is herein referred to as memory-side metal interconnect structures (88A, 86, 82, 84, 98A, 96, 94, 92, 102, 106, 108, 980). Each of the bit lines 108 can be electrically connected to top ends of a respective subset of the vertical semiconductor channels 60 through metallic via structures (88A, 98A), and can be electrically connected to a respective conductive via structure 84 through at least one additional discharge-path via structure 94. Thus, each conductive via structure 84 can be electrically connected to a respective set of drain regions 63 through a bit line 108.

In the third embodiment, the combination of the bit lines 108, the discharge-path connection via structures 94, and the conductive via structures 84 provide the electrically conductive paths between each metal interconnect structure 980 that is electrically connected to the bit lines 108 to the carrier substrate 9 throughout the processing steps employed to form the metal interconnect structures 980. An exemplary discharge path through a bit line 108 is illustrated in FIG. 50.

Referring to FIG. 51, a photoresist layer (not shown) can be applied over each memory die 900, and can be lithographically patterned to form an elongated opening that extends along a horizontal direction that is perpendicular to the lengthwise direction of the bit lines 108. For example, the elongated opening may laterally extend along the first horizontal direction hd1. The elongated opening may overlie or may be proximal to a boundary between the field dielectric material portion 66 located in the peripheral region 300 and the alternating stack (32, 46) located in the memory array region 100.

An anisotropic etch process can be performed to etch through the memory-side dielectric material layers 960 and through underlying portions of the bit lines 108. A cut trench 969 can be formed in volumes from which materials of the memory-side dielectric material layers 960 and the bit lines 108 are etched. Each bit line 108 can be divided into a remaining bit line 108 that is electrically connected to a respective set of drain regions 63 and located on one side of the cut trench 969, and a dummy bit line 108D that is electrically connected to the conductive via structures 84 and is electrically disconnected from the remaining bit line 108. Thus, the conductive via structures 84, the discharge-path connection via structures 94, and the dummy bit lines 108D can be electrically isolated from the bit lines 108.

Generally, the memory-side metal interconnect structures (88A, 86, 82, 84, 98A, 94, 96, 92, 102, 106, 108, 108D, 980) comprise a plurality of bit lines 108 that extend along the second horizontal direction (e.g., bit line direction hd2) and are laterally spaced apart from each other along a first horizontal direction hd1 with a first pitch. In the third exemplary structure, the memory-side metal interconnect structures (88A, 86, 82, 84, 98A, 94, 96, 92, 102, 106, 108, 108D, 980) further comprise a plurality of dummy bit lines 108D that are laterally spaced from each other along the first horizontal direction hd1 with the first pitch and laterally spaced from the plurality of bit lines 108 along the second horizontal direction hd2 by a gap. The conductive via structures 84 can be electrically connected to each of the plurality of dummy bit lines 108D, and can be electrically isolated from each of the plurality of bit lines 108. Thus, if the bit lines 108 were previously electrically connected to each other through the structures 94, then the bit lines 108 are electrically disconnected from each other another upon formation of the cut trench 969.

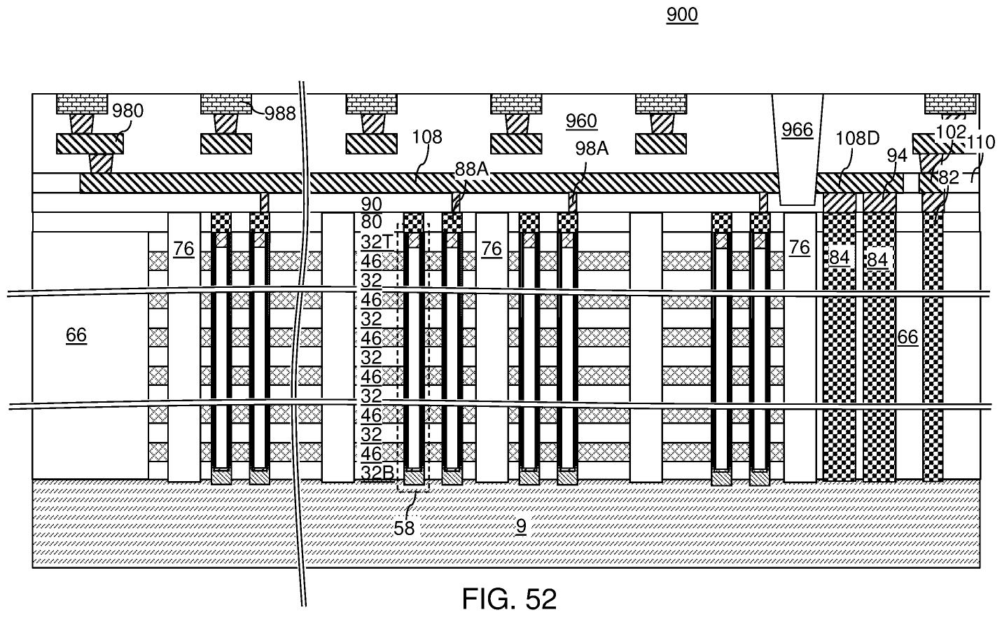

Referring to FIG. 52, a dielectric fill material, such as silicon oxide or silicon nitride, can be deposited in the cut trench 969 to form a dielectric trench fill structure 966.

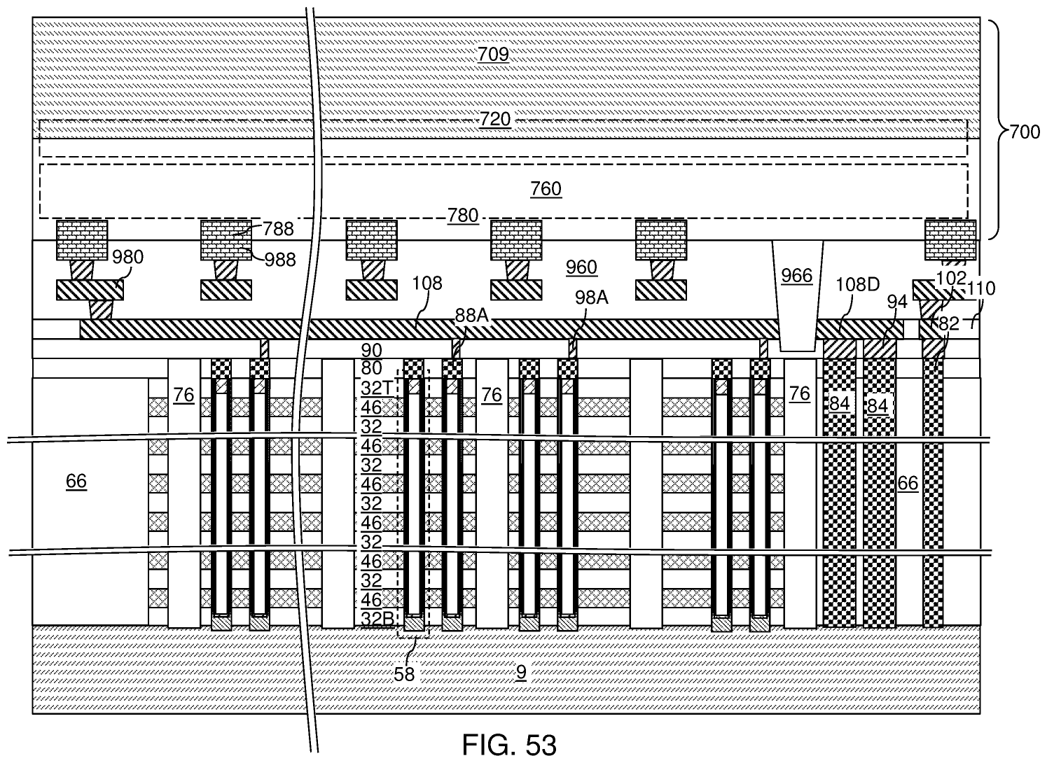

Referring to FIG. 53, the processing steps described with reference to FIG. 22 can be performed to bond a logic die 700 to each memory die 900.

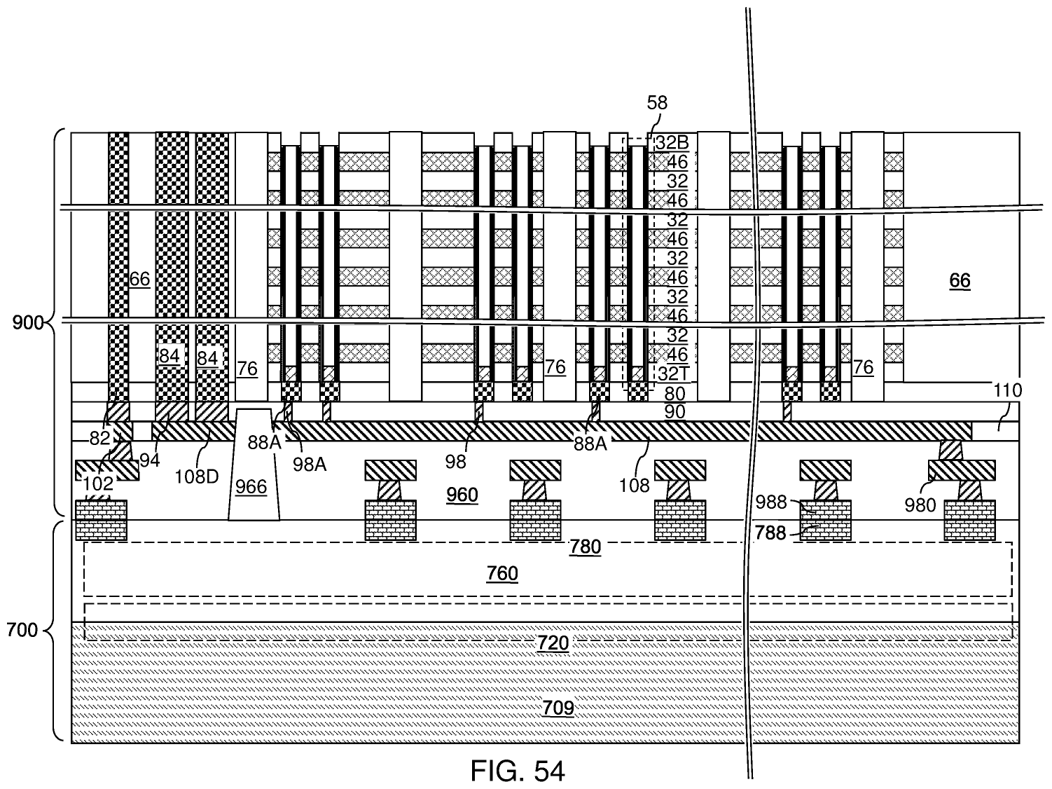

Referring to FIG. 54, the processing steps described with reference to FIGS. 23, 24A and 24B, and 25A and 25B can be performed to remove the sacrificial pillar structures 11, and to remove portions of the memory films 50 located on the bottom side of the alternating stacks (32, 46) and to physically expose end portions of the vertical semiconductor channels 60.

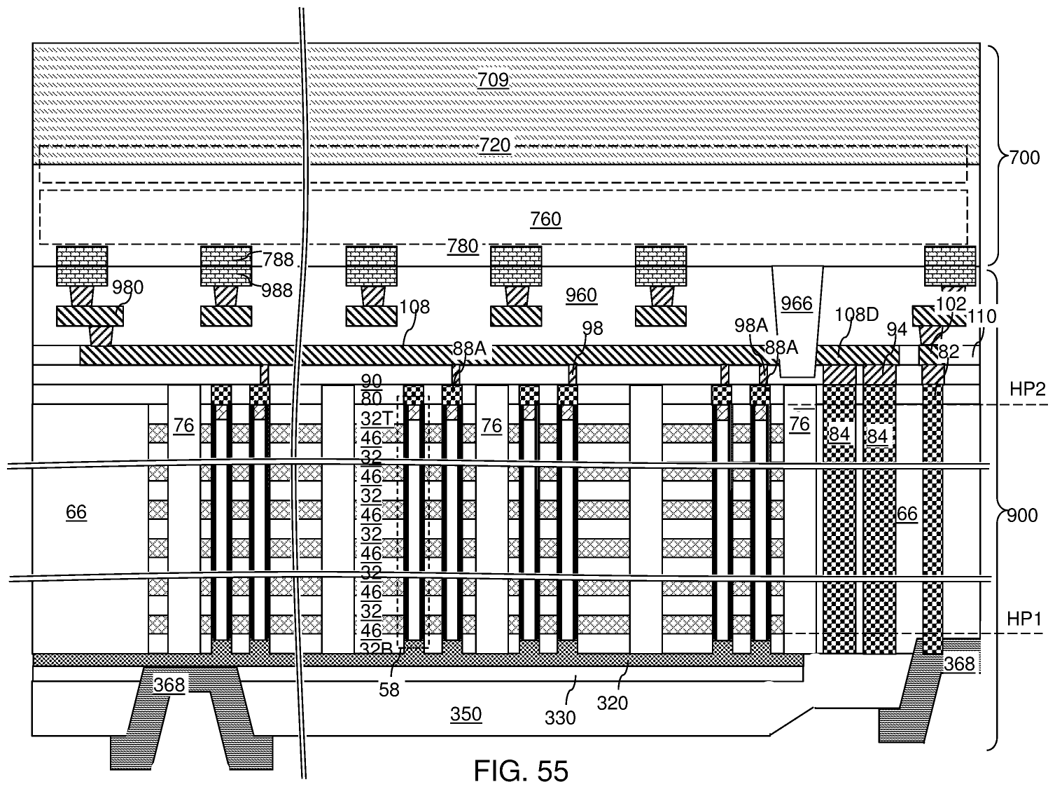

Referring to FIG. 55, the processing steps described with reference to FIG. 26 can be performed to form a source layer 320, a dielectric cover layer 330, a backside dielectric layer 350, and optional backside bonding pads 368.

The entirety of each bottom surface of the conductive via structures 84 can be contacted by the backside dielectric layer 350. In one embodiment, the backside dielectric material layer 350 may have a contoured bottom surface such that a bottom surface of a first portion of the backside dielectric material layer 350 that underlies the memory opening fill structures 58 is recessed below a horizontal plane including a bottom surface of a second portion of the backside dielectric material layer 350 that underlies the conductive via structures 84. The second portion of the backside dielectric material layer 350 may have the same thickness as the first portion of the backside dielectric material layer 350.

The conductive via structures 84 vertically extend between one of the memory-side metal interconnect structures (88A, 86, 82, 84, 98A, 94, 96, 92, 102, 106, 108, 108D, 980) (such as a respective one of the discharge-path connection via structures 94) and the backside dielectric material layer 350. The entirety of an end surface of each conductive via structure 84 can be in contact with the backside dielectric material layer 350. The conductive via structures 84 are not in direct contact with any conductive material or with any semiconductor material on a side of the alternating stacks (32, 46) (i.e., on the side of the source layer 320) relative to the first horizontal plane HP1 upon formation of the backside dielectric layer 350.

The source layer 320 underlies the alternating stacks (32, 46), overlies a portion of the backside dielectric material layer 350, and contacts each bottom end of the vertical semiconductor channels 60. A first subset of the backside bonding pads 368 can be formed on the source layer 320. A second subset of the backside bonding pads 368 can be formed on the through-memory-level via structures 82.

Referring to all drawings and according to various embodiments of the present disclosure, a memory device comprising a memory die 900 is provided. The memory die 900 comprises: an alternating stack (32, 46) of insulating layers 32 and electrically conductive layers 46 that overlies a backside dielectric material layer 350; a memory opening 49 vertically extending through the alternating stack (32, 46); a memory opening fill structure 58 located in the memory opening 49 and comprising a vertical stack of memory elements and a vertical semiconductor channel 60; memory-side metal interconnect structures (88A, 88B, 86, 82, 98A, 98B, 96, 94, 92, 102, 106, 108, 108D, 980) embedded within memory-side dielectric material layers (80, 90, 110, 960) that overlie the alternating stack (32, 46); and a conductive via structure (38, 338, 84) vertically extending between one of the memory-side metal interconnect structures (88A, 88B, 86, 82, 98A, 98B, 96, 94, 92, 102, 106, 108, 108D, 980) and the backside dielectric material layer 350, wherein an entirety of an end surface of the conductive via structure (38, 338, 84) is in contact with the backside dielectric material layer 350.

In one embodiment, the memory device further comprises a source layer 320 underlying the alternating stack (32, 46), overlying a portion of the backside dielectric material layer 350, and contacting a bottom end of the vertical semiconductor channel 60.

In one embodiment, the backside dielectric material layer 350 has a contoured bottom surface such that a bottom surface of a first portion of the backside dielectric material layer 350 that underlies the memory opening fill structure 58 is recessed below a horizontal plane including a bottom surface of a second portion of the backside dielectric material layer 350 that underlies the conductive via structure (38, 338, 84); and the second portion of the backside dielectric material layer 350 has a same thickness as the first portion of the backside dielectric material layer 350.

In one embodiment, the conductive via structure (38, 338, 84) vertically extends at least from a first horizontal plane HP1 including a top surface of a bottommost insulating layer 32 within the alternating stack (32, 46) to a second horizontal plane HP2 including a top surface of a topmost insulating layer 32 within the alternating stack (32, 46). In one embodiment, the conductive via structure (38, 338, 84) is not direct contact with any conductive material or with any semiconductor material located below the first horizontal plane HP1.

In one embodiment, the memory opening fill structure 58 comprises a drain region 63 contacting a top end of the vertical semiconductor channel 60; the memory-side metal interconnect structures ((88A, 88B, 86, 82, 98A, 98B, 96, 94, 92, 102, 106, 108, 108D, 980) comprises a bit line 108 that is electrically connected to the drain region 63 through at least one metal via structure (88, 98); and the conductive via structure (38, 338, 84) is electrically connected to the bit line through at least one additional metal via structure {(88, 98) or 94}.

In one embodiment, the memory device comprises: memory-side bonding pads 988 embedded within the memory-side dielectric material layers (80, 90, 110, 960) and electrically connected to the memory-side metal interconnect structures (88A, 88B, 86, 82, 98A, 98B, 96, 94, 92, 102, 106, 108, 108D, 980); and a logic die 700 comprising a peripheral circuit 720, logic-side metal interconnect structures 780 embedded in logic-side dielectric material layers 760 and electrically connected to the peripheral circuit 720, and logic-side bonding pads 788 electrically connected to the logic-side metal interconnect structures 780 and bonded to the memory-side bonding pads 988.

In one embodiment, the conductive via structure (38, 338, 84) vertically extends through and is laterally surrounded by each electrically conductive layer within the alternating stack (32, 46).

In the first embodiment, the conductive via structure 38 comprises a doped semiconductor material; and the memory device comprises a vertical stack of cylindrical dielectric semiconductor oxide portions 36 that laterally surrounds the conductive via structure 38 and contacts the electrically conductive layers 46.

In the second embodiment, the memory device comprises a vertical stack of dielectric material plates 42′ and interlaced with the insulating layers 32 within the alternating stack (32, 46) along a vertical direction, wherein each dielectric material plate within the vertical stack of dielectric material plates 42′ is located at a level of and is contact with a respective electrically conductive layer 46 of the electrically conductive layers 46, and the conductive via structure 338 vertically extends through the vertical stack of dielectric material plates 42′ and each insulating layer 32 within the alternating stack (32, 46). In the second embodiment, the conductive via structure 338 comprises a metallic material and is in contact with the vertical stack of dielectric material plates 42′ and each insulating layer 32 within the alternating stack (32, 46).

In the third embodiment, the memory device comprises a dielectric material portion 66 located adjacent to the alternating stack (32, 46) and having a same vertical extent as that alternating stack (32, 46), wherein the conductive via structure 84 vertically extends through and is in contact with the dielectric material portion 66. In the third embodiment, the memory-side metal interconnect structures (88A, 88B, 86, 82, 98A, 98B, 96, 94, 92, 102, 106, 108, 108D, 980) comprise a plurality of bit lines 108 that are laterally spaced from each other along a first horizontal direction hd1 with a first pitch and laterally extend along a second horizontal direction hd2; the memory-side metal interconnect structures (88A, 88B, 86, 82, 98A, 98B, 96, 94, 92, 102, 106, 108, 108D, 980)) further comprise a plurality of dummy bit lines 108D that are laterally spaced apart from each other along the first horizontal direction hd1, and laterally spaced from the plurality of bit lines 108 along the second horizontal direction hd2 by a dielectric filled gap 969; and the conductive via structure 84 is electrically connected to the plurality of dummy bit lines 108D and is electrically isolated from each of the plurality of bit lines 108.

The various embodiments of the present disclosure can be employed to electrically ground all metal interconnect structures that are connected to the bit lines 108 during formation of the memory-side metal interconnect structures 980, and to avoid or reduce metal voids caused by floating electrical potential and/or battery effects.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A memory device comprising a memory die, wherein the memory die comprises:
an alternating stack of insulating layers and electrically conductive layers that overlies a backside dielectric material layer;
a memory opening vertically extending through the alternating stack;
a memory opening fill structure located in the memory opening and comprising a vertical stack of memory elements and a vertical semiconductor channel;
memory-side metal interconnect structures embedded within memory-side dielectric material layers that overlie the alternating stack; and
a conductive via structure vertically extending between one of the memory-side metal interconnect structures and the backside dielectric material layer, wherein an entirety of an end surface of the conductive via structure is in contact with the backside dielectric material layer.

2. The memory device of claim 1, further comprising a source layer underlying the alternating stack, overlying a portion of the backside dielectric material layer, and contacting a bottom end of the vertical semiconductor channel.

3. The memory device of claim 2, wherein:
the backside dielectric material layer has a contoured bottom surface such that a bottom surface of a first portion of the backside dielectric material layer that underlies the memory opening fill structure is recessed below a horizontal plane including a bottom surface of a second portion of the backside dielectric material layer that underlies the conductive via structure; and
the second portion of the backside dielectric material layer has a same thickness as the first portion of the backside dielectric material layer.

4. The memory device of claim 1, wherein the conductive via structure vertically extends at least from a first horizontal plane including a top surface of a bottommost insulating layer within the alternating stack to a second horizontal plane including a top surface of a topmost insulating layer within the alternating stack.

5. The memory device of claim 4, wherein the conductive via structure is not direct contact with any conductive material or with any semiconductor material located below the first horizontal plane.

6. The memory device of claim 1, wherein:
the memory opening fill structure further comprises a drain region contacting a top end of the vertical semiconductor channel;
the memory-side metal interconnect structures comprise a bit line that is electrically connected to the drain region through at least one metal via structure; and
the conductive via structure is electrically connected to the bit line through at least one additional metal via structure.

7. The memory device of claim 1, further comprising:
memory-side bonding pads embedded within the memory-side dielectric material layers and electrically connected to the memory-side metal interconnect structures; and
a logic die comprising a peripheral circuit, logic-side metal interconnect structures embedded in logic-side dielectric material layers and electrically connected to the peripheral circuit, and logic-side bonding pads electrically connected to the logic-side metal interconnect structures and bonded to the memory-side bonding pads.

8. The memory device of claim 1, wherein the conductive via structure vertically extends through and is laterally surrounded by each electrically conductive layer within the alternating stack.

9. The memory device of claim 8, wherein:
the conductive via structure comprises a doped semiconductor material; and
the memory device comprises a vertical stack of cylindrical dielectric semiconductor oxide portions that laterally surrounds the conductive via structure and contacts the electrically conductive layers.

10. The memory device of claim 1, further comprising a vertical stack of dielectric material plates and interlaced with the insulating layers within the alternating stack along a vertical direction, wherein each dielectric material plate within the vertical stack of dielectric material plates is located at a level of, and is contact with, a respective electrically conductive layer of the electrically conductive layers, and the conductive via structure vertically extends through the vertical stack of dielectric material plates and each insulating layer within the alternating stack.

11. The memory device of claim 10, wherein the conductive via structure comprises a metallic material and is in contact with the vertical stack of dielectric material plates and each insulating layer within the alternating stack.

12. The memory device of claim 1, further comprising a dielectric material portion located adjacent to the alternating stack and having a same vertical extent as that alternating stack, wherein the conductive via structure vertically extends through, and is in contact with, the dielectric material portion.

13. The memory device of claim 1, wherein:
the memory-side metal interconnect structures comprise a plurality of bit lines that are laterally spaced from each other along a first horizontal direction and laterally extend along a second horizontal direction;
the memory-side metal interconnect structures further comprise a plurality of dummy bit lines that are laterally spaced from each other along the first horizontal direction and laterally spaced from the plurality of bit lines along the second horizontal direction by a dielectric filled gap; and
the conductive via structure is electrically connected to the plurality of dummy bit lines and is electrically isolated from each of the plurality of bit lines.

14. A method forming a memory device, comprising:
forming an alternating stack of insulating layers and spacer material layers over a carrier substrate, wherein the spacer material layers are formed as, or are subsequently replaced at least partly with, electrically conductive layers;
forming a memory opening through the alternating stack;
forming a memory opening fill structure in the memory opening, wherein the memory opening fill structure comprises a vertical stack of memory elements and a vertical semiconductor channel;
forming a conductive via structure in electrical contact with the carrier substrate through or adjacent to the alternating stack, wherein the conductive via structure vertically extends at least from a first horizontal plane including a top surface of a bottommost insulating layer within the alternating stack to a second horizontal plane including a top surface of a topmost insulating layer within the alternating stack;
forming memory-side metal interconnect structures embedded within memory-side dielectric material layers over the alternating stack and the conductive via structure;
removing the carrier substrate; and
forming a backside dielectric layer underneath the alternating stack and the conductive via structure, wherein an entirety of a bottom surface of the conductive via structure is contacted by the backside dielectric layer.

15. The method of claim 14, further comprising bonding a logic die over the memory-side metal interconnect structures prior to the removing the carrier substrate, wherein an electrically conductive path extends between the carrier substrate and the memory-side metal interconnect structures through the conductive via structure.

16. The method of claim 14, wherein:
the memory-side metal interconnect structures comprise a bit line that is electrically connected to a top end of the vertical semiconductor channel through at least one metallic via structure and electrically connected to the conductive via structure through at least one additional metallic via structure; and
the conductive via structure is not direct contact with any conductive material or with any semiconductor material on a side of the alternating stack relative to the first horizontal plane upon removal of the carrier substrate.

17. The method of claim 14, further comprising forming a source layer on a bottom end of the vertical semiconductor channel after removing the carrier substrate by depositing and patterning a conductive material or a semiconductor material, wherein the source layer is not in contact with the conductive via structure, and the backside dielectric material layer is formed on a bottom side of the source layer.

18. The method of claim 14, further comprising:
forming a connection opening through the alternating stack, wherein the conductive via structure is formed by depositing a doped semiconductor material in the connection opening, and the spacer material layers are formed as sacrificial material layers;
forming backside recesses by removing the sacrificial material layers; and
forming a vertical stack of cylindrical dielectric semiconductor oxide portions on the conductive via structure by oxidizing surface portions of the connection via structure exposed in the backside recesses.

19. The method of claim 14, wherein:
the spacer material layers are formed as sacrificial material layers; and
the method further comprises replacing first portions of the sacrificial material layers with the electrically conductive layers, wherein remaining second portions of the sacrificial material layers comprise dielectric material plates; and
the dielectric material plates laterally surround the conductive via structure.

20. The method of claim 14, further comprising forming a dielectric material portion on a side of the alternating stack, wherein the conductive via structure is formed through the dielectric material portion.
